(19) United States
(12) Patent Application Publication
(10) Pub. No.: US 2023/0106866 A1
(43) Pub. Date: Apr. 6, 2023

(54) Illumination Devices with Nested Enclosures

(71) Applicant: Bruce H. Baretz, Montclair, NJ (US)

(72) Inventor: Bruce H. Baretz, Montclair, NJ (US)

(21) Appl. No.: 18/048,640

(22) Filed: Oct. 21, 2022

Related U.S. Application Data
(63) Continuation-in-part of application No. 17/458,971, filed on Aug. 27, 2021.

(51) Int. Cl. F21K 9/237; F21V 9/30; F21V 29/70; F21K 9/232; F21V 31/04

(52) U.S. Cl. CPC F21K 9/237; F21V 9/30; F21V 29/70; F21K 9/232; F21V 31/04

(57) ABSTRACT

A light emitting assembly comprising a solid state device, when and if coupleable with a power supply constructed and arranged to power the solid state device to emit from the solid state device a first wavelength radiation (i.e., primary radiation), and a set of nesting enclosures enhancing the luminescence of the solid-state device and providing a mechanism for arranging luminophoric medium in receiving relationship to said first radiation, and which in exposure to said first radiation, is excited to responsively emit a second wavelength radiation (i.e., secondary radiation) or to otherwise transfer its energy without radiation to a third radiative component (i.e., tertiary radiation). In a specific embodiment, monochromatic blue or UV light output from a light-emitting diode is converted to achromatic light with fluorescers and phosphors under an inert gas. In a specific embodiment, heat is dissipated to the external surroundings without employing a heat sink.

### BACKGROUND/SUMMARY

### Field of the Invention

This invention relates to solid state light emitting devices such as light-emitting diodes, also called LEDs, and more particularly to such devices which produce achromatic light without hue (white light) or chromatic light with hue (colored light).

This invention solves the unwanted problem of unavoidable heat generation in such microelectronic devices at the site of a Stokes shift and at a p-n junction of a light-emitting diode.

This invention employs a set of nesting enclosures enhancing the luminescence of the solid-state device and providing a mechanism for arranging luminophoric medium in receiving relationship to said first radiation, and which in exposure to said first radiation, is excited to responsively emit a second wavelength radiation (i.e., secondary radiation) or to otherwise transfer its energy without radiation to a third radiative component (i.e., tertiary radiation). In a specific embodiment, monochromatic blue or UV light output from a light-emitting diode is converted to achromatic light with fluorescers and phosphors under an inert gas. In a specific embodiment, heat is dissipated to the external surroundings without employing a heat sink.

The present invention applicable to general illumination is based on the discovery that a highly efficient achromatic, chromatic and non-visible light emitting device may be simply and economically fabricated utilizing a solid state light emitting diode die that generates primary radiation which transfers its energy, radiatively or non-radiatively, to secondary luminescent elements where the diode die and or the secondary luminescent elements are in an enhancing and or protecting enclosure. The invention enhances and protects both the p-n junction and or luminescent elements associated with light generation, instantaneously and, or, over the long term. More specifically, the invention achieves the dissipation of heat through an outer optically transmissive enclosure to an external surroundings.

Nested enclosures are used in the instant invention with exemplary embodiments allowing for different environments to be sequestered in different enclosures, each of which may contain different elements required to make the microelectronic device perform instantly at its best or to protect these elements from long-term operationally degradation. The enclosures must be optically transmissive so that the desired luminance be obtained at the same time thermal radiation may be transmitted. With respect to an optically transmissive enclosure, specifically we define, as used herein, transmissive means the act of transmission, itself meaning to cause (something, such as light) to pass or be conveyed through space or a medium, such as an outer optically transmissive enclosure.

Optically means of, relating to, or being objects that emit light in a range of frequencies; hence optically transmissive enclosures are those that allow for the passage of a range of frequencies through (emphasis is on “through”) said enclosure from a source that is within an enclosure or where the enclosure intervenes between the source and the external surroundings. How this is accomplished depends on how heat dissipation occurs: either through convection, conduction, or thermal radiation. In the case of thermal radiation, the optically transmissive enclosure allows for the passage through the enclosure as if the enclosure itself was a region of space that is a vacuum, a vacuum is a region of space with the absence of matter. In other words, the optically transmissive enclosure allows for the passage through but does not in of itself carry the thermal radiation. For convection and conduction, in general, any medium or matter through which the heat is dissipated, that medium is said to carry, or participate in the process of dissipating the heat.

There is a difference between passage through a medium in the context of a medium allowing radiation to pass through versus that of a medium carrying or participating (conveying) in the process of dissipating heat. A medium that carries the heat being dissipated is one where the molecules carrying the heat increase their kinetic energy, increase their molecular volume, or break intermolecular bonding. [By way of illustrative example, in “The Molecular Basis for the Heat Capacity and Thermal Expansion of Natural Waters”, Peter Brewer and Edward Peltzer point out that “Warming of water increases the kinetic energy of the molecules and induces breaking of hydrogen bonds (8.364 kJ/mol; 1.999 kcal/mol); both effects increase the volume of the fluid. Warming pure water from 0-10° C. increases the single H₂O molecular form by 1.64%, accounting for 36.3% of the energy consumed. The specific heat of pure water is thus attributable (63.7%) to increasing the kinetic energy of the water, and (36.3%) to the energy required to break hydrogen bonds.”]. Thermal radiation to dissipate heat is best employed when there is no molecular interaction (absorption) of the radiation, as opposed to convection and conduction. This is the reason the optically transmissive intervening enclosures' spectral transmittivity should match the spectrum of a thermal radiation as close as possible to avoid molecular involvement. Paradoxically, of course, thermal radiation is initially generated from molecular motions such as in a blackbody but relies not on molecular involvement for its transport. [Brewer, P. G., & Peltzer, E. T. (2019). The Molecular Basis for the Heat Capacity and Thermal Expansion of Natural Waters. Geophysical Research Letters, 46, 13227-13233. https://doi.org/10.1029/2019GL085117] One consequence for the transport or dissipation of the heat is that when molecules collide and the kinetic energy of one is transferred to another, then the macroscopic heat itself is transferred from one location to another.

### BACKGROUND OF THE INVENTION

General illumination is a basic need of society which becomes most evident when it is not otherwise available. Throughout the history of lighting innovation, the challenge facing the inventor and those engaged to practice the inventions have been to 1) coax more light from a device so designed, 2) produce the light more efficiently, 3) effect the produced light in a manner that is physiologically preferred, 4) produce the maximal light for longer periods of time and 5) manufacture the device that meets the first four criteria in a lowest possible competitive cost. In almost all cases, the advancement of the art for nascent lighting devices has taken a long a tortuous path requiring innovation from a multitude of inventors and scientists and the practicable application of these innovations in manufacturing and ultimately in the marketplace. The more recent discovery of white light solid-state lighting from a single light emitting diode die (B. H. Baretz et. al., U.S. Pat. No. 6,600,175, filed on 26 Mar. 1996, issued on 29 Jul. 2003: hereinafter “Baretz et. al. [2003]”) has elevated the heretofore chromatic solid-state lights unsuitable for general illumination into a lighting innovation with foresight; it is expected, to be an alternative device for indoor and outdoor lighting for many decades.

Other examples of white-light light-emitting diodes, or light sources comprising them, include:
(1). “White Color Light Emitting Diode”, Canadian Patent Number CA 2427559, Inventor: FUJIWARA, SHINSUKE (Japan), Owner: SUMITOMO ELECTRIC INDUSTRIES, LTD., File Date: 2003 May 2;
(2) “Light Emitting Diode Light Source”, Canadian Patent Number CA 2486266, Inventor: DRY, JOEL M., Owner: Optolum, Inc., File Date: 2003 May 5; and
(3) “LED-Based White-Emitting Illumination Unit, Canadian Patent Number CA 2410668, Inventor: ELLENS, ANDRIES (Germany), JERMANN, FRANK (Germany), OSTERTAG, MICHAEL (Germany), Owners: Patent-Treuhand-Gesellschafts Fuer Electrische Gluelampen mBH, Osram Opto Semiconductors GmbH, File Date: 2001 May 11.

It is the present-day desire to improve the performance of achromatic solid-state lights, primarily, and chromatic light, secondarily, so that the current deficiencies for these devices based on a p-n junction be resolved. The invention that I have made is a dramatic improvement in the utility of solid-state lights based on semiconductor p-n junctions in the context of 1) light output, 2) light efficiency, 3) light projection and utility, 4) light generation durability and 5) the physiological appreciation of the light so produced.

The invention of Baretz et. al. [2003] allows white light for general illumination to be generated using photons emanating from at least one p-n junction which, when connected to a power supply with a suitable electrical current, initially generates radiation through a hole-electron recombination at the p-n junction.

My current invention solves many of the problems that solid-state lighting presently experiences when using light-emitting diode die with a semiconductor p-n junction for the generation of achromatic and chromatic light, as defined hereinafter. My present invention focuses on certain elements of the design of the lamp—the microelectronic device—and allows for a broader implementation of achromatic light formation from a single diode die, a plethora of dies, or an array of dies, capable of producing primary radiation in the visible or outside the visible light spectrum. More specifically, the instant invention teaches how to dissipate heat from a site of a Stokes shift and other sources of inefficiency that culminates thermodynamically in an unwanted and deleterious temperature increase of the device itself.

### General Background on Blue Light Emitting Diodes

For the longest time, blue light-emitting diodes were absent from the list of visible light light-emitting diodes. Pioneering work in SiC and GaN semiconductors, as well as other materials, initiated and reduced to practice in the late 1980's and early 1990's, completed the visible light spectrum of chromatic solid-state lights. The very earliest focus on GaN semiconductors can be traced to gallium nitride “electroluminescent” diodes that were demonstrated at RCA Laboratories in the 1970s (J. I. Pankove, E. A. Miller, J. E. Berkeyheiser, RCA Rev. 32, 383 (1971)). At least three major problems had to be solved for GaNs to succeed: (i) the lack of suitable lattice-matched epitaxial substrates, (ii) thermal convection problems due to the remarkably high growth temperatures (about 1000° C.), and (iii) the failure of p-type doping. Ultimately these problems were solved, and today blue light-emitting diodes are sold in the billions of units per year and UV light-emitting diodes are also commercially available.

There are too many inventors and researchers of foremost importance and substantive contributions to reference herein, but considerable and substantive importance are the inventive work of Professor Isamu Akasaki of the School of Engineering, Nagoya University and Shuji Nakamura of Nichia Corporation. As it has been elsewhere reported (Faso, G. Science, Vol 272, Issue 5269, 1751-1752, 21 Jun. 1996), most research efforts worked with GaN and makes use of sapphire substrates, which have a lattice mismatch of about 15% with respect to GaN. Akasaki at Nagoya University and Nakamura at Nichia both developed buffer-layer technologies to achieve GaN epitaxial growth with appropriate defect density. Both Akasaki and Nakamura use metal-organic chemical vapor deposition methods. The substrate temperature is more than 1000° C. during growth. This temperature is exceptionally high and causes convection problems, which were addressed by one of Nakamura's inventions. It is reported that Nakamura developed a dual-flow reactor, where an auxiliary stream of gas blows perpendicularly to the substrate, pushing the principal stream of reactants toward the substrate and improving the growth.

A long-standing problem was the failure to achieve p-type doping in GaN materials. Akasaki showed that a solution existed: he discovered that low-level electron beam irradiation could yield p-type GaN (H. Amano et al., J. Lumin. 40-41, 121 (1988)). Nakamura found (S. Nakamura, N. Iwasa, M. Senoh, T. Mukai, Jpn. J. Appl. Phys. 31, 1258 (1992)) that many previous GaN researchers had annealed their samples in ammonia (NH3). Ammonia dissociates above ˜500° C., releasing atomic hydrogen, which passivates the acceptors. Therefore, Nakamura switched to annealing in a clean nitrogen (N2) atmosphere and thereby invented a reliable method to achieve high quality p-type GaN materials. (1. See also Shuskus, A., U.S. Pat. No. 4,448,633, issued on May 15, 1984. 2. See also “Process for doping crystals of wide band gap semiconductors” U.S. Pat. No. 4,904,618 (and patents that reference same), inventor Gertrude Newmark which proposes nitrogen as a “less mobile dopant” in a wide band gap semiconductor.) These discoveries led Nakamura with colleagues at Nichia to the development of commercial blue GaN light-emitting diodes (S. Nakamura, T. Mukai, M. Senoh, Jpn. J. Appl. Phys. 30, L1998 (1991)).

Relying on self-acclamations from Toyoda Gosei and Nichia, concurrently with the pioneering work reported from Nichia and as early as 1986, Toyoda Gosei started developing GaN-based blue light-emitting diodes under the guidance of Professor Isamu Akasaki and with the assistance of Toyota Central R&D Labs., Inc. In the following year, 1987, Japan Science and Technology Corporation supported the development of blue light-emitting diodes to Toyoda Gosei, which Toyoda Gosei successfully achieved in 1991. In October 1995, Toyoda Gosei started commercial production of high-brightness blue light-emitting diodes.

Prof. Shuji Nakamura and his efforts at Nichia and the University of California at Santa Barbara are as legendary as the outstanding science performed by Holonyak, Craford and Dupuis. What is clear is that inventing and implementing blue light emitting diodes was a dramatically brilliant breakthrough in materials science and electrical engineering.

Radiative recombination in GaN blue light-emitting diode die using time resolved measurements show a bimolecular recombination characteristic and at 300 K, a lifetime of 130 picoseconds. (C.-K. Sun, S. Keller, G. Wang, M. S. Minsky, J. E. Bowers, and S. P. DenBaars, “Radiative recombination lifetime measurements of InGaN single quantum well”, Applied Physics Letters—Sep. 23, 1996—Volume 69, Issue 13, pp. 1936-1938)

### The Discovery of White Light Emitting Diodes

The introduction of blue and or ultraviolet light-emitting diode, however, allows in theory for the introduction of white light light-emitting diode systems and thus has the potential to open the display market to light-emitting diodes by providing a practical means to achieve vibrant color, pale color, and white light (achromatic light without hue) illumination.

Given the desirability of solid-state white lights for general illumination and for displays, considerable effort has been expended to produce white light light-emitting diodes. Although the recent availability of the blue light-emitting diode makes a full color, and by extension a white light displays realizable, conventionally it has been considered that such a display would require at least three light-emitting diodes, at least one each of blue, green, and red-light emitting diode die. The multiple light-emitting diodes would be then incorporated into complicated and expensive light-emitting diode modules to obtain the required broadband illumination necessary to provide white light. Even if a discrete light-emitting diode lamp were constructed that provides white illumination (as opposed to the utilization of a multitude of single die, single color discrete light-emitting diode lamps in a module or sub-assembly), prior to the invention of Down Conversion for white light generation, the state of the art required the utilization of multiple light-emitting diode dies and typically at least four electrical leads to power these dies. An issued United States patent teaches a variable color light emitting diode having a unitary housing of clear molded solid epoxy supporting three light-emitting diode dies characterized as producing color hues of red, green, and blue, respectively. (Stinson, U.S. Pat. No. 4,992,704)

Attempts to make white light light-emitting diode from a single die, which would provide considerable economic and performance advantage over Stinson became an early concern in the development and enhancement of GaN semiconductors.

A rather interesting example similar in spirit to the technology referenced in the immediately preceding paragraph was the observation of Yoshinori Shimizu that if a blue light-emitting diode is used as a backlight in a display, and the display had a layer containing an orange fluorescing element; the display appeared to be white. (Y. Shimizu, Japanese Patent number JP8007614, Jan. 12, 1996; Japanese Application number JP19940134763, Jun. 17, 1994) However, the luminescent element and the light emitting diode lamp were not structurally related nor of the same structure.

### Discovery of Down-Conversion

Baretz et. al. [2003] taught the art of white light generation using Down Conversion. This is a fundamental process also referred to as luminescence conversion and or phosphor light-emitting diodes and the art has been dramatically enhanced by the utility of this method of generating white light from a single light emitting diode die. Baretz et. al. [2003] in the now issued U.S. Pat. No. 6,600,175 filed on 26 Mar. 1996 and issued on 29 Jul., 2003 claimed the invention of white light using primary radiation of a relatively shorter wavelength radiation and a collection luminophoric medium arranged in receiving relationship to said primary radiation, and which in exposure to said primary radiation, is excited to responsively emit a secondary, relatively longer wavelength, polychromatic radiation, “with separate wavelengths of said polychromatic radiation mixing to produce a white light output.” White light is known to be defined as achromatic light that is light with no hue. Many invoke the term pure white to refer to achromatic light. The term “white light” is not explicitly defined in Baretz et. al. [2003] although the specification states the purpose of the invention is to “provide while (sic) light solid state luminescent devices using a single die, which initially provide monochromatic radiation and wherein the monochromatic radiation is converted to polychromatic white light, thus providing a solid-state illumination device with white illuminance.” Hence, the specification teaches that white light is practiced as polychromatic and that which provides white illuminance. There is a crucial difference between luminance and illuminance even though that which is usually reported is the former: the latter indicates the light that falls on a surface. The point is that a light that has white luminance—appears white at the source of the light—may not be white light when falling upon a surface (such as a desk, a wall, or a floor); further, light that has white illuminance need not be white at the source of the light. For example, three spatially separate colored light-emitting diode lamps may appear white only on the surface of interest if just prior to falling on the surface of interest—the surface one is seeking to illuminate—the three discrete, distinct, and separate colors are mixed.

It is a well-known principle of excited state quenching that multiple quenchers, if simultaneously present, will ultimately find the lowest energy emitter. Hence, in the presence of blue, green and red fluorescers which are populated by a variety of radiative and or non-radiative means, but each of which may act as quenchers, may find themselves to exclusively populate—in a final state of equilibrium where no other quenching is to take place, only the excited state of the red fluorescer. Hence, the simultaneous presence of blue, green, and red fluorescers—all of which have spectral overlap that may afford Förster energy transfer to take place, for example—may only lead to red light emission. In the case of Baretz et. al. [2003], however, it was recognized that certain factors may take place—including extremely short radiative lifetimes and the dispersing of luminophoric centers—that may avoid the well-known quenching to the lowest energy emitter. Alternatively, as it has been demonstrated elsewhere, where only one luminophor is present in a white phosphor light-emitting diode (such as one with a blue light-emitting diode die and a yellow phosphor), quenching to the lowest energy emitter is not a problem nor contemplated since only one luminophoric dye is present in the system. Hence, the invention of Baretz et. al. [2003] teaches radiative down-conversion for single phosphor luminescence conversion, but also down-conversion in so called RGB phosphor light-emitting diodes (that is, lamps with red, green, and blue phosphors). The essential point, which this invention addresses, even for reasonably good phosphors with high yields of emission in the laboratory, should have fast rates of luminescence, or very short radiative lifetimes (e.g., between one and fifty nanoseconds).

Research from the Department of Physics at the University of Connecticut reported that the 4f↔5d transitions of cerium doped crystals are parity-allowed electric dipole transitions and thus have larger oscillator strengths and shorter radiative lifetimes than the more familiar 4f↔4f transitions of the rare-earth ions. The large Stokes shift (˜1800-5500 cm⁻¹) of these 4f↔5d transitions is indicative of the substantial change in the ion-lattice coupling due to the larger radial extent of the 5d wave function compared to the 4f wave function as well as the lack of shielding of the 5d wave function. Typically, the 4f↔5d transitions lie near ultraviolet with transition energies near 33,000 cm⁻¹. Lyu and Hamilton report the radiative lifetime of conventional Ce³⁺:YAG to be 59.1 nanoseconds whereas other Ce³⁺ phosphors with different lattices are between 17.1 nanoseconds and 39.0 nanoseconds. It is desirable to use a Ce³⁺: YAG phosphor where the radiative lifetime is shorter than 59.1 nanoseconds (the rate of fluorescence is faster) to avoid quenching due to high primary radiation dose and non-radiative rates (thermal quenching) with increasing temperature of the surroundings (due to thermally induced ionization of the 5d electron with an Arrhenius activation energy of 18.6 kcal per mole). [Lyu, L. and Hamilton, D. S., Journal of Luminescence 48 & 49 (1991) 251-254]. A desirable radiative lifetime range is between 17.1 nanoseconds and 39.0 nanoseconds. A high radiation flux quenching mechanism is thought to be due to singlet-singlet annihilation at exceedingly high doses of primary radiation continuing for an extended period (as opposed to stimulated emission).

Conventional Ce³⁺: YAG phosphor, as claimed in the prior art, have radiative lifetimes, unfortunately, more than (longer than) fifty nanoseconds. One advantage of luminophors with short radiative lifetimes as discussed in the preceding paragraph are that the rate of luminescence, essentially the reciprocal of the lifetime, is extremely fast. It has been observed and commented on by others investigating the phenomenon known as down conversion and invented by Baretz et. al. [2003] that with high photon flux of a primary radiation, there is essentially a saturation effect so that no more secondary radiation is produced, and more primary radiation is emitted. In the specific case of a blue light-emitting diode die, the phenomenon that has been observed is that as the electrical load is increased—which requires robust p-n junctions—more blue light is emitted, and proportionally less white light is emitted. The problem that has not been heretofore recognized is that with fast rates of luminescence from the excited states, these excited states cannot absorb a secondary photon, assuming of course that the absorption spectrum of the first excited state of the down converting luminophor overlaps the spectral characteristics of a primary radiation. With lower rates of luminescence, multiple photon events are more likely to occur; however, with low rates of luminescence, mechanisms, such as excited state degradation, become competitive thereby effecting the instantaneous and long-term performance of the underlying system. It would be desirable therefore for a device where low rates of luminescence are not problematic and where the device construction itself will mitigate and or eliminate these degradation mechanisms in the excited state (or in the ground state which may also occur, but generally with a lower rate). The means by which the instant invention reduces unwanted quenching of excited states, so that they emit with the highest possible quantum yields, is to use luminophors, whether they be inorganic or organic, whether they be Ce³⁺ doped yttrium aluminum garnet: YAG phosphors or perylene luminophors, with a radiative lifetime of less than fifty nanoseconds and more than one nanosecond. The same preferred radiative range for lifetimes applies to ceramic phosphors.

The invention of Baretz et. al. [2003] is not limited to any one semiconductor although the claims of the issued patent are limited to white light and at least one semiconductor die with the same primary radiative wavelengths; more recently down conversion is claimed in an organic light emitting diode, which is a solid-state light without a semiconductor p-n junction. (Duggal et. al., U.S. Pat. No. 6,700,322)

While Baretz, et. al. [2003] taught that both organic fluorescers and inorganic phosphors can be used for down-conversion to generate white light (as well as chromatic light), the teachings after the invention of Baretz et. al. [2003], and prior to this invention being claimed herein, have focused on inorganic phosphors frequently referred to as ceramic phosphors. Ceramic phosphors utilized in solid-state lighting are not particularly different from the phosphors previously discussed and used for fluorescent lighting and CRT emission. The major challenge for ceramic phosphors utilized in down conversion is that the light emission—a primary radiation—from the diode die are narrow, usually singular in range and of wavelengths of considerably lower energy than that absorbed by CRT and fluorescent lamp phosphors and that the narrow emission profile from the p-n junction has poor overlap with the excitation spectra of the ceramic phosphors required to effect down conversion.

For example, blue light emitting diode die typically emit—within a narrow 5 nm band pass—at 430 nm through 470 nm, depending on the material composition of the die active layer. The ceramic phosphor Ce³⁺ doped yttrium aluminum garnet absorbs blue radiation reasonably well and emits in the yellow. Nevertheless, a primary radiation is partially emitted (incomplete absorption of a primary radiation) and hence the color rendering index is not optimal. On the other hand, UV light-emitting diode die typically emit—within a narrow 5 nm band pass—at 340 nm through 390 nm, depending on the material composition of the die active layer with nearer 380 and 390 nm. Unfortunately, most ceramic phosphors that are said to be excited by UV radiation do not absorb substantively between 340 nm through 390 nm although many are known that absorb UV light from a mercury vapor lamp. For example, whereas a typical mercury vapor lamp has multiple line emissions from the excited states of mercury, these multiple lines are of relatively high energy (254 nm, 313 nm, 365 nm). Most of the phosphors used in other applications do not absorb in the region presently required in solid-state lighting implementations with a semiconductor p-n junction although some have utility: as the blue component, BaMgAl₁₀O₁₇:Eu²⁺ or ZnS:Ag⁺ are known as inorganic phosphors; ZnS:Cu⁺ or (Zn, Cd)S:Cu⁺, or ZnS:(Al, Cu)⁺ are known as blue-green component; Y₂O₂S:Eu²⁺ is known as red component. (Jermann, et. al.; United States Patent Application US2004056256; publication date Mar. 25, 2004) Jermann et. al. describe a white light light-emitting diode lamp using a blue phosphor ZnSAg⁺; using a green phosphor ZnS:Cu⁺, Al⁺ where Cu and Al are used together; and using a red phosphor ZnS:Cu⁺, Mn⁺, where Cu and Mn are used together. The green phosphor in the formulation of Jermann et. al. may alternatively be SrAl₂O₄:Eu²⁺. See for example phosphors sold and marketed by Honeywell Specialty Chemicals Seelze GmbH which are generally excited by UV light in between 340 nm through 390 nm.

### Fluorescent and Phosphorescent Down Conversion Materials Specific for Light-Emitting Diodes

As noted earlier, the major challenge for ceramic phosphors utilized in light-emitting diode driven down conversion is that the light emission—a primary radiation—from the diode die are narrow, usually singular in range and of wavelengths of considerably lower energy than that absorbed by CRT and fluorescent lamp phosphors; the narrow emission profile from the p-n junction has poor overlap with the excitation spectra of the ceramic phosphors required to effect down conversion. Hence, materials different than that used in fluorescent tube lighting is required to perfect light-emitting diode driven down-conversion.

Fluorescence and materials that fluoresce involves light emission without a change in spin multiplicity. Phosphorescence and materials that phosphoresce involves light emission with a change in multiplicity. Materials that fluoresce are called fluorescers or fluorophores; materials that phosphoresce are often called phosphors or more specifically, if the term phosphor is unclear, phosphorescent phosphors. [As used herein, the term phosphor does not imply a change in spin multiplicity as in the lighting industry, phosphors are used synonymously with fluorescent materials as well as phosphorescent materials.] Because state to state transitions that require a change in spin multiplicity have a slower rate of transition, phosphorescent phosphors (e.g., triplet states that phosphoresce) typically have long excited state lifetimes. State to state transitions that do not require a change in spin multiplicity have a faster rate of transition; hence fluorophore typically have short, excited state lifetimes. The longer the lifetime, the more probably an alternative event such as quenching may occur. Phosphorescence therefore is not expected to be a beneficial phenomenon in systems where quenchers, such as water and or oxygen may exist, unless there is a mechanism for speeding the rate of change in spin multiplicity. Spin-orbit coupling is such a mechanism and heavy elements, such as those elements found in ceramics, have spin-orbit coupling of sizable magnitude. In these cases, ceramic phosphors may have a reasonably short, excited state lifetime as the rate of the radiative transition is enhanced through spin-orbit coupling. As a result, in certain environments, phosphorescent phosphors may be as efficient as fluorophors in the yield of luminescence from their respective excited states.

Nevertheless, it is desirable to have solid-state lighting devices where the performance of the down conversion system is not ruled by the lifetime of the selected luminophor for reasons already cited. Other than enhancing the rate of luminescence, the only other means of accomplishing the desirability mentioned in the preceding sentence is to make competing processes less likely, a formidable chore, nevertheless one that this present invention addresses.

It has been reported that a near-UV light-emitting diode could be used as a primary light source to irradiate films of red, green, and blue powdered “fluors” dispersed on the surface of a glass slide. (Sato, et. al. Japanese Journal of Applied Physics, Vol. 35 (1996) L838-L839; received 27 Mar. 1996; accepted 16 May 1996; published 1 Jul. 1996. Title of reference: “Full-Color Fluorescent Display Devices Using a Near-UV Light-Emitting Diode.”] With said configuration, the “fluors” so irradiated produce the principal colors of red, green, or blue and “white color” is easily obtained. The fluorophores used by Sato, et. al., are inorganic materials ZnS:Ag (blue), ZnS:Cu, Al (green) and ZnCdS:Ag (red) and the fluors were dispersed in aqueous solutions of polyvinyl alcohol and spin-coated onto the glass slides. The glass slides are used to simulate a display and to prove that near-UV light-emitting diodes could be used to power said display through radiative energy transfer. More recently, it has been taught that a stable white light light-emitting diode “with InGaN-LED that generates a blue color of 410 nm-460 nm to excite the ZnSSe fluorescent screen by the blue so as to generate a yellow color, and then the blue and the yellow generated are synthesized into a white color.” (Fujiwara, Japanese Patent Application JP2003347588; filed 2003 Dec. 5; claims priority date of 2002 May 28)

In an excellent series of work but nevertheless one filed after the invention of Baretz et. al. [2003], Reeh, et. al. disclosed a light-radiating semiconductor component which has a radiation-emitting semiconductor body and a luminescence conversion element. (Reeh, et. al.; U.S. Pat. No. 6,576,930 (assignee: Osram; filed on 7 Dec. 2000; claims priority date of Jun. 26, 1996[DE] 196 25 622 and Sep. 20, 1996[DE] 196 38 667; issued on 10 Jun. 2003) The invention of Reeh, et. al., appears to have been the work of researchers from Fraunhofer Institute for Applied Solid State Physics and which, by virtue of the patent filing, and evidenced in subsequent documentation filed with the United States International Trade Commission, assigned to Osram Opto Semiconductors, a unit of Osram, itself a subsidiary of Siemens. The semiconductor body emits radiation in the ultraviolet, blue and/or green spectral region and the luminescence conversion element converts a portion of the radiation into radiation of a longer wavelength. This makes it possible to produce light emitting diodes which radiate polychromatic light, which appears as white light, with only a single light-emitting semiconductor body. The difference between achromatic light and polychromatic light is not addressed in the specification of Reeh et. al.

A luminescence conversion dye is YAG:Ce³⁺, a cerium doped yttrium aluminum garnet. [A substitute ceramic phosphor that may be used—not discussed by Reeh et. al.—as an alternative is Y₃(Al₁₋ₛGaₛ)₅O₁₂: YAG:Ce³⁺:XBaAl₂O₄ where s=0 and x=1.0 and where said phosphor may show considerable barium composition in the elemental spectral patterns.]

The invention of Reeh et. al. has the undesirable specification, claim and element that the white light so produced, achromatic light without a hue, contains a portion of the original radiation in the ultraviolet, if the original semiconductor body emits radiation in the ultraviolet. It is an undesirable element in that the ultraviolet light emanating from the semiconductor light may be a safety hazard to the observers of the white light. It would be desirable to not require the light so produced to contain a portion of the original radiation; my present invention has that desirable feature as will be more fully described herein. As evident within Claim 4 of U.S. Pat. No. 6,576,930 by Reeh et. al, the invention is based on “a luminescence conversion element with at least one luminescent material, said luminescence conversion element being deposited on said semiconductor body, said luminescence conversion element converting a radiation originating in the first wavelength range into radiation of a second wavelength range different from the first wavelength range, such that the semiconductor component emits polychromatic visible light comprising radiation of the first wavelength range and radiation of the second wavelength range.” For a white light powered by a blue light emitting diode die, the invention requires “radiation of the first wavelength range” and “radiation of the second wavelength range” where the latter requires excitation into the excited state by radiative energy transfer from the former and where the luminescence conversion element is deposited on the semiconductor body. It is generally not appreciated and recognized by those with skills in the art that for achromatic light powered by a blue light-emitting diode die as opposed to polychromatic light powered by the same blue light-emitting diode die, the blue component needs to be changed so as to parallel the photopic response in the blue region as closely as possible; therefore, it is desirable that the radiation of the first wavelength range be altered such that the blue component be distorted not only by radiative energy transfer (which only alters the quantity of the radiation of the first wavelength range) but also by spectral filtration (such that the radiation of the first wavelength range is in fact not at all part of the product's emission profile). The utilization of enclosures within enclosures makes spectral filtration rather easy to cause as there are a wide range of materials available that are suitable to make enclosures.

My present invention also does not require the luminescence conversion element to be deposited on the semiconductor body and the luminescence body is not deposited on the semiconductor body as will be claimed specifically. It is also the case that whereas the claim of Reeh et. al., is contingent on “semiconductor component emits polychromatic radiation”, an extremely unlikely event in that semiconductor components emit narrow band chromatic radiation all would agree, in the case of my invention the semiconductor body may emit monochromatic and or a mono-colored radiation although the device of my invention that includes a semiconductor component may emit chromatic or achromatic radiation subsequently thereto. In certain implementations, where the concentration of a luminescent element is high enough, the radiation of the first wavelength cannot be delivered in an unaltered state as by the definition of radiative energy transfer, the photons of the first radiative range are absorbed by a luminescent element and not every wavelength is absorbed with equal extinction coefficient. Hence the specification of Reeh et. al., is difficult to practice since radiative energy transfer, absorbs—does not transmit—photons of a primary radiation range thereby altering quantitatively and qualitatively a primary radiation range.

As noted, before, the invention of Reeh et. al., claiming a priority date after the filing of Baretz et. al. [2003] uses the term luminescence conversion to refer to using phosphors to emit chromatic and achromatic light. Luminescence conversion is detailed in various reports emanating from the Fraunhofer Institute. For example, one report in 1997 states “Single white LEDs were not feasible to date, as they emit monochromatic light only. The mixture of colors making up white light was only possible with a combination of three different diodes. Researchers at the Fraunhofer-Institute für Angewandte Festkörperphysik IAF (Fraunhofer Institute for Applied Solid State Physics) have achieved a breakthrough. The innovative idea was the generation of white light by luminescence conversion. Blue emitting diodes based on gallium nitride were combined with luminescent dyes giving bright light emission at changed wavelengths. The resulting mixture of colors is visible as white light. Furthermore, these LUCOLEDs—luminescence conversion LEDs—allow light emission in a wide color range, depending on the emission of the dyes used. In addition to white light, arbitrary color tones of the spectrum are possible, e.g., purple.” [January 1997 “Research News” published by Fraunhofer-Gesellschaft.]

In a press release on Apr. 23, 1999, the same Fraunhofer-Gesellschaft reported “Although red, green, and yellowish-green LEDs have been on the market for quite a long time, white light-emitting diodes could only be produced by combining different colored LEDs. But two years ago, research scientists at the Fraunhofer Institute for Applied Solid State Physics (IAF) in Freiburg solved the problem—concurrently with Japanese scientists—by developing white light-emitting luminescence conversion LEDs. Pumped by a primary light source, luminescent materials like dyes or phosphors emit light at longer wavelengths by luminescence down-conversion. To develop white light emitting diodes, the IAF team combined blue light-emitting LEDs based on gallium nitride with organic or inorganic luminescent materials emitting in the yellow spectral range. Mixing the blue radiation of the LED with the complementary yellow light of the luminescent material results in a white light-emitting LED. By varying the concentration of the dye, the hue can be changed easily. Thus, small LEDs open completely new opportunities in lighting design. The process for manufacturing white LEDs is simple: Yellow-emitting luminescent materials are mixed with epoxy resin and applied to the blue-emitting diode.

### The Yellow-Emitting Ceramic Phosphor YAG:Ce³-Doped Yttrium Aluminum Garnet and The Formation of White Light from Blue and Complementary Yellow Down Conversion

Nichia Corporation, as noted earlier, through the efforts of Nakamura and his colleagues, self-claim that they started developing blue light-emitting diodes in 1989 and built up the technology for industrialization of GaN-based Blue light-emitting diodes in 1991. The self-acclamation proffered by Nichia continues with the comments “Nichia Corporation succeeded in the commercial production of high-brightness Blue LEDs in November 1993. Further, by applying its expertise as a phosphor manufacturer, and by combining YAG (Yttrium Aluminum Garnet) phosphors, specifically Y₃Al₅O₁₂:Ce³⁺ with Blue LEDs and, according to their own acclaim, Nichia Corporation started commercial production of White LEDs in 1996 for the first time in the world.” (“A New Phosphor for Frying-Spot Cathode-Ray Tubes for Color Television: Yellow-Emitting Y₃Al₅O₁₂: YAG:Ce³⁺”, G. Glasse et al., Applied Physics Letters, vol. 11, No. 2, pp. 53-54 (1967) Nichia's research and commercial efforts on white light light-emitting diodes are documented and detailed: the self-asserted operable United States patent is of inventor Yoshinori Shimizu. (Demand for Jury Trial: Nichia vs. Sharper Image; United States District Court Northern District of California Case Number: C04-1360. Also, “Report on the filing or determination of an action regarding a patent or trademark”; TO: Commissioner of Patents and Trademarks; Washington, D.C. 20231; In Compliance with 35 § 290 and/or 15 U.S.C. § 1116 you are hereby advised that a court action has been filed in the U.S. District Court Northern District of California; Y. Shimizu, U.S. Pat. No. 5,998,925, issue date Dec. 7, 1999) Additional relevant information on U.S. Pat. No. 5,998,925 to aid the review of the related prior art is: assignee: Nichia; filed on Jul. 29, 1997; claims priority date of Jul. 29, 1996 [JP] 8-198585; Sep. 17, 1996 [JP] 8-244339; Sep. 18, 1996 [JP] 8-245381; Dec. 27, 1996 [JP] 8-359004; Mar. 31, 1997 [JP] 9-081010. Shimizu, et. al. (1999) claim a light emitting device, comprising a light emitting component and a phosphor capable of absorbing a part of light emitted by the light emitting component and emitting light of wavelength different from that of the absorbed light; wherein said light emitting component comprises a nitride compound semiconductor represented by the formula: InGaAlN and said phosphor contains a garnet fluorescent material comprising 1) at least one element selected from the group consisting of Y, Lu, Se, La, Gd and Sm, and 2) at least one element selected from the group consisting of Al, Ga and In, and being activated with cerium.

Shimizu argue that the principal purpose of their invention is to overcome either: for inorganic luminophors, degradation of the phosphor due to precipitation of the metal component or a change in properties of the metal component leads to discoloration; in the case of an organic luminophor, coloration occurs due to breakage of the double bond. It was supplementarily advanced that degradation may occur from localized heating and or moisture. There has been a long unmet need to overcome these deficiencies for a wide class of luminophors. Further, in the case of an organic luminophor that is charged (ionic), the localized electric field may cause electrophoresis which may cause an undesired change in color tone. Shimizu focused on selecting a very narrow class of luminophors that may overcome the challenges and highlighted two: cerium doped yttrium aluminum garnet and cerium doped gadolinium indium garnet. Shimizu also argues that it is preferable for the light-emitting diode to emit blue light, as opposed to ultraviolet (UV) light, since the latter will degrade the resin. (Shimizu, et. al.; 1999) However, in the absence of the degradation of the resin, one of ordinary skill in the art will recognize that it is preferable in at least some exemplary embodiments to have the light-emitting diode emit UV light as opposed to blue light since more luminophors absorb light in the UV than they do in the blue. However, the most important reason not to prefer blue to UV light for the light-emitting diode is that the blue light from the light-emitting diode die will inevitably contribute substantively to the chromaticity of the intended achromatic light therefore making the light not achromatic. More importantly, even if the light appears to be achromatic at zero time, it is inevitably the case, as the device ages, that the blue component will become more substantial as it is a primary radiation in the device of Shimizu. As noted earlier, high photon fluxes of blue light will inevitably increase blue component to the polychromatic irradiation due to saturation of the down-conversion process. Therefore, it is preferred in at least some exemplary embodiments, if achromatic light is to be generated, at zero time and throughout the useful light of the device, that a non-visible component be at the very least an element of a primary radiation.

This invention of Shimizu as issued in the patent is in some degree restricted to GaN semiconductors and claims garnet fluorescent materials. [See for example, Schlotter, P. et al., “Luminescence conversion of blue light emitting diodes”, Applied Physics A, Springer Verlag (publ.), April 1997, vol. 4, pp. 417-418.] A later issued invention of similar heritage discloses a light emitting device comprising a component capable of emitting blue light, and an opal coating member covering said light emitting component and containing a yellow phosphor capable of absorbing a part of blue light emitted by said light emitting component and emitting light of wavelength different from that of the absorbed light. (Shimizu, et. al., U.S. Pat. No. 6,069,440 (filed on Apr. 28, 1999; claims priority date of Jul. 29, 1996 [JP] 8-198585; Sep. 17, 1996 [JP] 8-244339; Sep. 18, 1996 [JP] 8-245381; Dec. 27, 1996 [JP] 8359004; Mar. 31, 1997 [JP] 9-081010) issued on 30 Mar. 2000) The opal coating bears no protecting and enhancing function.

Finally, as discussed in chapter 10.4 of “The Blue Laser Diode” by S. Nakamura et al., pages 216-221 (Springer 1997), incorporated herein by reference, white light light-emitting diodes can be fabricated by forming a ceramic phosphor layer on the output surface of a blue emitting semiconductor light-emitting diode. The blue light-emitting diode is an InGaN single quantum well light-emitting diode, and the phosphor is a cerium doped yttrium aluminum garnet Y₃Al₅O₁₂:Ce³⁺ (“YAG:Ce³⁺”). The blue light emitted by the light-emitting diode excites the phosphor, causing it to emit yellow light. The blue light emitted by the light-emitting diode is transmitted through the phosphor and is mixed with the yellow light emitted by the phosphor. The viewer perceives the mixture of blue and yellow light as white light. This invention is because yellow light is a secondary color, a combination of red and green light and when red and green and blue are combined, as taught by Baretz et. al. [2003] white light is obtained. [Interestingly, if a yellow complementary color mixed with blue can provide a white light, one would argue that a blue green (also called cyan) complementary color mixed with red can provide a white light. See Mueller-Mach et. al. in JP2002016295, EP1150361, U.S. Pat. No. 6,603,258]

Osram's research and commercial efforts on white light light-emitting diodes are documented and detailed: the self-asserted operable United States patents which have advanced the art for solid-state white light include U.S. Pat. No. 6,613,247 “Wavelength-converting casting composition and white light-emitting semiconductor component”, U.S. Pat. No. 6,592,780 “Wavelength-converting casting composition and white light-emitting semiconductor component”, U.S. Pat. No. 6,576,930 “Light-radiating semiconductor component with a luminescence conversion element”, U.S. Pat. No. 6,066,861 “Wavelength-converting casting composition and its use”, U.S. Pat. No. 6,245,259 child to U.S. Pat. Nos. 6,066,861, 6,277,301, a continuation of U.S. Pat. Nos. 6,066,861, 6,592,780 a continuation of U.S. Pat. Nos. 6,245,259, and 6,613,247 “Wavelength-Converting Casting Composition and White Light-Emitting Semiconductor Component”. (Documents associated with Complaint of Osram GmbH and Osram Opto Semiconductors GmbH under Section 337 of the Tariff Act of 1930, as Amended; In the Matter of Certain Light Emitting Diodes and Products Containing the Same; United States International Trade Commission; Investigation Number 337-TA-512, Washington, D.C. 20436) The U.S. Pat. No. 6,576,930 does not define the term “white light” but does specify “The hue (color locus in the CIE chromaticity diagram) of the white light . . . .” Since achromatic light has no hue, the patent does not teach to achromatic light. The same patent at times refers to white light as polychromatic light and as white light of mixed color.

U.S. Pat. No. 6,066,861 speaks to a composition containing pigments that convert light of one wavelength (e.g., blue, green, or ultraviolet light) to light of another wavelength (e.g., yellow light). They also relate to light-emitting semiconductor components containing this composition. The principal application—the conversion of blue light to yellow light in white light-emitting diodes—is not claimed. The invention is specific to an “epoxy casting resin”, the term “casting” is not defined. The child refers to phosphors containing cerium ion. The continuation refers to a composition that contains epoxy casting resin and pigments having phosphors selected from the group consisting of YAG: Ce³⁺-doped phosphors; garnets doped with rare earths; thiogallates doped with rare earths; aluminates doped with rare earths; and orthosilicates doped with rare earths. It is generally understood, in the context of luminophors, that pigments are inorganic luminescent materials that have color prior to photo-activation and that dyes are organic luminescent materials that have color prior to photo-activation. When using epoxy casting resin, many approaches have been used to deposit phosphor onto the light-emitting diode, such as, for example, a time-pressure technique and a roller coating technique. Each of these approaches and many others are designed to fill up a reflector cup of the light-emitting diode with phosphor. However, the volumetric accuracy is typically unsatisfactory due in part to the settling of the phosphor within the solution. Another disadvantage is a result of the process of mixing phosphor compounds with an optically clear substance, such as, for example a clear epoxy resin. It is difficult to achieve and duplicate a uniform mixture of the phosphor compound particles in the optically clear substance. This difficulty results in a less than desirable uniformity of the light emission from the lighting device.

The blue light-emitting diode-YAG: Ce³⁺ phosphor white light illumination system suffers from the following additional disadvantages. The blue light-emitting diode, YAG:Ce³⁺phosphor system, produces white light with a high color temperature ranging from 6000 K to 8000 K, which is comparable to sunlight, and a typical color rendering index (CRI) of about 70 to 75. While the blue light-emitting diode YAG:Ce³⁺ phosphor illumination system, with a relatively high color temperature and a relatively low CRI, is acceptable to customers in the far east lighting markets, the customers in the North American markets generally prefer an illumination system with a lower color temperature, while the customers European markets generally prefer an illumination system with a high CRI. For example, North American customers generally prefer systems with color temperatures between 3000 K and 4100 K, while European customers generally prefer systems with a CRI above 90. It is desirable from the perspective of general illumination for solid-state lights to have chromatic light with a hue; likewise, for many other applications—for example as a light source for scanning or as a backlight for displays—it is desirable to produce white light—that is achromatic light without a hue.

Regardless of the adjustment of additional phosphors including red emission phosphors to adjust the color temperature of blue light emitting diodes with yellow phosphor, this system has one fundamental and significant problem: the number of blue photons emanating there from is far greater than the relative number of blue photons in the photopic curve. In other words, the photons being generated are not useful in terms of luminous intensity; this means that the light is not productive for general illumination. The luminous intensity could increase dramatically if the blue photons were substantively adjusted to green photons (near the photopic maximum); heretofore, it has not been successful to dramatically reduce the blue component and to generate a spectral light mimicking the photopic curve using a blue light-emitting diode die and a complementary yellow phosphor. This is a fundamental problem that will always impact the magnitude of brilliance of white light-emitting diodes based on blue die and yellow complementary phosphors. Solid-state lighting based on combinations of red, green, and blue phosphors do not, in theory, have this fundamental challenge, presuming of course that non-radiative energy transfer between the phosphors does not force the spectral emission bathochromic to the photopic curve. Interest in creating an achromatic light using a UV-emitting light-emitting diode to pump a trio of RGB -emitting of phosphors, UV light is adsorbed by the phosphors, and the mixed RGB output appears achromatic much the same as a mixed light-emitting diode array of red, green, and blue light-emitting diode-dice. In contrast let us note, “The quantum deficit between the UV pump and the phosphors, especially the low energy red phosphor, dissipates significant energy and makes this approach inherently less efficient than either the red, green and blue light-emitting diode-dice or the phosphor conversion using a blue light-emitting diode and yellow phosphor emitter schemes for generating white light.” (D. A. Stiegerwald, et. al., “Illumination with Solid State Lighting Technology”, IEEE JOURNAL ON SELECTED TOPICS IN QUANTUM ELECTRONICS, VOL. 8, NO. 2, MARCH/APRIL 2002) Notwithstanding this observation which relates to conversion of electrical energy to photonic energy, we add that the conservation of energy does not preclude one quantum of primary radiation to generate only one quantum of secondary radiation.

Other difficulties attesting to the general undesirability of using blue light-emitting diode-YAG:Ce³⁺ phosphor illumination—in the conventional construction at least—is articulated by Doxsee, Daniel Darcy; et al. within United States Patent Application 20040135154 (Jul. 15, 2004). Therein they state “In addition to this somewhat limited emission intensity, the color output of such an LED-phosphor system varies greatly due to frequent, unavoidable routine deviations from desired parameters (i.e., manufacturing systemic errors) during the production of the light. For example, the color output of the finished device is extremely sensitive to the thickness of the phosphor layer covering the LED. If the phosphor is too thin, then more than a desired amount of the blue light emitted by the LED will penetrate through the phosphor and the combined phosphor LED output will appear bluish. In contrast, if the phosphor layer is too thick, then less than a desired amount of the blue LED light will penetrate through the phosphor layer. In this case, the combined phosphor-LED output will appear yellowish. Therefore, the thickness of the phosphor layer is an important variable affecting the color output of a blue LED based system. Unfortunately, the thickness of the phosphor layer is difficult to control during large scale production of LED-phosphor lamp systems, and the variations in phosphor thickness often result in relatively poor lamp to lamp color control. In addition, lamp to lamp variations occur due to the varying of the optical power from chip to chip.” The solution proposed by Doxsee et. al. (2004) is replacement of blue LED die with UV LED die (“emitting in the 380-420” nm range according to the definition of Doxsee et. al. of a UV emitting diode die) and the utilization of UV excited phosphor blends to generate white light: BaMg₂Al₁₆O₂₇:Eu²⁺ with a second phosphor where the second phosphor is a terbium aluminum garnet. Note that the first phosphor uses europium instead of the cerium in YAG:Ce³⁺ and that the yttrium aluminum garnet—an yttrium aluminum oxide in a garnet crystal structure—is replaced with a barium magnesium aluminum oxide. The second phosphor claimed by Doxsee et. al. (2004) is Tb₃Al_{4.9}O₁₂: YAG:Ce³⁺ where the cerium complexes not with YAG (an yttrium aluminum oxide in a garnet crystal structure) but with terbium aluminum oxide in a garnet structure. Doxsee et. al. sequester the phosphors claimed either as a layer on the LED die itself [The phosphor, radiationally coupled to the LED chip, is deposited on the LED by any appropriate method . . . (for example, a water based suspension of the phosphor(s) can be formed, and applied as a phosphor layer to the LED surface by coating and drying the phosphor suspension over the LED chip)] or where the phosphor powder may be interspersed within a single region of the encapsulant material or throughout the entire volume of the encapsulant material.

Doxsee et. al. teach the preparation of terbium aluminum garnet complexed with cerium, for example, with the following specifications: The TAG phosphor for use in the phosphor blend of the present invention may be produced by a method comprising the steps of: (1) providing stoichiometric amounts of oxygen containing compounds of terbium; oxygen-containing compounds of at least one rare-earth metal for example Ce³⁺; and oxygen-containing compounds of at least one member selected from the group consisting of for example Al; (2) mixing together the oxygen containing compounds to form a mixture; and (3) firing the mixture in a reducing atmosphere at a temperature and for a time sufficient to convert the mixture to a rare earth-activated terbium-containing garnet phosphor. Doxsee et. al. teach that the reducing atmosphere may optionally be diluted with an inert gas, such as nitrogen, helium, neon, argon, krypton, xenon; after the preparation of the TAG phosphor, these inert gases are not utilized by Doxsee et. al.

The challenge in utilizing ceramic phosphors for the generation of achromatic white light (light without hue) is formidable at best and most difficult and expensive at worst and has led to extremely complicated mixtures of ceramic phosphors to effect achromatic white light. For example, in U.S. Pat. No. 6,084,250, Justel, et. al. claims a white light emitting diode comprising a UV-diode with a primary emission of 300 nm through 370 nm and a phosphor layer including a combination of a blue emitting phosphor having an emission band, with 430 nm through 490 nm, a green emitting phosphor having an emission band, with 520 nm through 570 nm and a red emitting phosphor having an emission band, with 590 nm through 630 nm, emits high quality white light. The color-rendering index CRI is approximately 90 at a color temperature of 4000 K. The color rendition depends only on the composition of the three phosphors, not on the relation between converted and non-converted light, and hence can be readily controlled and regulated.

Even when a used single ceramic phosphor is available, ultimate performance is compromised. Shimizu et al., describes various phosphor LEDs that generate white output light having a color temperature somewhere between 5,000 to 6,000 Kelvin. (Shimizu, et. al.; PCT Application number WO1997JP02610 Jul. 29, 1997, published as WO 98/05078: “Light Emitting Device and Display Device”) In one embodiment, the light-emitting diode of Shimizu et al., utilizes an yttrium aluminum garnet (YAG) phosphor to convert some of the primary light into secondary light having a peak wavelength of about 580 nm. The spectral distribution in this embodiment has two emissions peaks; one peak is predominately caused by the primary light emitted from the GaN die of the Shimizu et al. and the other peak is predominately caused by the secondary light emitted from an yttrium aluminum garnet phosphor.

A concern with the Shimizu et al. light-emitting diode is that the “white” output light has an undesirable color balance for a true color rendition. The output light of the Shimizu et al. LED is adequate for applications in which simple illumination is required. However, for applications in which a high color rendition is desired, the output light is deficient in the red region of the visible light spectrum (647-700 nm range).

As an example of another disclosure where an improved phosphor is claimed, see for example, in the issued U.S. Pat. No. 6,680,569, where Mueller-Mach, et al. discloses a light emitting device which includes a light source that emits first light in response to an electrical signal, and a fluorescent layer positioned over the light source. The fluorescent layer includes a first fluorescent material which radiates second light and a second fluorescent material—which must “comprise” a nitrido-silicate—which radiates third light.

The invention of Mueller-Mach, et. al. discloses the use of an yttrium aluminum garnet (YAG) phosphor in general or a cerium-activated yttrium aluminum garnet, more specifically, as the first fluorescent material and comprises a nitride-silicate which radiates red light. Hence, whereas the disclosure of Shimizu et. al. uses a single phosphor to emit polychromatic light and a primary radiation of the semiconductor light emitting diode die, the disclosure of Mueller-Mach, et. al. uses two fluorescent materials to emit polychromatic light with a greater red contribution than that otherwise available from an yttrium aluminum garnet phosphor as a single phosphor, by itself. The mechanism by which the nitride-silicate which radiates red light is brought to its excited state is not articulated. Further, there is a requirement that a primary radiation “emits first light” and that this occurs as a response to an electrical signal. This wording would seem to preclude non-radiative energy transfer between the p-n junction and the first fluorescent material.

As one skilled in the art would appreciate, the discovery of new inorganic materials for specific luminescent applications—especially those amenable to their use in the manufacture of consistent and high-quality light emitting diode lamps—is a challenge. The preparation and discovery of new solid state inorganic compounds is limited by the lack of a general framework that provides broad based predictive synthetic strategies and theories. Due to the lack of predictive tools available to the solid-state inorganic chemist, the preparation of new phosphors has generally been restricted to serial synthesis and analysis techniques. As such, serial synthesis and testing of powder phosphors has been the discovery and development paradigm for the last one hundred and fifty years. “Such techniques have resulted in the discovery of less than one hundred phosphors suitable for commercial use” (see, Vecht, SID Seminar Lecture Notes, 2, F-2/3 (1996); Ropp, The Chemistry of Artificial Lighting Devices, Elsevier, Amsterdam, pp. 414-656 (1993)). At the same time, efforts to predict basic solid-state properties from theory, including intrinsic or extrinsic luminescent efficiency, have been unsuccessful (see, DiSalvo, Science, 247:649 (1990)). Using traditional methods, fewer than 1% of all possible ternary compounds and less than 0.01% of all possible quaternary compounds have been synthesized heretofore (see, Rodgers, et al., Mat. Res. Bull., 18:27 (1993)). Combinatorial techniques have been helpful (see U.S. Pat. No. 6,315,923 “Storage phosphors”; U.S. Pat. No. 6,203,726 “Phosphor Materials” and U.S. Pat. No. 6,013,199 “Phosphor materials”) but the challenge and cost associated with complex combinatorial ceramics is formidable.

In contrast, organic compositions of matter are readily produced and conceived and the art of conjugation in molecular design is appreciated and easily practiced. Organic luminophors in general and organic fluorescent and organic phosphorescent materials have extremely broad emission profiles, are relatively inexpensive to manufacture and a well-accepted paradigm exists for the organic chemist skilled in the art to molecularly design emission profiles of useful characteristics. They also have high quantum yields of luminescence: the quantum efficiency of the organic Lumogen dyes in solution is >0.98 and no loss in efficiency was observed with a polymethylmethacrylate (PMMA) host whereas the quantum yield of the ceramic phosphor Y(Gd)AG:Ce³⁺ doped was measured relative to a known standard and found to be 0.86. (A. R. Duggal, J. J. Shiang, C. M. Heller, and D. F. Foust, “Illumination Quality OLEDs for Lighting” Technical Information Series GE Global Research Technical Report 2002GRC189, August 2002) Notwithstanding the appeal of organic luminophors, there have been only a few examples, other than that taught by Baretz et. al. [2003] of organic fluorescers being used in Down-Conversion in solid-state lighting with a p-n junction.

In a series of experiments imitating down-conversion, it has been reported that thin films of dilute organic dyes in amorphous inorganic matrix materials may be promising materials for optoelectronic devices based on luminescence conversion, because the separation and immobilization of the dye molecules by the matrix reduces non-radiative relaxation processes of excited molecules in bulk dyes. High quantum efficiencies were demonstrated in such diluted systems realized by sol-gel technique or by incorporation in organic matrices. However, the room temperature photo-stability in these systems is not suitable for many applications based on the luminescence. As an improvement, it was subsequently found that an organic-inorganic system prepared by co-evaporation of the components in high vacuum which allows (i) to use very stable dye molecules independent of their solubility in the matrix, (ii) to use different substrates and (iii) which results in homogeneous dye molecule distribution. In dependence on dye concentration, absorption and luminescence spectra change dramatically due to the changes in intermolecular distance and surrounding. For the lower concentrations, both absorption and luminescence spectra can be described as monomer transitions with vibrational progression and broadened peak widths. In the system perylene-3,4,9,10-tetracarboxylic-dianhydride in silicon dioxide (silica) the maximum photoluminescence quantum efficiency is obtained at a concentration of about 0.1 volume % as expected from energy transfer processes between the molecules, which were analyzed by luminescence anisotropy measurements. (H. Froeb, M. Kurpiers, K. Leo “Highly Efficient and Photostable Organic Dyes in Inorganic Matrices: A Novel Path to Luminescence Conversion Devices.”, Institut fur Angewandte Photophysik, Technische Universitaet Dresden, Dresden, GERMANY. Proceedings published as Volume 560 of the Materials Research Society Symposium Proceedings Series, Apr. 7, 1999.)

The important observation is that even when the organic luminophor has extremely high quantum yields of luminescence (e.g., 98% for Lumogen organic luminophors, nearly quantitative for the bis(phenyl-ethynyl) anthracenes), under high photon flux alternative mechanisms of deactivation ultimately lead to a measurable altering of the initial structures. In many cases, the “leakage” results from bimolecular events—aggregation; excimer formation is energetically favorable but leads to alternative reactions, nonradiative decay and generally lower yields of radiative decay (luminescence). Agglomeration also occurs in ceramic phosphors and is also thought to be a reason for long term luminophor instability; those ceramic particles are not soluble in epoxy matrices enhances agglomeration. In any case, sequestering an organic luminophor in a silica matrix is like sequestering the luminescent Ce³⁺ion within a garnet structure. Note that the vacuum was used to disperse the dyes and that once dispersed the vacuum was released, all prior to radiation.

Hide, et. al. reported a hybrid Light-Emitting Diode for white lighting and for full-color applications [Hide, F.; DenBaars, S. P.; and Heeger, A. J.; U.S. Pat. No. 5,966,393, filed on 4 Feb. 1997, priority date of 13 Dec. 1996 from provisional application No. 60/032,849; issued 12 Oct. 1999]. Hide, et. al., claim a photoluminescent polymer—a photoluminescent conjugated semiconducting polymer—which down-converts light from a solid-state inorganic light-emitter.

A similar disclosure was reported by Zhang, C.; et. al. entitled “Gallium nitride/conjugated polymer hybrid light emitting diodes: Performance and lifetime.” [Chi Zhang and Alan J. Heeger, Journal of Applied Physics—Aug. 1, 1998; Volume 84, Issue 3, pp. 1579-1582; Received 12 Jan. 1998; accepted 28 Apr. 1998] In this disclosure a “pure white” light emission from GaN/conjugated polymer hybrid light emitting diodes (LEDs) using a single layer of conjugated polymer was reported. When the conjugated polymer is properly encapsulated, the report states that the hybrid LEDs can operate at least 5000 h, with decay in output luminosity comparable to that of commercial blue GaN lamps. By using different conjugated polymers, emission with a full range of colors is demonstrated with the hybrid LED. [Also “White light from InGaN/conjugated polymer hybrid light-emitting diodes”, F Hide, P Kozodoy, S P Denbaars, A J Heeger; Applied Physics Letters 70(20), 2664 (1997)]

Bojarczuk et. al., disclosed a hybrid organic-inorganic semiconductor-based light-emitting diode [Bojarczuk, Jr.; Nestor A.; Guha; Supratik; Haight; Richard Alan; filed Mar. 5, 1997; issued Apr. 20, 1999, U.S. Pat. No. 5,895,932; priority date of Jan. 24, 1997, from Ser. No. 08/788,509]. This invention provides a novel hybrid organic-inorganic semiconductor light emitting diode. The device consists of an electroluminescent layer and a photoluminescent layer. The electroluminescent layer is an inorganic GaN light emitting diode structure that is electroluminescent in the blue or ultraviolet (UV) region of the electromagnetic spectrum when the device is operated. The photoluminescent layer is a photoluminescent organic thin film such as tris-(8-hydroxyquinoline) Al, Alq₃, deposited onto the GaN light-emitting diode and which has high photoluminescence efficiency. The UV emission from the electroluminescent region excites the Alq₃ which yields luminance in the green. Such a photoconversion results in a light emitting diode that operates in the green (in the visible range). Other colors such as blue or red may be obtained by appropriately doping the Alq₃. Furthermore, other luminescent organics in addition to Alq₃ may be used to directly convert the UV or blue to other wavelengths of interest. The invention provides the benefits of simplicity and ease of fabrication, since a complete redesign of the structure is not necessary to change emission wavelength, and the possibility for making displays by spatially varying the deposition of the emissive layer. This invention claims a hybrid organic-inorganic semiconductor light emitting diode comprising, in sequence, a substrate, a n-doped semiconductor layer, a light emission region where electrons and holes recombine to produce light, a p-doped semiconductor layer, and a layer of an organic photoluminescent material which comprises a fluorescent compound or combination of compounds which absorb light at the wavelength emitted by said light emission region and re-emit light at a different wavelength. This invention is limited to “a layer of an organic photoluminescent material.”

In U.S. Pat. No. 5,898,185, Bojarczuk, Jr., et al. (1999a) claim a hybrid organic-inorganic semiconductor light emitting diode consisting of a layer of a light emitting, inorganic electroluminescent material and an overlying layer of an organic photoluminescent material or a hybrid organic-inorganic semiconductor light emitting diode consisting of, in sequence, a substrate, an n-doped semiconductor layer, a light emission region where electrons and holes recombine to produce light, and a p-doped semiconductor layer and further including a layer of an organic photoluminescent material. [Bojarczuk, Jr.; Nestor A.; Guha; Supratik; Haight; Richard Alan; issued Apr. 27, 1999; filed 5 Mar. 1997; a continuation-in-part of application Ser. No. 08/788,509, filed Jan. 24, 1997.] This invention is limited to a “layer of an organic photoluminescent material.”

Guha et. al. disclosed a hybrid organic-inorganic semiconductor-based light-emitting diode [received 7 Mar. 1997, accepted 11 Jul. 1997, published 15 Oct. 1997; Journal of Applied Physics, Volume 82, Issue 8, pp 4126-4128] whereby a GaN-based light emitting diode emits shorter wavelength light and an organic thin-film part that absorbs the electro-luminescence (a primary radiation) and fluoresces at a longer wavelength resulting in color conversion. (See also “Efficient white and red-light emission from GaN/tris-(8-hydroxyquinolato) aluminum/platinum (II) meso-tetrakis(penta-fluorophenyl) porphyrin hybrid light-emitting diodes”, Hai-Feng Xiang, SzeChit Yu, Chi-Ming Che, and P. T. Lai, Applied Physics Letters Vol 83(8) pp. 1518-1520. Aug. 25, 2003.)

Notwithstanding the progress made in using organic fluorescers or ceramic phosphors as down-conversion luminescent elements, the current state of the art finds it difficult to generate achromatic light or chromatic light using down-conversion with reasonable operational lifetimes.

Though organic fluorescers with extremely high quantum yields of fluorescence, which necessitate short, excited state lifetimes and are unlikely to be quenched or degraded by oxygen or other reactants, nevertheless degrade over an extended period of operation which solid-state light-emitting diodes find themselves. Hence, ceramic phosphor materials have been a luminescent element of choice from the perspective of operational durability.

What ceramic phosphors gain—in theory—from the perspective of stability, they lose from the standpoint of performance. Ceramic phosphors in general have two major limitations: they are not soluble in the matrix that envelopes the light emitting diode die and the ability of ceramic phosphors to mimic the photopic light curve has been fraught with challenges. In the case of the former, an extensive non-intuitive discussion is stated within United States Patent Application 20030227249 (Mueller, Gerd O.; et al., publication date Dec. 11, 2003). Organic fluorescers generally do not have these difficulties in solubility nor in finding a broad set of luminophors, either fluorescent and or phosphorescent, to match the spectral distribution of the photopic light curve.

It has been demonstrated by Butterworth, et. al. (WO9902026 in a patent application with the title Fluorescent Dye Added to Epoxy of Light Emitting Diode Lens) that a standard blue GaN light emitting diode with blue light emission at 470 nm efficiently radiatively transfers its energy to Coumarin 6 (for green emission), Fluorol 7 (for yellow green emission) and to Rhodamine 110 (for yellow emission). In contrast, Butterworth notes that ceramic phosphors are not soluble in the epoxy lens used to focus light emitting diode die and substantial scattering occurs. (See also Doxsee et. al., U.S. Pat. No. 6,791,259, issue date Sep. 14, 2004, where organic luminescent dyes are utilized and titanium dioxide is used as a scattering agent to form a Lambertian surface, even though titanium dioxide is, itself, photo-active and often leads to molecular degradation through electron transfer reactions.)

Scattering by phosphor particles of primary emission from a semiconductor device and of secondary emission from the phosphor particles themselves may be reduced by reducing the size of the phosphor particles to substantially below wavelengths (e.g., peak wavelengths) of the primary and secondary emission. For example, semiconductor nanocrystals or semiconductor quantum dots, which typically have a diameter less than about 10 nm and hence scatter little of the primary and secondary light, may be used as substantially non-scattering phosphors. The use of semiconductor nanocrystals and quantum dots to phosphor convert the output of a light-emitting semiconductor device is disclosed in U.S. patent application Ser. No. 09/167,795 and in U.S. patent application Ser. No. 09/350,956, both of which are incorporated herein by reference in their entirety. These references do not recognize, however, the significant losses due to scattering by large phosphor particles in conventional phosphor converted light-emitting devices and the consequent advantages to be realized by using non-scattering phosphor particles instead. Further, quantum dots are constructed from elements that may be viewed as the solid-state toxicological equivalent of Hg in fluorescent lamps.

### Environmental Effects for Instantaneous and Long-Term Performance

What is needed is a semiconductor light-emitting device having improved light extraction, improved phosphor conversion, or both, and in a manner that allows for the use of luminophors, in general, and organic fluorescers more specifically, that may do not degrade instantly or over a prolonged period when under constant excitation in a solid-state light. Prior to the invention presented herein, the structure of solid-state lighting with a p-n junction has had very limited diversity of functional form.

### Description

### BRIEF DESCRIPTION OF THE DRAWING

FIG. 1 shows an embodiment of a light emitting diode assembly constructed in accordance with the present disclosure and includes a side view.

FIG. 2 shows an embodiment of a light emitting diode assembly constructed in accordance with the present disclosure.

FIG. 3 shows an embodiment of a light emitting diode die within an enclosure and a plurality of embodiments of a lighting element comprising a light emitting diode.

FIG. 4A shows an embodiment of an orthogonal view of a lighting element comprising a plurality of light-emitting diode 1 by x arrays mounted onto a metal base which forms an outer boundary of a light-emitting lighting fixture.

FIG. 4B shows an embodiment of an orthogonal view of an embodiment of a light-emitting fixture comprising an outer optically transmissive boundary of a light-emitting fixture.

FIG. 4C shows an embodiment of a perspective view of an embodiment of a light-emitting fixture comprising an outer optically transmissive enclosure and a metal base from which the former is secured.

FIG. 5 shows an embodiment of a light emitting diode array constructed in accordance with the present disclosure.

### SUMMARY OF THE INVENTION

The present invention is based on the discovery that a highly efficient, chromatic and non-visible light emitting device may be simply and economically fabricated utilizing solid state light emitting diode dies that in the absence of certain elements of the following generates primary radiation which transfers its energy, radiatively, to secondary luminescent elements where the diode die and or the secondary luminescent elements are in an enhancing and or protecting enclosure.

The present invention relates broadly to a semiconductor light emitting assembly comprising a solid-state device with at least one p-n junction which induces the emission from the solid-state device of a first wavelength radiation to chromatic radiation (radiation, light, luminance, or illuminance with hue), or achromatic radiation (radiation, light, luminance, or illuminance) without hue. The solid state device is structurally associated with a recipient down-converting luminophoric medium, as hereinafter defined, which when either radiatively or otherwise impinged by the first relatively shorter wavelength radiation, or is otherwise non-radiatively excited, through Förster or Dexter energy transfer from the excited states that absent the energy transfer would radiatively emit a first relatively shorter wavelength radiation, or the secondary luminescent elements as hereinafter defined within the luminophoric medium are otherwise non-radiatively excited, through Förster or Dexter energy transfer from the excited states that absent the energy transfer would radiatively emit a relatively shorter wavelength radiation, to responsively emit a tertiary radiation, chromatic and achromatic, polarized or unpolarized, in the visible and non-visible light spectrum. The recipient down-converting luminophoric medium is protected by virtue of a segregating enclosure from elements that instantaneously decrease performance or over long term reduce effectiveness of the down-converting medium. When the segregating enclosure is constructed to also include the active layer of the solid-state device, the same enclosure introduces and maintains a favorable environment to maintain, sustain, protect, or increase performance of the underlying semiconductor with a p-n junction where said performance is the ability to generate light and or to transfer its energy non-radiatively. The site of the acceptor in Förster Resonance Energy Transfer may undergo a Stokes shift (a site of a Stokes shift) as a consequence of a vibrational relaxation of the initially populated excited state although the rate of said vibrational relaxation from Förster Resonance Energy Transfer is slower than that rate for the same excited state generated through radiative energy transfer. [Petkov, et. al., Chem, 5 (8), 2111 (2019)] This is one of the earliest indicators that the means by which an excited state is populated has an impact on the ultimate fate of said excited state. So-called “Hot FRET” is when the donor is still in a higher vibrational state in the electronic excited state—not yet decayed to lowest vibrational state of the first electronic excited state—when the non-radiative energy transfer to the acceptor rakes place. This occurs when the rate of vibrational relaxation in the donors excited electronic state is slower than the rate of energy transfer of the Förster type.

In accordance with a specific embodiment of the present invention, a light-emitting diode operative to emit, for example, monochromatic blue or ultraviolet (UV) radiation is packaged along with fluorescent organic and/or inorganic fluorescers and phosphors—the secondary luminescent elements in the luminophoric medium—in an insulating or isolating enclosure (an assembly), such as a sealed glass ampoule, said package molded within and suspended within a matrix otherwise protecting the aforementioned assembly. In the case of radiative energy transfer, the monochromatic blue or UV radiation output of the light-emitting diode is absorbed and then down converted by the fluorophor or phosphor—the secondary luminescent elements in the luminophoric medium—to yield longer wavelengths to include a broad spectrum of frequencies which appear to an observer as white light. The atmosphere or in the case of a vacuum, the absence of atmosphere, within the insulating or isolating enclosure is selected to increase the probability that the luminophors (the secondary luminescent elements in the luminophoric medium) required to effect down conversion of light from a light-emitting diode responsively emit light of secondary radiation.

This use of an insulating or isolating enclosure to enhance the secondary radiative probability of the fluorescers and/or phosphors to effect down conversion of light from a light-emitting diode in a solid-state light emitting device using a dye or pigment material (a luminophor that fluoresces or phosphoresces; the secondary luminescent elements in the luminophoric medium) is a significant departure from prior art teaching. In addition to allowing for the generation of achromatic (white) light from a blue or ultraviolet emitting light-emitting diode die with a typical p-n junction construction without destruction of the luminophors so selected, devices in accordance with the invention can be variously constructed to provide an essentially infinite series of colored (visible) light emissions, of either narrow or broad spectral distribution, from one single p-n junction construction.

### Detailed Description of the Invention and Exemplary Embodiments Thereof

When a light-emitting diode die is placed within a protecting and enhancing enclosure, said diode die is separated from the resin that absent this invention would otherwise completely cover the diode die; further in this embodiment, the protecting and enhancing enclosure contains within its internal boundaries material of a gaseous, liquid or solid phase that protects and enhances the generation of primary light or non-radiative energy transfer from the light emitting diode die. When the luminophoric medium is placed with a protecting and enhancing enclosure or enclosure, the luminophoric medium is separated from the resin that absent this invention completely covers the diode die; further in this embodiment, the protecting and enhancing enclosure contains within its internal boundaries' material of a gaseous, liquid or solid phase that protects and enhances the generation of secondary radiation from the luminophoric medium itself.

Achromatic light light-emitting diode solid state devices may be made by the method of the present invention. It is preferred in at least some exemplary embodiments that achromatic light if made is affected is through down-conversion, although there is no requirement that the invention be limited to generating achromatic light nor is the invention limited to achromatic light through down conversion. If achromatic light is generated utilizing a down conversion process whereby an excited state that either generates a primary photon—or otherwise is capable of generating a primary photon absent energy transfer—generated in the active region of the diode, then said primary radiation is down converted with primary blue emission and/or secondary blue fluorescent or phosphorescent centers, as well as green and red fluorescent or phosphorescent centers where the fluorescent or phosphorescent centers are within an enclosure and are protected by a vacuum or a beneficial atmosphere or by some other enhancing effect within or impacting an enclosure. These fluorescent and or phosphorescent centers, which may solely emit yellow radiation, comprise the luminophoric medium. Such a light-emitting diode device can down-convert the relatively monochromatic light, typical of all heretofore monochromatic light-emitting diode dies and lamps, to a broader emission that appears as achromatic light from red, green, and blue emission centers, or from yellow emission centers. Such a device is also able to enhance the efficiency of generation of primary radiation in the absence of luminophors as the beneficial atmosphere augments the generation of primary light by virtue of access of the beneficial atmosphere to the active layer that defines the semiconductor p-n junction. As one skilled in the art will immediately observe, the primary photon generated in the active region of the diode may be a blue photon or an ultraviolet photon, if only one diode die is utilized. There is no requirement that only one diode die be utilized, or i more than one diode die is utilized, that they emit with the same spectral distribution.

Under certain circumstances, it may be desirable for both the light emitting diode die and the luminophoric medium to be enclosed in the same enclosure, in separate enclosures, or only one of the two in an enclosure. Generally, the light-emitting diode is within an interior space of a second optically transmissive, although there is an embodiment whereby the light-emitting diode is within an inner space of an outer optically transmissive enclosure. In this embodiment, the luminescent matter (also called the luminophor, the phosphor, the fluorescer or luminescent element) is contained within the second optically transmissive enclosure and is in a receiving relationship with primary radiation from a light-emitting diode placed within an outer optically transmissive enclosure.

When the luminophoric medium contains luminescent elements that emit red, green and blue light, in the case of a UV light-emitting diode die, or 1) red, green and blue light; 2) yellow; 3) red, green and yellow, or other suitable combination of primary and complementary colors in the case of a blue light-emitting diode die, achromatic light is generated.

When two light-emitting diode dies of different wavelengths are used, for example and UV and a blue light-emitting diode die, then the luminophoric medium can be optimized to generate achromatic light by adjusting in concentration or in space the secondary luminescent elements. It is preferred in at least some exemplary embodiments that the two light-emitting diode die be of different wavelengths with as large a gap between their respective emission wavelength maximum as possible. When a blue light-emitting diode die and a cyan light-emitting diode die are used, then the luminophoric medium will contain secondary luminescent elements that emit in the yellow and in the red. When a UV and green light-emitting diode die is utilized, then the secondary luminescent elements will be blue and red; when a blue and red light-emitting diode die are utilized, then the secondary luminescent elements will be green. When a blue light-emitting diode die and a yellow or amber light-emitting diode die are utilized, then the secondary luminescent elements need only be adjusted to optimize the color temperature of the achromatic light. The invention is not limited to secondary luminescent elements of multiple molecular compositions (for example, a red emitter, a green emitter, and a blue emitter) as single component emitters are known that generate achromatic light when suitably activated. In at least some exemplary embodiments, a preferred white-emitting phosphor comprises zinc sulfide activated with copper, manganese, chlorine, and, optionally, one or more metals selected from gold and antimony. In at least some exemplary embodiments, a preferred phosphor is Mn doped ZnS nano clusters with no less than 5% and no more than 9% Mn, prepared from a colloidal route and where ultraviolet-visible absorption curves show that on changing the concentration of Mn²⁺ ions, there is a maximum in the band gap for an optimum doping (5.5% of Mn), and where the fluorescence spectra of the doped clusters consist of two distinct emissions: orange and blue.

It is immediately apparent to a skilled practitioner of the teachings presented herein that achromatic light may be formed by methods other than down conversion and this invention is not limited to the implementation of down-conversion for the generation of achromatic light.

When two light emitting diode dies are utilized at least one must be internal to an enclosure and where the secondary luminescent elements are, if utilized, internal of external to an enclosure, are dependent of optimization of the output and durability of the lamp so constructed. When at least one enclosure contains only luminescent elements and not a semiconductor die, that enclosure just described is replaceable and interchangeable at will.

When both the diode die and dice are in an enclosure and the secondary luminescent elements are in an enclosure, they need not be in the same enclosure for radiative energy transfer to take place; they only need to be in a geometric relationship such that the latter receives a primary radiation emanating from the diode die or dies.

A significant advantage of organic luminescent materials is their relatively broad emission bandwidth that offers the maximal overlap of photon wavelengths to generate an achromatic illumination most readily. Prior to this invention, when multiple luminophors were in use (red, green, and blue luminophors) it had been most desirable to utilize fluorescent materials with extremely short radiative lifetimes, less than 50 nanoseconds, to preclude non-radiative energy transfer (to the lowest energy emitter). However, solid-state lighting requiring an after-glow, illumination provided after the power supply is shut off, is not otherwise available since after-glow devices require luminophors with a lifetime greater than 50 nanoseconds, in fact millisecond lifetimes are more specifically preferred in at least some exemplary embodiments. It is for the most part desirable that fluorescent materials or phosphorescent materials with a radiative lifetime greater than 50 nanoseconds be spatially separated within an enclosure and by virtue thereof, these down-conversion luminophors can continue to provide achromatic or chromatic illumination after the power supply is shut off.

It is for the most part desirable that organic fluorescent materials and organic phosphorescent materials are incorporated within an enclosure under vacuum or noble gas or other inert media so as to avoid the opportunity for oxidation of the luminophoric medium instantaneous to their excitation or otherwise degrade the luminophoric medium over an extended period of time. It is also desirable for inorganic or ceramic luminophors to be incorporated within an enclosure under vacuum or noble gas or other inert gas or inert liquid or inert solid to avoid the opportunity for quenching with any quencher—a gas, liquid or solid not inert. It is recognized by one skilled in the art that the mechanism by which gases such as nitrogen, argon, krypton, and xenon are utilized in incandescent lamps is different than the mechanism in which it is utilized in this invention and that it has not heretofore been recognized, prior to this invention, that gases have a beneficial effect in the long-term totality of lighting from p-n junctions or in solid-state lighting devices. The principal utility of gas in incandescent lighting is related to regeneration of the filament first; the utility of a gas also relates to convection and conduction of heat and to prevent the vaporization of the underlying filament element and the inert gas contains a regenerative gas which returns material evaporated from the filament back to the filament. The principal utility of gas in the invention being claimed herein is the protection of the secondary luminescent elements within the luminophoric medium from the deleterious effects of oxygen and other quenchers. The utility of this invention is apparent when it is recognized that when gas is utilized in mercury vapor lamps, as opposed to incandescent lamps and or solid-state lamps with a p-n junction, the principal purpose for doing so is for conductive and or convective heat flow to activate the phosphors which perform better at a higher temperature: Johnson (1984) claims embodiments in which the phosphor employed exhibits a higher efficiency at elevated temperatures and an enclosure space includes inert gas such as nitrogen or argon so that some convective and/or conductive heat flow may be provided to the phosphor to permit arc tube to provide the desired operating temperature for the phosphor.

Notwithstanding the principal benefit of the invention being claimed herein, it has heretofore not been recognized that the p-n junction—in a light-emitting diode (LED) lamp—itself will benefit from operating in an environment such as claimed herein. The prior art shows no examples of LED die lamps, or solid-state lamps with a p-n junction, whereby the p-n junction used for general illumination lighting is purposely sequestered within an enclosure and that a separate enclosure contains gas to enhance the performance of primary radiation from the p-n junction itself. It is also desirable for the diode die to be incorporated within an enclosure or otherwise exposed to a noble or inert gas (or inert liquid or inert solid) whereby the index of refraction of the inert media are more closely aligned with the index of refraction of the light emitting diode die. A skilled practitioner of the art of enhancing light emission in incandescence will note that the benefit of filament exposure to gas has not been correlated with the index of refraction of a gas itself although, in incandescent lamps, the index of refraction of solids and the beneficial design thereof, has been noted. (Warren, et. al., 1976, Westinghouse Electric Company; Tschetter et. al., 1985, General Electric Company)

Notwithstanding the invention itself, others have noted that the operational performance of light-emitting diode die may benefit from dissipation of charge or dissipation of heat. The traditional mechanism by which this has been achieved is using a heat sink, sometimes a ceramic heat sink. (Lamina on Metal Ceramic Solutions, “Thermal performance is the key to achieving high luminous densities, high reliability, and long life. Lamina's LTCC-M (low temperature co-fired ceramic) packaging allows LED devices (die) to be mounted directly to an engineered metal core without submounts.”, White LED Light Engine Product Specification Sheet, Lamina Ceramics, Inc., 120 Hancock Lane, Westampton, N.J. 08060.) A heat sink (also commonly spelled heatsink) is a passive heat exchanger that transfers the heat generated by an electronic or a mechanical device to a fluid medium.

For heat dissipation, heat sinks are in almost all cases defined to be internal components, difficult to engineer into the design of the microelectronic device, difficult to manufacture when so designed, and add considerably to the weight of said device. If the heat sink is external to the device, its design is almost always at odds with the aesthetic design of the outer appearance. The rate at which heat is transferred by conduction, is proportional to the product of the temperature gradient and the cross-sectional area of the heat sink through which heat is transferred. The greater the area, the faster the rate of dissipation of heat. The instant invention is based on the heretofore unrecognized feature that a metal base even with a thin dimension can actively dissipate heat if the area of the metal base defined by its width and length far exceed the volume of space of an array of light-emitting diode dies defined by its height by width by length. This is especially so if the metal base is comprised as an inert solid as a significant amount of heat is dissipated by the metal base thereby raising its temperature as the internal heat is dissipated through the metal base to the external surroundings. A metal base comprised of an inert solid is essential when the base is carrying a high temperature mode and the molecular vibrations and kinetic energy is a at a maximum so as to avoid obsolescence of the metal base which has structural demands on its as well as heat demands.

Going back to heat sinks heretofore used, another factor impacting the rate and the capacity of a heat sink is called the spreading resistance phenomenon. The resistance reflects how the heat travels from the heat source location and causes a large temperature gradient between the heat source and the edges of the heat sink. This means that there is nonuniformity of the temperature across the functional area of the heat sink. This nonuniformity increases the heat sink's effective thermal resistance.

To decrease the spreading resistance in a base of a heat sink, and to overcome the consequential deficiency of a high spreading resistance, it is common to increase the thickness in certain parts of the heat sink. For internal heat sinks, which are never optically transmissive, such thickness leads to increase bulkiness, more blocking of desired luminescence and electromagnetic radiation necessary for a microelectronic device to be used for general illumination. The instant invention uses a different structure to effectively dissipate heat to the external surroundings. Instead of a heat sink structure, the instant invention employs, among other factors, a large surface area but thin metal base structure on the external boundaries of the device in a configuration that directs desired radiation, without blocking, to an optically transmissive enclosure which, when coupled with a metal base, forms an outer boundaries of the microelectronic device. Vents or protrusions may be placed throughout a flat metal base comprising an inert solid to ameliorate the deficiency a flat material has with respect to spreading resistance.

To direct the required luminescence away from a metal base structure and towards an outer optically transmissive enclosure, an inner wall of a metal base structure may be coated with a thin layer of phosphors. When joined with vents that are opened (i.e.; opened vents) or gaps (effectively opened vents) designed into the external boundary of the microelectronic device through which heat may escape to the external surroundings, a metal base structure is a dramatic improvement in dissipating heat by conduction using not a bulky, thick structure but a tin, flat, high surface area structure. A metal base may be made of aluminum, steel, or copper, among many other metals that conduct heat and have high emissivity. Coating an inner wall of a metal base structure with a thin layer of phosphors also increases the emissivity of a metal base directing the heat away through an outer optically transmissive enclosure at the same time it directs luminescence through the same outer optically transmissive enclosure. For the avoidance of doubt, all the above means that a metal base should be comprised of a metal that has high heat or thermal conductivity although electric conductivity is not a required characteristic of the metal, or a metal base so used.

In addition to the instant invention employing a thin, flat, large area compared to the area of the light-emitting diodes themselves, metal base comprising an inert solid, the instant invention uses vents and gas to effectively dissipate heat from within to the external surroundings of the microelectronic device. The use of a gas to optimally dissipate heat, from one enclosure through another enclosure—from a second enclosure containing a light-emitting diode die through a primary enclosure to the external surroundings, using a gas for thermal transport, and using a metal base—for a solid-state lamp with a p-n junction, has not until now been taught. In the exemplary embodiments of the instant invention, heat sinks are not used as these means of dissipating heat have many disadvantages, far too many to elaborate here.

Generally, the process of dissipating heat means designing and allowing for a heat flow or a heat transfer (i.e., the transfer of heat). The heat equation is an important partial differential equation that describes the distribution of heat (or variation in temperature) in each region over time. In some cases, exact solutions of the equation are available[see M C Wendl (2012) Theoretical Foundations of Conduction and Convection Heat Transfer, Wendl Foundation, DOI 10.13140/RG.2.1.1875.3120]; in other cases the equation must be solved numerically [see Zhengbiao Peng, Elham Doroodchi, Behdad Moghtaderi, Heat transfer modeling in Discrete Element Method (DEM)-based simulations of thermal processes: Theory and model development, Progress in Energy and Combustion Science, Volume 79, 2020, 100847, ISSN 0360-1285].

Heat transfer is a discipline of thermal engineering that concerns the generation, use, conversion, and exchange of thermal energy (heat) between physical systems. Heat transfer is classified into various mechanisms, such as thermal conduction, thermal convection, thermal radiation, and transfer of energy by phase changes. Engineers also consider the transfer of mass of differing chemical species (mass transfer in the form of advection), either cold or hot, to achieve heat transfer. While these mechanisms have distinct characteristics, they often occur simultaneously in the same system.

Heat conduction, also called diffusion, is the direct microscopic exchanges of kinetic energy of particles (such as molecules) or quasiparticles (such as lattice waves) through the boundary between two systems. When an object is at a different temperature from another body or its surroundings, heat flows so that the body and the surroundings reach the same temperature, at which point they are in thermal equilibrium. Such spontaneous heat transfer always occurs from a region of elevated temperature to another region of lower temperature, as described in the second law of thermodynamics.

Heat convection occurs when the bulk flow of a fluid (gas or liquid) carries its heat through the fluid. All convective processes also move heat partly by diffusion, as well. The flow of fluid may be forced by external processes, or sometimes (in gravitational fields) by buoyancy forces caused when thermal energy expands the fluid (for example in a fire plume), thus influencing its own transfer. The latter process is often called “natural convection”. The former process is often called “forced convection.” In this case, the fluid is forced to flow by use of a pump, fan, or other mechanical means.

Thermal radiation occurs through a vacuum or any transparent or transmissive medium (solid or fluid or gas). It is the transfer of energy by photons or electromagnetic waves governed by the same laws. Unique among the various transfers of heat, heat dissipation by thermal radiation can proceed through a vacuum; the intervening medium does not carry the heat transfer and all that is required is that the medium be transparent or transmissive to the frequencies of the thermal radiation, said frequencies solely a function of the temperature of the source that generates the thermal radiation. In vacuum or outer space, there is no convective heat transfer, thus in these environments, radiation is the only factor governing heat flow between a surface and the environment. For a satellite in space, generating heat within a satellite—generated due to its electrically powered instruments—in the vacuum of space, a 100° C. (373 K) satellite surface facing the Sun will absorb a lot of radiant heat, because the Sun's surface temperature is nearly 6000 K, whereas the same surface facing deep space will radiate a lot of heat, since deep space has an effective temperature of only several Kelvin. Indeed, the International Space Station relies on thermal radiation to dissipate heat from the internal equipment to the external boundaries. It was Max Planck himself, in the opening pages of his heat transfer thesis, who marveled at the wonder of thermal radiation that it can transport heat for million of miles through the vacuum of space, without any intervening matter required to carry the heat, and which when focused can still melt an ice cube on Earth on the coldest days of winter.

When the dissipation of heat is that which is generated at a site of the p-n junction and dissipated via the mechanism of thermal radiation, the heat flow is through (emphasis on “through”) an optically transmissive enclosure including, by necessity, an outer optically transmissive enclosure, to the external surroundings.

When the dissipation of heat is of that which is generated at a site of a Stokes shift and dissipated via the mechanism of thermal radiation, the heat flow is through (emphasis on “through”) an optically transmissive enclosure including, by necessity, an outer optically transmissive enclosure, to the external surroundings. When the external surroundings are of the same temperature as an inner space of an outer optically transmissive enclosure, a thermal equilibrium has taken place. When the external surroundings are of a lower temperature than an inner space of an outer optically transmissive enclosure, then heat will be continuously transferred to the external surroundings.

It is important to acknowledge that in both the case of heat generated at a site of the p-n junction and a site of a Stokes shift, then the electromagnetic waves called luminescence and the electromagnetic waves called thermal radiation will simultaneously be emitted and passed through a space, including a space (inner or interior) under vacuum. The spectral frequencies of the luminescent electromagnetic waves will be decided by the bandgap of the p-n junction or the energy of the luminophor's first electronic excited state whereas the spectral frequencies of the thermal radiation will be determined by the temperature at which these emitters are found to operate. The optically transmissive enclosures, whether inner or outer, whether primary or secondary, whether first or second, must allow for both the luminescence and the thermal radiation to pass through.

In the special case where both the diode die and the secondary luminescent element are sequestered within the same enclosure, it is for the most part desirable that an enclosure that sequesters within it the p-n junction also contain an inert gas or inert liquid or inert solid with excellent heat conduction if the p-n junction is more sensitive to heat than the luminophors so as to remove heat from the p-n junction itself. It is preferential in at least some exemplary embodiments that nitrogen or argon be used as krypton conducts heat less than argon does, and xenon conducts heat less than even krypton does. Note that this embodiment is the opposite of that which is needed with incandescence of tungsten filament in a sealed light bulb. It is generally the case that when inorganic luminophors are utilized, the heat insensitivity of these inorganic luminophors is such that it is preferred in at least some exemplary embodiments to dissipate the heat away from the p-n junction. In the case where the light output of the inorganic luminophor requires an elevated temperature in at least some exemplary embodiments, then it is preferred to use nitrogen or argon or other gas with excellent heat conductivity.

It is for the most part desirable that an enclosure that sequesters within it the p-n junction also contains an inert gas or inert liquid or inert solid with poor heat conduction if the p-n junction is less sensitive to heat than the luminophors so as to preclude heating the luminophors themselves. It is preferential in at least some exemplary embodiments that xenon be used as krypton conducts heat less than argon does, and xenon conducts heat less than even krypton does. It is generally the case that when organic luminophors are utilized in at least some exemplary embodiments, the high heat sensitivity of these organic luminophors is such that it is preferred to not dissipate the heat away from the p-n junction.

Chromatic light light-emitting diode solid state devices may be made by the method of the present invention. While not necessary to produce chromatic light, it is apparent that the devices of this invention may produce chromatic light, utilizing a down conversion process whereby an excited state that either generates a primary photon or otherwise is capable of generating a primary photon absent non-radiative energy transfer generated in the active region of the diode is down converted with primary blue or primary UV or primary blue and UV emission and/or secondary blue fluorescent or phosphorescent centers, as well as green or red fluorescent or phosphorescent centers where the fluorescent or phosphorescent centers are within an enclosure and are protected by a vacuum or a beneficial atmosphere or by some other enhancing effect within or impacting an enclosure. Such an LED device can down-convert the relatively monochromatic light; typical of all heretofore colored LED dies and lamps, to a broader emission that provides chromatic light from red, green, and blue emission centers. The secondary luminescent elements may be selected and varied as desired, with control of concentrations and spatial arrangements of each selected secondary luminescent element such that the light generated by the luminophoric medium supplies color of any hue and apparent tint.

It is an essential element that either inorganic or organic fluorescent or phosphorescent materials can be used to down-convert the primary ultraviolet or blue light emission to a mixture of blue, green and red luminescent emissions. A significant advantage of organic luminescent materials is their relatively broad emission bandwidth which offers the maximal overlap of photon wavelengths to generate a chromatic illumination most readily. Further, it is most desirable to use organic fluorescent material with extremely short radiative lifetimes, less than 50 nanoseconds, to preclude non-radiative energy transfer (to the lowest energy emitter) since an after-glow is not desired in this embodiment. It is for the most part desirable that organic fluorescent materials and organic phosphorescent materials are incorporated within an enclosure under vacuum or noble gas or other inert media so as to avoid the opportunity for oxidation of the luminophoric medium instantaneous to their excitation or over an extended period of time.

As discussed above, there have been disclosures regarding the generation of white light in solid state semiconductor devices with p-n junctions using radiative energy transfer and these examples use primarily inorganic dopants near the active layers of the p-n junctions or organic fluorescers within the epoxy matrix encapsulating the semiconductor, but none are known that apply the principles of the present invention to semiconductor-based p-n junction LED lamps. It has not been until now recognized than organic luminophors can acts as dopants and non-radiative energy transfer will populate the excited states of these luminophors when so arranged to generate secondary radiation. Absent the invention described here, the utilization of an isolating and protecting enclosure, said non-radiative energy transfer is not effective. As an example, benzophenone is often used as a triplet sensitizer using the mechanism of Dexter energy transfer previously described. Benzophenone when excited enters a singlet excited state and then rather rapidly crosses over into its triplet excited state through a process known to those skilled in the art as intersystem crossing.

Once benzophenone triplet is formed—an excited state species that is easily quenched by the ground state of oxygen, itself a triplet, rendering the process sought after basically useless it can transfer its energy non-radiatively to the ground state (typically a singlet) of a luminophor such as bis(phenyl-ethynyl) anthracene to form the excited triplet state of bis(phenyl-ethynyl) anthracene which is then able to phosphoresce. There is no other means of practically garnering the excited triplet state of bis(phenyl-ethynyl) anthracene other than through non-radiative energy transfer since radiative energy transfer only populates the singlet excited state and the efficiency of intersystem crossing from the singlet excited state to the triplet excited state in bis(phenyl-ethynyl) anthracene is essentially zero. However, as mentioned, triplet benzophenone is easily quenched by oxygen and triplet benzophenone is excellent at destroying through hydrogen abstraction the epoxy resin used normally in potting a LED lamp. Therefore, the invention herein described which includes among its elements a protecting and enhancing enclosure, allows for immobilization of benzophenone within the isolating and protecting enclosure, isolation and protection of benzophenone triplets so formed from quenching by either oxygen or hydrocarbons such as epoxy resin, and non-radiative energy transfer from the protected benzophenone triplet to a luminophor with the emission requirements required to form chromatic, achromatic or non-visible light emission.

The present invention is based on the discovery that a highly efficient achromatic, chromatic and non-visible light emitting device may be simply and economically fabricated utilizing solid state light emitting diode dies that generates primary radiation which transfers its energy, radiatively, to secondary luminescent elements where the diode die and or the secondary luminescent elements are in an enhancing and or protecting enclosure.

The present invention relates broadly to a semiconductor light emitting assembly comprising a solid-state device with at least one p-n junction which induces the emission from the solid-state device of a first wavelength radiation to chromatic radiation (radiation, light, luminance or illuminance with hue), or achromatic radiation (radiation, light, luminance or illuminance) without hue. The solid state device is structurally associated with a recipient down-converting luminophoric medium, as hereinafter defined, which when either radiatively or otherwise impinged by the first relatively shorter wavelength radiation, or is otherwise non-radiatively excited, through Förster or Dexter energy transfer from the excited states that absent the energy transfer would radiatively emit a first relatively shorter wavelength radiation, or the secondary luminescent elements as hereinafter defined within the luminophoric medium are otherwise non-radiatively excited, through Förster or Dexter energy transfer from the excited states that absent the energy transfer would radiatively emit a relatively shorter wavelength radiation, to responsively emit a secondary radiation, chromatic and achromatic, polarized or unpolarized, in the visible and non-visible light spectrum. The recipient down-converting luminophoric medium is protected by virtue of a segregating enclosure from elements that instantaneously decrease performance or over long term reduce effectiveness of the down-converting medium. When the segregating enclosure is constructed to also include the active layer of the solid-state device, the same enclosure introduces and supports a favorable environment to maintain, sustain, protect or increase performance of the underlying semiconductor with a p-n junction where said performance is the ability to generate light and or to transfer its energy non-radiatively.

In accordance with a specific embodiment of the present invention, an LED operative to emit, for example, monochromatic blue or ultraviolet (UV) radiation is packaged along with fluorescent organic and/or inorganic fluorescers and phosphors—the secondary luminescent elements in the luminophoric medium—in an insulating or isolating enclosure (an assembly), such as a sealed glass ampoule, said package molded within and suspended within a matrix otherwise protecting the aforementioned assembly. In the case of radiative energy transfer, the monochromatic blue or UV radiation output of the LED is absorbed and then down converted by the fluorophor or phosphor—the secondary luminescent elements in the luminophoric medium—to yield longer wavelengths to include a broad spectrum of frequencies which appear to an observer as white light. The atmosphere or in the case of a vacuum, the absence of atmosphere, within the insulating or isolating enclosure is selected to increase the probability that the luminophors (the secondary luminescent elements in the luminophoric medium) needed to effect down conversion of light from light-emitting diode, in fact, responsively and successfully emit light of secondary radiation.

This use of an insulating or isolating enclosure to enhance the secondary radiative probability of the fluorescers and/or phosphors to effect down conversion of light from an LED in a solid-state light emitting device using a dye or pigment material (a luminophor that fluoresces or phosphoresces; the secondary luminescent elements in the luminophoric medium) is a significant departure from prior art teaching. In addition to allowing for the generation of achromatic (white) light from a blue or ultraviolet emitting LED die with a typical p-n junction construction without destruction of the luminophors so selected, devices in accordance with the invention can be variously constructed to provide an essentially infinite series of colored (visible) light emissions, of either narrow or broad spectral distribution, from one single p-n junction construction.

As used herein, the term “atmosphere” refers to a surrounding influence or environment.

As used herein, the term “attenuation” means to lessen the amount, force, magnitude, or value of.

As used herein, the term “base” is a both a part used in an assembly of parts or substructures, or when assembled into a device, forms that part of the assembly to which an article external to the microelectronic device may be attached to the microelectronic device, or which that part of the microelectronic device that sits upon the external article, or that part of the microelectronic device that hangs from the external article. The external article is a part or assembly that is external to and recognized not to be an inclusive component of the microelectronic device itself. For example, a base is that part of the microelectronic device that sits upon a table or hangs from a ceiling where the external article is the table or the ceiling, respectively. A base is usually the lowest region or edge of something (the microelectronic device), especially the part on which it (the something) rests or is supported. However, the device when in use may have a base situated so that it is not the lowest (closest to Earth) region of the device even if, when not in use, a base may be observed as the lowest part of the device. To further explain using a common sense observation in nature, a base of a tree (that which has the widest diameter when a tree remains planted in the ground) converted into a telephone pole may be the lowest part of the pole if the pole's widest diameter is inserted into the ground or may be the highest part of the pole if the widest diameter is that which is up in the air and supports the wires which hang upon it. In the latter case, and for the avoidance of doubt as used herein, a base of the substructure, when put into use, whether temporary or permanent, is no longer the lowest part of the substructure but is still characterized as a base.

As used herein, the term “boundary” means for example a line that marks the limits of an area; more specifically outer boundary means the edge of the device or assembly (or fixture) that marks the limits of the area of said device with the external surroundings.

As used herein, a “coating” on a wall or surface may be covalently bonded to the wall or surface or it may not be covalently bonded but still adheres to the wall or surface.

As used herein, the term “enclosure” refers to a natural or artificial enclosed space or cavity whose atmosphere can be controlled during assembly or during use. The term “envelope” is used interchangeably with the term “enclosure.” In most teachings herein, the term “second enclosure” or “enclosure” is used and is by virtue of my assertion tantamount with how the term “enclosure” and “envelope” might be utilized in this instant invention. The term optically transmissive enclosure is used in the instant invention to describe the matter, an assembly of material parts, that forms the external boundary of the natural or artificial enclosed space or cavity whose atmosphere can be controlled, and the volume so enclosed is referred to as either an inner space or an interior space, as contextually clear from how it is used. In other words, in the specification and claims of the instant invention, the term enclosure is used to described that which encloses as opposed to or in addition to that which is enclosed. When used in the context of that which encloses, an optically transmissive enclosure is one that allows for the transport of radiation (light) from the space that is enclosed through the boundaries that make up the enclosure to the outer world. The term optically transmissive enclosure allows for a portion of the boundaries (which define the enclosure) to allow light to be transported through, e.g., not all the boundary or boundaries may be transmissive or transparent. That portion of the enclosure boundaries that are transmissive may be those which direct or transport light to the external surfaces in the external environment and that provides the desired amount of illuminance onto that surface. In at least some exemplary embodiments, when the boundaries of the enclosure contain matter that is not optically transmissive it is usually because the external surface facing the opaque boundary is one where the adjacent space does not have any illuminance (e.g., a specific area on the surface of a ceiling or a wall to which the lighting fixture is flush mounted, said specific area being of similar size to the size of the opaque boundary of the outermost enclosure). For the avoidance of doubt, an optically transmissive enclosure does not carry thermal radiation and it is preferential that all the thermal radiation frequencies pass through an optically transmissive enclosure without any attenuation of any frequency.

As used herein, chemically inactive means that the substance of which a part is comprised does not react with and is not otherwise modified nor destroyed by chemical reagents. As used herein, such a chemically inactive surface may still be successfully coated with a thin layer of another element or matter as the coating does not react with the surface but simply adheres to it.

As used herein, the term “colored light” and “chromatic light” refers to visible light having hue.

As used herein, the term “conduction” means for example the process by which heat is directly transmitted through a substance when there is a difference of temperature between adjoining regions, without movement of the material. Like electrical conduction in a copper wire, the conduction of heat proceeds without movement of the copper material but is carried, or transported by, the movement of electrons through the material, whereby the kinetic energy of said movement carries the heat along with it. More specifically, heat conduction is a phenomenon that occurs through the interaction of neighboring atoms and molecules, transferring their energy/heat (partially) to their neighbors. This is the most significant means of heat transfer within a solid and between solid objects in thermal contact. Heat transfer physics describes the kinetics of energy storage, transport, and energy transformation by the principal energy carriers: phonons (lattice vibration waves), electrons, and fluid particles. Heat conduction, or heat transfer, or heat dissipation to the external surroundings, requires matter that can conduct heat. Metals selected for utilization in the instant invention, especially metals that are inert solids, are those which are excellent conductors of heat. The instant inventions use a base comprising an inert, solid metal, such as steel or copper, to transport heat generated at and to be dissipated from, a site of the p-n junction or a site (or location or source) of a Stokes shift, to the external surroundings whereby the heat is said to be carried by the phonons and electrons within a metal base. It is important to use a metal that conducts heat, the metal that comprises the base need not conduct electricity. For example, the metal Vanadium Dioxide (a metal at 67 degrees Celsius, well within the operating temperature of the instant invention) is a good conductor of electricity but not of heat. [In Vanadium Dioxide, “[T]the electrons [were] are moving in unison with each other, much like a fluid, instead of as individual particles like in normal metals. For electrons, heat is a random motion. Normal metals transport heat efficiently because there are so many different possible microscopic configurations that the individual electrons can jump between. In contrast, the coordinated, marching-band-like motion of electrons in vanadium dioxide is detrimental to heat transfer as there are fewer configurations available for the electrons to hop randomly between.” See for example Jennifer Ellis, “Metal that Conducts Electricity but Not Heat”, Feb. 2, 2017 8:02 PM PST, retrieved from www.labroots.com on 1 Oct. 2022.]

As used herein, the term “convection” means for example the movement caused within a fluid by the tendency of hotter and therefore less dense material to rise, and colder, denser material to sink under the influence of gravity, which consequently results in transfer of heat. The transfer of heat by convection to the external surroundings, i.e., the dissipation of heat, requires a vent that is opened whereby said opened vent is placed on the outer boundary of the microelectronic device and whereby a vent allows for the movement of hotter fluid through it and crossing into the external surroundings. The outer boundary onto which the opened vent is placed may be either that which is a metal base and, or, that which is an outer optically transmissive enclosure, and, or the seam between a metal base and an outer optically transmissive enclosure, all of which forming jointly when coupled an outer boundary of the microelectronic device which defines an inner space. As used herein, a seam means a gap. As used herein, the gap between two substructures that form the outer boundary of the microelectronic device is an opened vent that cannot be closed. As used herein, said opened vents on a metal base can be closeable and opened vents on an outer optically transmissive enclosure may be closeable.

As used herein, the term electro-luminescent means for example a radiative transition with or without a change in spin multiplicity from the excited state, itself populated by an electrical current and from which it emits to the lower energy state to which, after light emission, it remains.

As used herein, the term an “external surrounding” is that environment that the entire microelectronic device resides within. The term more explicitly means the environment that is all around the outside of the microelectronic device and is recognized as not being part of the device itself.

As used herein, a first wavelength radiation is that which is emitted by a light-emitting diode with a p-n junction when powered with an electrically voltage. This is also referred to as primary radiation.

As used herein, the term “flat” means a smooth and even surface; without marked lumps or indentations. The entire surface of a flat metal base need not be continuously flat to allow for the insertion of vents or apertures or gaps or even protrusions at the edges while maintaining a smooth and even surface. When there are protrusions on the otherwise flat metal solid base, these protrusions are limited to the edges of the base and still referred to as a flat metal base. These protrusions, if any, do not interfere with the mounting of the microelectronic device to an external flat surface. The term “flat dimensions” means “flat”.

As used herein, the term “fluid” means for example a substance that has no fixed shape and yields easily to external pressure; a gas or (especially) a liquid.

As used herein, the term fluorescent means for example a radiative transition without a change in spin multiplicity from the excited state from which it emits to the lower energy state to which, after light emission, it remains. A fluorophor or a fluorescer both mean a substance that fluoresces.

As used herein, the term “heat dissipation” means the transfer of heat generated within a microelectronic device, whether at a site of electron: hole recombination or at a site of a Stokes shift, to at least one external surroundings of said device.

As used herein, the term “hue” refers to visible light with the attribute of colors that permit them to be classed as red, yellow, green, blue, or an intermediate between any contiguous pair of these colors.

As used herein, “indentations” means more than one deep recess on the surface of something that is observable by the unaided human eye.

As used herein, the term “interior volume” means the same as “interior space”.

As used herein, the term “luminophoric medium” refers to a material which in response to radiation emitted by the solid-state device or is otherwise non-radiatively excited, emits light—achromatic light or color light in the visible light spectrum—by fluorescence and/or phosphorescence or emits infra-red light in the non-visible light spectrum. The term “down-converting medium” is synonymous in our usage with “luminophoric medium” as the luminophors of interest and discussion herein are those that have a Stokes shift.

As used herein, a metal base is a base comprised of a metal.

As used herein, a metal base comprising an inert solid, or an inert, solid, metal base, mean the same thing and is a metal base that is both a solid, more explicitly, something with a rigid or relatively rigid structure that is not completely compressible and is virtually incompressible, and is unreactive to the elements or chemically inactive.

As used herein, a “nested relationship” or “nested” means something (an enclosure, as an example) that is fully contained within something else of the same kind (another enclosure, as an example). A triply nested relationship as used herein means at least one optically transmissive enclosure within an optically transmissive enclosure both of which are within an optically transmissive enclosure. A doubly nested relationship means at least one optically transmissive enclosure within another optically transmissive enclosure.

As used herein, the term optically transmissive enclosure means the same as light transmissive enclosure, with or without a hyphen preceding transmissive. This invention teaches that a plurality of light-emitting diodes and an array of light-emitting diodes with multiple enclosures may be used in the microelectronic device so claimed. Hence, the plural of optically transmissive enclosure (i.e., optically transmissive enclosure) is frequently used in the claim limitations to convey that there are a multiple of enclosures in which are a multiple of light emitting diodes. As used in the context of optically transmissive enclosures, enclosure means an area that is sealed off, partitioned off or separated off with an artificial barrier, i.e.; the part that encloses said area is the enclosure. Enclose means surround or close off on all sides. As used, it may take more than one part to close off on all sides, but each part may still be described as an enclosure. This is explicitly cited when at least two parts are said to be coupled and when joined form a boundary of the fully closed off area. This boundary is frequently cited to be an outer boundary if it separates off an area of the microelectronic device from the external surroundings. Each enclosure has an inner wall and an external wall. For the avoidance of doubt, the cited walls will be also associated with a given enclosure. A second enclosure may also have its walls described as an outer boundary facing the inner space as opposed to facing the external surroundings whereby the outer boundary of the outer enclosure forms the inner space within it.

As used herein, the terms optically transmissive and optically transmissive enclosures mean the same.

As used herein, optically-transmissive means for example either the full or partial transport (through the surface) of thermal radiation or luminescence—including electroluminescence, scattered electroluminescence, and fluorescence—or both (thermal radiation and luminescence).

As used herein, the term outer optically transmissive enclosure means the enclosure of the microelectronic device that is outermost. Hence, outermost optically transmissive enclosure means the same as outer optically transmissive enclosure.

As used herein, the term outermost means that which is farthest from the center of the microelectronic device.

As used herein, the term phosphorescent means for example a radiative transition with a change in spin multiplicity from the excited state from which it emits to the lower energy state to which, after light emission, it remains.

As used herein, the term “p-n junction” means for example an interface or a boundary between two semiconductor material types, namely the p-type and the n-type, inside a semiconductor. The p-side or the positive side of the semiconductor may have an excess of holes and the n-side, or the negative side may have an excess of electrons.

As used herein, the term a “primary radiation” means the initial photons directly produced by hole-electron recombination at a p-n junction. It is also referred to as a “first wavelength radiation”.

As used herein, the term radiative lifetime means for example the lifetime of an electronic state in the situation where only radiative processes depopulate that level, or otherwise recognized as the reciprocal of the rate of luminescence.

As used herein, the term “removably coupled” means for example to move by lifting, pushing aside, or taking away or off (removably being an adjective of coupled) that to which it is otherwise paired or connected.

As used herein, the term “second enclosure” is that enclosure fully within an inner space, that is optically transmissive, and which contains an interior space. A second enclosure is also called an inner, optically transmissive enclosure. A second enclosure has both an interior wall and an exterior wall: the interior wall faces and is in contact with an interior space; the exterior wall faces and is in contact with the inner space. The interior space may also be called an interior volume.

As used herein, the term “secondary luminescent elements” refers to the specific materials that together—whether intimately mixed or not, whether spatially separated or not—comprise the luminophoric medium.

As used herein, the term second light transmissive enclosure means the same as second optically transmissive enclosure. All mean the same. Since enclosure is already defined as being optically transmissive enclosure or light transmissive enclosure—the term optically transmissive enclosure is often used in the instant invention to describe the matter, an assembly of material parts, that forms the external boundary of the natural or artificial enclosed space or cavity whose atmosphere can be controlled, and the volume so enclosed is referred to as either an inner space or an interior space (or interior volume), as contextually clear from how it is used—secondary means that which is not the primary enclosure. The primary optically transmissive enclosure or primary light-transmissive enclosure is an outer optically transmissive enclosure or the outer light transmissive enclosure. The term second enclosure means the same as inner optically transmissive enclosure.

As used herein, the term a “secondary, longer wavelength” means a wavelength of radiation that is bathochromic to a first wavelength radiation.

As used herein, a second wavelength radiation is a luminescence which is emitted by a phosphor, a flurophor or a luminescent material in response to absorption of a first wavelength radiation. This luminescence is said to originate from secondary luminescent elements.

The term “secondary radiation” means the photons subsequently generated by virtue of transfer of the energy of the excited state that defines the p-n junction to form some other excited state and the radiation that is released by virtue of relaxation of this other excited state.

As used herein, the term “shade” refers to the degree to which a color is decreasingly illuminated; that is, a gradation of darkness for color light.

As used herein, the term “smooth” means a regular surface free from perceptible projections, lumps, or indentations observable by the unaided human eye. Nothing in this definition requires the avoidance of vents or gaps that may be inserted into a flat, metal surface comprising an inert solid and which has a smooth thin layer coating of phosphor.

As used herein, the term “solid state device,” used in reference to the device for generating a primary radiation which subsequently is down-converted to a longer wavelength radiation in such visible achromatic (white) or chromatic (color) light spectrum, means a device which is selected from the group consisting of semiconductor light emitting diodes, semiconductor lasers, thin film electroluminescent cells, electroluminescent display panels, and internal junction organic electroluminescent devices. As used herein, the term “spectral” means relating to or derived from the electromagnetic spectrum of radiation or light; regardless of whether the radiation is primary, secondary, tertiary or thermal.

As used herein, the term thermal radiation is for example a process by which energy, in the form of electromagnetic radiation, is emitted by a heated surface in all directions and travels directly to its point of absorption; thermal radiation may not involve an intervening medium to carry it even though it can pass through the intervening medium provides said medium is optically transmissive.

As used herein, a thermodynamic definition of outer boundary may be a closed surface surrounding a system through which energy and mass may enter or leave the system. Everything external to the system is for example the surroundings. In at least some exemplary embodiments of the instant invention, mass may enter, and mass may leave the luminaire through vents (convection) and through the entry and exit ports.

As used herein, an “inert solid” is a thermodynamic state of matter that is not a gas nor is it a liquid but is a physical state known as a solid. A solid is a substance which exists in the solid-state. Solids feature tightly packed atoms whose kinetic energies are much lower than those of liquids and gases. All solids have rigid structures that tend to resist any external forces applied to them. Solids also are known to have a fixed, definite shape (unlike liquids and gases, which assume the shape of the container they are placed in). Furthermore, solids are also known to have a fixed, definite volume (unlike gaseous substances which expand to occupy the entire volume of the container they are placed in). Solids do not have the ability to flow as liquids and gases do. Another dissimilarity between solids and gases is that gases can be compressed when some external pressure is applied to them, but solids are virtually incompressible. The atoms of a solid can be bound together in either a regular or an irregular manner. The way the atoms of the solid are arranged in three-dimensional space determines the type of the solid. An inert solid is all the above but which does not substantively change in time due to exposure to the elements, whether these elements are chemicals or adventitious agents from the surroundings to which an inert solid is exposed. Succinctly, inert means chemically inactive. Hence an inert solid is a solid that is chemically inactive.

As used herein, the term “thermo-luminescent” means for example a radiative transition with or without a change in spin multiplicity from the excited state, itself populated by an applied heat and from which it emits to the lower energy state to which, after light emission, it remains.

As used herein, a third radiative component is that luminescence which is emitted by a phosphor, a fluorophore or a luminescent material subsequent its electronic excitation non-radiatively (e.g.; Förster Resonance Energy Transfer).

As used herein, the term “tint” refers to a variation of a color produced by adding white to it and characterized by a low saturation with relatively high lightness.

As used herein, the term “transmissivity” means a measure of the capacity of a material to transmit radiation (the ratio of the amounts of energy transmitted and that received or incident thereon).

As used herein, the term “transmitting” means conveying energy or force through a medium.

As used herein, the term “transmissive” means of or relating to transmissivity of a material.

As used herein, “transmittance” means the fraction of incident light, or other radiation, that passes through a substance (medium or material).

As used herein, the term “white light” and “achromatic light” refers to visible radiation possessing no hue. Achromatic light is free of color; achromatic pigment or dye is a color perceived to have no hue, such as neutral grays. White light is light perceived as achromatic, that is, without hue.

As used herein, when a light-emitting diode is within an interior space and the phosphor is within an interior space, then the internal enclosure may be called the “second enclosure” or “second optically transmissive enclosure” and the outermost enclosure may be called the primary enclosure or primary optically transmissive enclosure”.

As used herein, a light-emitting diode die is, in the context of a light-emitting diode, a small block of semiconducting material on which a given functional circuit is fabricated. Typically, diodes are produced in large batches on a single wafer of, for example, GaN on sapphire. The wafer is cut (diced) into many pieces, each containing one copy of light-emitting diode. Each of these pieces is called a die. There are three commonly used plural forms: dice, dies and die. To simplify handling and integration most dies are packaged in various forms with leads. A light-emitting diode is a semiconductor light source that emits light when current flows through it. Electrons in the semiconductor recombine with electron holes, releasing energy in the form of photons. The color of the light (corresponding to the energy of the photons) is determined by the energy required for electrons to cross the band gap of the semiconductor. A light-emitting diode die may also be called a “LED die” or a “single die semiconductor LED”, or a “single die semiconductor light-emitting diode”.

As used herein, when the light-emitting diode is within an interior space and the phosphor is within an inner space or interior space, then the internal enclosure is called a “second enclosure” or a “second optically transmissive enclosure”.

Other aspects, features and embodiments of the invention will be more fully apparent from the ensuing detailed description and claim limitations.

### Detailed Description of the Invention and Exemplary Embodiments Thereof

The present invention is based on the discovery that a highly efficient light emitting device with long term stability may be simply and economically fabricated utilizing a solid state light emitting diode die that either generates primary radiation (acting as a radiative donor) or non-radiatively transfers energy (acting as a non-radiative donor) from the excited state-which defines the p-n junction under an applied voltage—and where the diode die (the donor) and or the acceptor of primary radiation and or non-radiative energy transfer is in an enhancing and or protecting nesting set of enclosures.

Less broadly, the present invention is based on the discovery that a highly efficient achromatic, chromatic and non-visible light emitting device may be simply and economically fabricated utilizing a solid state light emitting diode die (a donor) approximate to a luminophoric medium (an acceptor) that generates primary radiation and where the excited state—which defines the p-n junction under an applied voltage—transfers its energy, radiatively or non-radiatively, to secondary luminescent elements in the luminophoric medium and where the diode die and or the luminophoric medium are in a nesting set of enclosures.

Less broadly, the present invention is where an enclosure is optically transmissive, or light transmissive, or radiation transmissive, all of which mean that electromagnetic energy transmits through enclosure either partially or fully, further meaning that the frequencies of the electromagnetic source are not fully attenuated by any one enclosure.

Less broadly, the present invention is where at least one inner optically transmissive, or light transmissive, or radiation transmissive, all of which mean the same, enclosure is within an outer optically transmissive, or outer light transmissive or outer radiation transmissive enclosure.

Less broadly, the present invention is where within one outer optically transmissive, or light transmissive or radiation transmissive enclosure—all of which mean the same—is at least one, if not more, inner optically transmissive, or light transmissive, or radiation transmissive, enclosures. The space within an outer optically transmissive, or light transmissive or radiation transmissive enclosure is called an inner space of said outer enclosure. The space within an inner optically transmissive, or light transmissive or radiation transmissive enclosure is called an interior space of said inner optically transmissive enclosure. An interior space as so defined may be in an optically transmissive enclosure that is called an inner optically transmissive enclosure or a second optically transmissive enclosure. An inner space as so defined may be in an optically transmissive enclosure called an outer light transmissive enclosure or a primary light transmissive enclosure or a primary optically transmissive enclosure, all of which mean the same.

Less broadly, the present invention is based on the discovery that a highly efficient achromatic, chromatic and non-visible light emitting device may be simply and economically fabricated utilizing a solid state light emitting diode die proximate to a luminophoric medium that in the absence of certain elements of the following generates primary radiation and where the excited state—which defines the p-n junction under an applied voltage—transfers its energy, radiatively or non-radiatively, to secondary luminescent elements in the luminophoric medium and where the diode die and the luminophoric medium are both in the same enhancing and or protecting optically transmissive enclosure.

Less broadly, the present invention is based on the discovery that a highly efficient achromatic, chromatic and non-visible light emitting device may be simply and economically fabricated utilizing a solid state light emitting diode die proximate to a luminophoric medium that in the absence of certain elements of the following generates primary radiation and where the excited state—which defines the p-n junction under an applied voltage—transfers its energy, radiatively or non-radiatively, to secondary luminescent elements in the luminophoric medium and where the diode die and the luminophoric medium are in different enhancing and or protecting optically transmissive enclosures.

When the diode die is placed with a protecting and enhancing enclosure, the diode die is separated from the resin that absent this invention completely covers the diode die; further in this embodiment, the protecting and enhancing enclosure contains within its internal boundaries' material of a gaseous, liquid or solid phase that protects and enhances the generation of primary light or non-radiative energy transfer from the light emitting diode die. When the luminophoric medium is placed with a protecting and enhancing enclosure, the luminophoric medium is separated from the resin that absent this invention completely covers the diode die; further in this embodiment, the protecting and enhancing enclosure contains within its internal boundaries' material of a gaseous, liquid or solid phase that protects and enhances the generation of secondary radiation from the luminophoric medium itself.

Achromatic light LED solid state devices may be made by the method of the present invention. It is preferred in at least some exemplary embodiments that achromatic light, if made, is produced through down-conversion, although there is no requirement that the invention be limited to generating achromatic light nor is the invention limited to achromatic light through down conversion.

In some embodiments, if achromatic light is generated utilizing a down conversion process whereby an excited state that either produces a primary photon—or otherwise is capable of generating a primary photon absent energy transfer—generated in the active region of the diode, then said primary radiation is down converted with primary blue emission and/or secondary blue fluorescent or phosphorescent centers, as well as green and red fluorescent or phosphorescent centers where the fluorescent or phosphorescent centers are within an enclosure and are protected by a vacuum or a beneficial atmosphere or by some other enhancing effect within or impacting an enclosure. These fluorescent and or phosphorescent centers comprise the luminophoric medium. Such a light-emitting diode (LED) device can down-convert the relatively monochromatic light, typical of all heretofore monochromatic light-emitting diode dies and lamps, to a broader emission that appears as achromatic light from red, green, and blue emission centers. Such a device is also able to enhance the efficiency of generation of primary radiation in the absence of luminophors as the beneficial atmosphere augments the generation of primary light by virtue of access of the beneficial atmosphere to the active layer that defines the semiconductor p-n junction. As one skilled in the art will immediately observe, the primary photon generated in the active region of the diode may be a blue photon or an ultraviolet photon, if only one diode die is utilized. There is no requirement that only one diode die be utilized.

Under certain circumstances, it may be desirable for both the light emitting diode die and the luminophoric medium to be enclosed in the same enclosure, in separate enclosures, or only one of the two in an enclosure.

When the luminophoric medium contains luminescent elements that emit red, green and blue light, in the case of a UV LED die, or 1) red, green and blue light; 2) yellow; 3) red, green and yellow, or other suitable combination of primary and complementary colors in the case of a blue LED die, achromatic light is generated.

When two LED die of different wavelengths are used, for example and UV and a blue LED die, then the luminophoric medium can be optimized to generate achromatic light by adjusting in concentration or in space the secondary luminescent elements. It is preferred in at least some exemplary embodiments that the two LED die be of different wavelengths with as large a gap between their respective emission wavelength maximum as possible. When a blue LED die and a cyan LED die are used, then the luminophoric medium will contain secondary luminescent elements that emit in the yellow and in the red. When a UV and green LED die is utilized, then the secondary luminescent elements will be blue and red; when a blue and red LED die are utilized, then the secondary luminescent elements will be green. When a blue LED die and a yellow or amber LED die are utilized, then the secondary luminescent elements need only be adjusted to optimize the color temperature of the achromatic light. The invention is not limited to secondary luminescent elements of multiple molecular compositions (for example, a red emitter, a green emitter, and a blue emitter) as single component emitters are known that generate achromatic light when suitably activated.

In at least some exemplary embodiments, a preferred white-emitting phosphor comprises zinc sulfide activated with copper, manganese, chlorine, and, optionally, one or more metals selected from gold and antimony. In at least some exemplary embodiments, a preferred phosphor is Mn doped ZnS nano clusters with no less than 5% and no more than 9% Mn, prepared from a colloidal route and where ultraviolet-visible absorption curves show that on changing the concentration of Mn²⁺ ions, there is a maximum in the band gap for an optimum doping (5.5% of Mn), and where the fluorescence spectra of the doped clusters consist of two distinct emissions: orange and blue.

It is immediately apparent to a skilled practitioner of the teachings presented herein that achromatic light may be formed by methods other than down conversion and this invention is not limited to the implementation of down-conversion for the generation of achromatic light.

When two light emitting diode dies are utilized at least one must be internal to an enclosure and where the secondary luminescent elements are, if utilized, internal of external to an enclosure, are dependent of optimization of the output and durability of the lamp so constructed. When at least one enclosure contains only luminescent elements and not a semiconductor die, that enclosure just described is replaceable and interchangeable at will.

When both the diode die and dice are in an enclosure and the secondary luminescent elements are in an enclosure, they need not be in the same enclosure for radiative energy transfer to take place; they only need to be in a geometric relationship such that the latter receives a primary radiation emanating from the diode die or dies.

A significant advantage of organic luminescent materials is their relatively broad emission bandwidth that offers the maximal overlap of photon wavelengths to generate an achromatic illumination most readily. Prior to this invention, when multiple luminophors were in use (red, green, and blue luminophors) it had been most desirable to utilize fluorescent materials with extremely short radiative lifetimes, less than 50 nanoseconds, to preclude non-radiative energy transfer (to the lowest energy emitter). However, solid-state lighting requiring an after-glow, illumination provided after the power supply is shut off, is not otherwise available since after-glow devices require luminophors with a lifetime greater than 50 nanoseconds, in fact millisecond lifetimes are more specifically preferred in at least some exemplary embodiments. It is for the most part desirable that fluorescent materials or phosphorescent materials with a radiative lifetime greater than 50 nanoseconds be spatially separated within an enclosure and by virtue thereof, these down-conversion luminophors can continue to provide achromatic or chromatic illumination after the power supply is shut off.

It is for the most part desirable that organic fluorescent materials and organic phosphorescent materials are incorporated within an enclosure under vacuum or noble gas or other inert media so as to avoid the opportunity for oxidation or hydrolysis of the luminophoric medium instantaneous to their excitation or otherwise degrade the luminophoric medium over an extended period of time. It is also desirable for inorganic or ceramic luminophors to be incorporated within an enclosure under vacuum or noble gas or other inert gas or inert liquid or inert solid to avoid the opportunity for quenching with any quencher—a gas, liquid or solid not inert. It is recognized by one skilled in the art that the mechanism by which gases such as nitrogen, argon, krypton, and xenon are utilized in incandescent lamps is different than the mechanism in which it is utilized in this invention and that it has not heretofore been recognized, prior to this invention, that gases have a beneficial effect in the long-term totality of lighting from p-n junctions or in solid-state lighting devices.

The primary utility of gas in incandescent lighting is related to regeneration of the filament first; the utility of a gas also relates to convection and conduction of heat and to prevent the vaporization of the underlying filament element and the inert gas contains a regenerative gas which returns material evaporated from the filament back to the filament. The major utility of gas in the invention being claimed herein is the protection of the secondary luminescent elements within the luminophoric medium from the deleterious effects of oxygen and other quenchers.

Notwithstanding the principal benefit of the invention being claimed herein, it has heretofore not been recognized that the p-n junction—in a LED lamp—itself will benefit from operating in an environment such as claimed herein. The prior art shows no examples of LED die lamps, or solid-state lamps with a p-n junction, whereby the p-n junction used for general illumination lighting is purposely sequestered within an enclosure and that an enclosure contains gas to enhance the performance of primary radiation from the p-n junction itself. It is also desirable for the diode die to be incorporated within an enclosure or otherwise exposed to a noble or inert gas (or inert liquid or inert solid) whereby the index of refraction of the inert media are more closely aligned with the index of refraction of the light emitting diode die.

Notwithstanding the invention itself, others have noted that the operational performance of LED diode die may benefit from dissipation of charge or dissipation of heat and the mechanism by which this has been achieved is using a ceramic heat sink. (Lamina on Metal Ceramic Solutions, “Thermal performance is the key to achieving high luminous densities, high reliability, and long life. Lamina's LTCC-M (low temperature co-fired ceramic) packaging allows LED devices (die) to be mounted directly to an engineered metal core without submounts. This creates the optimum thermal path to conduct heat away from the LED device. The result is that multiple devices can be in proximity while maintaining target LED junction temperatures.”, White LED Light Engine Product Specification Sheet, Lamina Ceramics, Inc., 120 Hancock Lane, Westampton, N.J. 08060.) However, the use of a gas to optimally manage heat, from one enclosure through another, for a solid-state lamp with a p-n junction has not heretofore been taught. Further, in the specific case where the ceramic submount of Lamina are preferred in at least some exemplary embodiments, the method of this invention allows for said submounts to be sequestered within the protecting and enhancing enclosure. However, in at least some exemplary embodiments, the instant invention is one that does not rely on a ceramic heat sink nor may it have an engineered metal core.

In the special case where both the diode die and the secondary luminescent element are sequestered within the same enclosure, it is for the most part desirable that an enclosure that sequesters within it the p-n junction also contain an inert gas or inert liquid or inert solid with excellent heat conduction if the p-n junction is more sensitive to heat than the luminophors so as to remove heat from the p-n junction itself. It is preferential in at least some exemplary embodiments that nitrogen or argon be used as krypton conducts heat less than argon does, and xenon conducts heat less than even krypton does. Note that this embodiment is the opposite of that which is required with incandescence of tungsten filament in a sealed light bulb. It is generally the case that when inorganic luminophors are utilized, the heat insensitivity of these inorganic luminophors is such that it is preferred in at least some exemplary embodiments to dissipate the heat away from the p-n junction. In the case where the light output of the inorganic luminophor requires an elevated temperature in at least some exemplary embodiments, then it is preferred to use nitrogen or argon or other gas with excellent heat conductivity.

It is for the most part desirable that an enclosure that sequesters within it the p-n junction also contains an inert gas or inert liquid or inert solid with poor heat conduction if the p-n junction is less sensitive to heat than the luminophors so as to preclude heating the luminophors themselves. It is preferential in at least some exemplary embodiments that xenon be used as krypton conducts heat less than argon does, and xenon conducts heat less than even krypton does. It is generally the case that when organic luminophors are utilized in at least some exemplary embodiments, the high heat sensitivity of these organic luminophors is such that it is preferred to not dissipate the heat away from the p-n junction.

Environmental effects, such as available with this invention, on luminescence efficiency—even when quenching or its absence is not a factor—is well known. Effects such as spin-orbit coupling—which enhance moving between states of different multiplicities and therefore enhance the efficiency of luminescence when multiplicity changes (i.e., phosphorescence)—can be affected by the environment that the excited state species finds itself in. Sequestering the luminophoric medium that contains a phosphorescent luminescent element within an enclosure as described herein allows for enhancement of the underlying luminescence efficiency by introducing a molecule within an enclosure that interacts with the luminophors therein and which the molecule has a heavy atom effect. The heavy atom effect is well known and is the enhancement of the rate of a spin-forbidden process by the presence of an atom (for example bromine) of high atomic number, which is either part of, or external to, the excited molecular entity. Mechanistically, it responds to a spin-orbit coupling enhancement produced by a heavy atom. (IUPAC Compendium of Chemical Terminology 2nd Edition (1997), 1996, 68, 2245)

Chromatic light LED solid state devices may be made by the method of the present invention. While not necessary to produce chromatic light, it is apparent that the devices of this invention may produce chromatic light, utilizing a down conversion process whereby an excited state that either generates a primary photon or otherwise is capable of generating a primary photon absent non-radiative energy transfer generated in the active region of the diode is down converted with primary blue or primary UV or primary blue and UV emission and/or secondary blue fluorescent or phosphorescent centers, as well as green or red fluorescent or phosphorescent centers where the fluorescent or phosphorescent centers are within an enclosure and are protected by a vacuum or a beneficial atmosphere or by some other enhancing effect within or impacting an enclosure. Such an LED device can down-convert the relatively monochromatic light; typical of all heretofore colored LED dies and lamps, to a broader emission that provides chromatic light from red, green, and blue emission centers. The secondary luminescent elements may be selected and varied as desired, with control of concentrations and spatial arrangements of each selected secondary luminescent element such that the light generated by the luminophoric medium provides color of any hue and apparent tint. Chromatic light with a strong tint is in fact pale color light, for general illumination. Chromatic light with a strong shade is not useful for general illumination but is beneficial for clandestine applications of lighting and signaling. Such a device for chromatic light emission, based on down-conversion, requires a LED solid state device to generate primary light that is either blue or ultraviolet in emission, or can generate primary light that is either blue or ultraviolet in emission absent non-radiative energy transfer, such as is available using blue or ultraviolet LED dies and lamps. It is an essential element of this consideration that either inorganic or organic fluorescent or phosphorescent materials can be utilized to down-convert the primary ultraviolet or blue light emission to a mixture of blue, green, and red luminescent emissions. A significant advantage of organic luminescent materials is their relatively broad emission bandwidth which offers the maximal overlap of photon wavelengths to generate a chromatic illumination most readily. Further, it is most desirable to utilize organic fluorescent material with extremely short radiative lifetimes, less than 50 nanoseconds, to preclude non-radiative energy transfer (to the lowest energy emitter) since an after-glow is not desired in this embodiment. It is for the most part desirable that organic fluorescent materials and organic phosphorescent materials are incorporated within an enclosure under vacuum or noble gas or other inert media so as to avoid the opportunity for oxidation of the luminophoric medium instantaneous to their excitation or over an extended period of time.

A significant part of certain inorganic phosphors is that they can absorb more than one photon prior to radiatively relax to their ground state. This is preferred in the exemplary case of solid-state lighting of the design described herein and where it is observed a saturation of the primary photon absorption. In this exemplary case, it is preferred to maximally down-convert the primary photons, even though the observed saturation occurs with most ceramic phosphors utilized heretofore. It is preferred in at least some exemplary embodiments then to use a ceramic phosphor that can absorb more than one photon and it is preferred that this occurs with luminophors of extremely long lifetime. An excellent ceramic phosphor with extremely long lifetime is SrAl₂O₄ phosphors doped with Eu and Dy. In an exemplary embodiment, the phosphor so identified in the immediately preceding sentence is coated on the interior walls of an enclosure, using dispersion in a binder, and after the film is dried, the layer of selected phosphor is capable of absorbing multiple photons while immobilized within the desired enclosure. The phosphors may also be coated on the sapphire substrate in which a GaN on sapphire LED is constructed.

As discussed above, there have been disclosures regarding the generation of white light in solid state semiconductor devices with p-n junctions using non-radiative energy transfer and these examples use primarily inorganic dopants near the active layers of the p-n junctions or organic fluorescers within the epoxy matrix encapsulating the semiconductor, but none are known that apply the principles of the present invention to semiconductor-based p-n junction LED lamps. It has not been heretofore recognized than organic luminophors can acts as dopants and non-radiative energy transfer will populate the excited states of these luminophors when so arranged to generate secondary radiation.

Absent the invention described herein, the utilization of an isolating and protecting enclosure, said non-radiative energy transfer is not effective. As an example, benzophenone is frequently used as a triplet sensitizer using the mechanism of Dexter energy transfer previously described. Benzophenone when excited enters a singlet excited state and then rather rapidly crosses over into its triplet excited state through a process known to those skilled in the art as intersystem crossing. Once benzophenone triplet is formed—an excited state species that is easily quenched by the ground state of oxygen, itself a triplet, rendering the process sough after basically useless—it can transfer its energy non-radiatively to the ground state (typically a singlet) of a luminophor such as bis(phenyl-ethynyl) anthracene to form the excited triplet state of bis(phenyl-ethynyl) anthracene which is then able to phosphoresce. There is no other means of practically garnering the excited triplet state of bis(phenyl-ethynyl) anthracene other than through non-radiative energy transfer since radiative energy transfer only populates the singlet excited state and the efficiency of intersystem crossing from the singlet excited state to the triplet excited state in bis(phenyl-ethynyl) anthracene is essentially zero. However, as mentioned, triplet benzophenone is easily quenched by oxygen and triplet benzophenone is excellent at destroying through hydrogen abstraction the epoxy resin used normally in potting a LED lamp. Therefore, the invention herein described which includes among its elements a protecting and enhancing enclosure, allows for immobilization of benzophenone within the isolating and protecting enclosure, isolation and protection of benzophenone triplets so formed from quenching by either oxygen or hydrocarbons such as epoxy resin, and non-radiative energy transfer from the protected benzophenone triplet to a luminophor with the emission requirements required to form chromatic, achromatic or non-visible light emission.

As shall be clearer, due to the many structures claimed in the independent claims of the instant invention, multiple FIG.'s are within the Drawing for the purpose of showing all the structures of the claim limitations of all the claims.

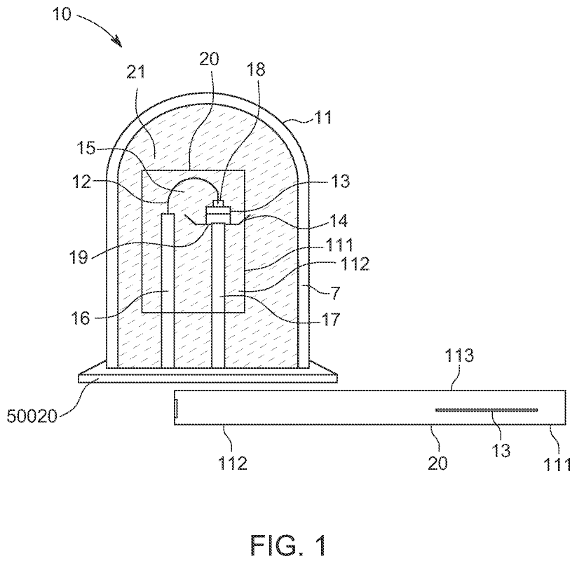

The labeling of parts for FIG. 1:
7 represents an enclosing wall; 10 represents the operable microelectronic device with an enclosure within an enclosure; 11 represents the optically transmissive outer enclosure of this device which forms the outer boundary of this embodiment; 12 represents an electrical lead; 13 represents the light-emitting diode die; 14 represents a support; 15 the interior space of a second enclosure; 16 represents electrical conductors; 17 represents electrical conductors; 18 represents emitting face of light-emitting diode die 13; 19 represents rear faces of light-emitting diode die 13; 20 represents down-converting material; 21 represents the inner space of an outer enclosure; 111 represents an optically transmissive second enclosure of this device; 112 represents interior wall of second enclosure and facing interior space; and 113 represents exterior wall of second enclosure and facing inner space.

Referring now to the Drawing, FIG. 1 shows an achromatic or chromatic or infra-red light emitting diode assembly 10 constructed in accordance with the invention. As the drawings must show every feature of the invention specified in the claims, the instant invention relies upon multiple figures to show all the features of the claim limitations.

With respect to FIG. 1, this assembly teaches an optically transmissive enclosure within an optically transmissive enclosure, a second enclosure as cited in the independent claims of the instant invention, and a metal base. This assembly comprises an enclosing wall 7 defining an optically transmissive glass, plastic, or resin enclosure 11 having an interior volume there within. The enclosure 11, comprising its walls, therefore, may be formed of any suitable material having a optically-transmissive character, such as a clear or translucent polymer, or a glass material. The enclosure 11 along with a second enclosure 111 is referenced as a plurality of optically transmissive enclosures, at least more than one fully within another. A plurality of optically transmissive enclosures, at least more than one fully within another, as shown in FIG. 1 is a substructure that may be incorporated within another FIG. that will reveal at least one outer optically transmissive enclosure. This embodiment shows that the outer enclosure 11 is mounted onto a base 50020.

Referring to FIG. 1, again, a second optically-transmissive enclosure 111—which is an enclosure of this invention—houses in its interior space 15 a light emitting diode (LED) die 13 positioned on support 14. First and second electrical conductors 16 and 17 are connected to the emitting and the rear faces 18 and 19 of LED die 13, respectively, and with the emitting face 18 of the LED die coupled to the first electrical conductor 16 by lead 12.

A second enclosure 111 contains at least one light emitting diode die and reflective supports and is associated with a suitable down converting material 20, e.g., a down-converting medium or luminophoric medium comprising fluorescent and or phosphorescent elements (component(s), or mixtures thereof)—for example a luminophoric medium coated on the interior wall of a second enclosure 111, which functions to down convert the light output from face 18 of LED 13 or reflecting off of surface 19 on which LED 13 rests to achromatic or chromatic or infra-red light. In this respect, this embodiment shown in FIG. 1 not only teaches a plurality of optically transmissive enclosures, at least more than one fully within another, but also teaches at least one light-emitting diode die and luminescent medium within an interior space of a second enclosure. For the avoidance of doubt, this embodiment does reveal the less broadly claim limitation of the instant invention: at least one outer optically transmissive enclosure coupled to a metal base comprising an inert solid or at least one outermost optically transmissive enclosure said enclosure connected to a metal base comprising an inert solid. A plurality of optically transmissive enclosures, at least more than one fully within another, as shown in FIG. 1, is a substructure that will be incorporated within another FIG. that will reveal at least one outer optically transmissive enclosure coupled to a metal base comprising an inert solid or one outermost optically transmissive enclosure coupled to a metal base comprising an inert solid.

The down-converting medium need not be coated on the interior wall of a second enclosure 111 but need only be within the outer wall of a second enclosure 111. The down-converting medium may be dispersed inside a second enclosure and not be attached, physically nor chemically to the interior wall. The second optically transmissive enclosure 111 is under vacuum or is filled with a medium that enhances, instantaneously or over the long term, primary radiation generated by the light emitting diode (LED) die 13 and or enhances, instantaneously or over the long term, the quantity and quality of secondary radiation generated by the luminophoric medium, and or enhances, instantaneously or over the long term the radiative or nonradiative energy transfer from the excited state in the active layer of the LED die 13 to the luminophoric medium. A second enclosure 111 has both an interior wall 112 and an exterior wall 113: the interior wall faces and is in contact with an interior space; the exterior wall faces and is in contact with the inner space. As expressed hereinabove, a light-emitting diode is within the interior space of a second enclosure and the luminescent material is either within the interior space, coated on the inner wall of a second enclosure again being in the interior space, or within the wall of a second enclosure therefore being within the inner space. As expressed hereinabove, the drawing and the detailed description of the FIG. 1 teaches at least one light-emitting diode with a plurality of light-emitting diodes each including at least one p-n junction operable to emit a primary radiation when energized with an electrical connection, positioned fully within at least one second enclosure that isolates the plurality of light-emitting diodes from an outer boundary of said second enclosure, and which defines an interior space.

The active layer of the light emitting diode die is permanently within the space formed by a second enclosure and the reflecting posts onto which the light emitting diode die rests is also contained in the interior volume of a second enclosure. Note that luminophor may be coated on the external wall 113 of a second enclosure 111; in that case, however, the luminophor does not enjoy any additional benefit from the protecting and enhancing material enclosed within a second enclosure but is, in fact, in intimate contact with 21 which comprises a vacuum or a gas within an inner space. For avoidance of doubt, the matter within the interior volume, also called interior space, 15 and 21 in the inner space are representing either a gas or a vacuum or vice versa. Without limiting the scope of this invention, the more broadly teaching of this invention could claim both 15 and 21 in the inner space as a fluid, a liquid or a solid. This FIG. 1 uses different demarcations for interior space and inner space as the claim limitations of a vacuum and or gas that fills these spaces may not be the same. A material sequestered within a second enclosure 111 protects and enhances the emission of primary light as well as secondary light in contrast to gas sequestered within incandescent lamps which primarily regenerate the incandescent filament. This embodiment of the instant invention teaches what is within a second enclosure—both a light-emitting diode and a luminophoric medium—and represents a portion of the claim limitations of the independent claims. Other figures will show this second enclosure within the inner space of an outer optically transmissive enclosure, also required within the independent claim limitations.

In one embodiment, a second enclosure 111 is filled with a gaseous medium that is inert such as argon gas and otherwise limits the oxidation or other means of bimolecular and unimolecular degradation of the luminophoric medium (also called luminescent element) which contains fluorescent centers. Solely for the purpose of manufacturing, a dense inert gas such as argon is preferred in at least some exemplary embodiments so that when sealing a second enclosure, air is kept out of the enclosure and argon is kept inside of the enclosure. However, techniques for sealing enclosures of the type presented herein, with inert gases and electrical leads permeating through an enclosure, such as a glass enclosure is well known and practiced. This embodiment aligns with the claim limitation: . . . to cause the luminescent element to emit a secondary radiation with a Stokes shift wherein the at least one site of a Stokes shift is exposed to a gas. A Stokes shift occurs at that specific site in a luminophoric medium where primary radiation is incident thereupon, effects a successful excitation of to an excited states from which a lower energy photon is successfully emitted spontaneously. A Stokes shift has hereinbefore described is the source of heat that a gas of the instant invention seeks to dissipate to the ultimate external surroundings.

In one embodiment, a second enclosure 111 is filled with a gaseous medium that is inert such as argon gas and otherwise prevents the quenching of the excited state of a phosphorescent component of the luminescent medium that provides secondary radiation after excitation by either primary radiation or non-radiative energy transfer. This embodiment aligns with the claim limitation: . . . to cause the luminescent element to emit a secondary radiation with a Stokes shift wherein the at least one site of a Stokes shift is exposed to a gas. A Stokes shift occurs at that specific site in a luminophoric medium where primary radiation is incident thereupon, effects a successful excitation of to an excited states from which a lower energy photon is successfully emitted spontaneously. A Stokes shift has hereinbefore described is the source of heat that a gas of the instant invention seeks to dissipate to the ultimate external surroundings. Almost every phosphorescent component of a luminescent medium experiences upon activation a Stokes shift as said phosphorescence requires a change in spin multiplicity and the resultant triplet excited state from which spontaneous emission occurs is lower in energy than the singlet excited state from which intersystem crossing takes place. Spontaneous emission is different from stimulated emission in that the former generates radiation from an excited state regardless of how the excited state is formed. The latter generates twice the emission from an excited state, regardless of how the excited state is formed, stimulated by the passage of another radiation. More generally, stimulated emission is the process by which an incoming photon of a specific frequency can interact with an excited atomic electron (or other excited molecular state), causing it to drop to a lower energy level. The liberated energy transfers to the electromagnetic field, creating a new photon with a frequency, polarization, and direction of travel that are all identical to the photons of the incident wave. This is in contrast to spontaneous emission, which occurs at a characteristic rate for each of the atoms/oscillators in the upper energy state regardless of the external electromagnetic field.

In another embodiment, a second enclosure 111 is filled with a gaseous, liquid, or solid medium and whereby the medium, whether completely inert or not, is selected solely for the basis of its index of refraction so that the selected medium has an index of refraction that maximizes the projection of primary radiation and or secondary radiation. Without any intention of limited the full range of materials that can be utilized to practice my invention, we claim the use of the following environment as operable environments when consideration of index of refraction is the most important consideration: in the series of vacuum, helium, argon, krypton, xenon, benzene, epoxy, carbon disulfide, sapphire, flint glass with 81% lead, cubic zirconia, GaN, and crystal iodine the index of refraction changes from 1.00, 1.00, 1.00, 1.29 (liquid), 1.38 (liquid), 1.501, 1.545, 1.63, 1.76, 1.805, 2.173, 2.45, and 3.340. The index of refraction roughly correlates with the density of the material, for organic molecules, the greater the high halogen content, the greater the density and the greater the index of refraction. Hence, methylene iodide has roughly the same index of refraction as sapphire (1.74 for the former vs. 1.77 for the latter), whereas 1-iodo-benzene and iodo-napthalene have refractive indices of 1.62 and 1.704, respectively. Solid medium of utility are zinc oxide (index of refraction of 2.02) antimony oxide (index of refraction of 2.09 to 2.29) zinc sulfide (index of refraction of 2.37), zirconium oxide (index of refraction of 2.40), rutile titanium oxide (index of refraction of 2.70). Many materials that can have high index of refraction have heavy atoms that also enhance spin-orbit coupling. Many organic polymers that are opaque to x-rays and do not degrade because of x-ray irradiation have heavy elements and as a result are inert solids in the context of this invention; moreover, these inert solids with heavy elements have a high index of refraction.

In another embodiment, a second enclosure 111 is filled with a gaseous, liquid or solid medium and whereby the medium, whether completely inert or not, is selected solely for the basis of its dispersion so that the selected medium has a low degree of dispersion of blue, green and red photons so that the achromatic light so formed does not appear to be subsequently dispersed back into their relative components.

In one embodiment, a second enclosure is filled 111 with a liquid solvent that solubilizes the down-converting medium. A liquid solvent is a fluid. Like a gas, a liquid solvent can be used within the interior space of a second enclosure 111 to dissipate heat.

In one embodiment, a second enclosure 111 is filled with a solid inactive matrix, such as a zeolite or a cyclodextrin that sequesters individual molecules of fluorescent components and otherwise limits bimolecular degradation of the fluorescent components. The secondary luminescent element is physically or chemically adsorbed to the zeolite cavity or is otherwise sequestered with a cyclodextrin cavity adopting the methodology of sequestering organic dyes in nano-porous zeolite crystals. (Irene L. Li, Z. K. Tang, X. D. Xiao, C. L. Yang, and W. K. Ge, Applied Physics Letters Vol 83(12) pp. 2438-2440. Sep. 22, 2003) Organic: ceramic hybrids may be used within the enclosure. In one embodiment, the organic luminophor such as a Lumogen derived diimide organic fluorescer is physically immobilized or covalently attached to an otherwise non-luminescent garnet aluminate structure such as an undoped yttrium aluminum garnet or to a doped yttrium aluminum garnet. In another embodiment, the organic fluorescer is immobilized within a xerogel with pores of less than 100 Angstroms. (Design of hybrid organic-inorganic materials synthesized via sol-gel chemistry by C. Sanchez and F. Ribot, New J. Chem., 18, 1007-1047 (1994); Hybrid organic-inorganic materials: The sol-gel approach by J. D. Mackenzie, in Hybrid Organic-Inorganic Composites, pp. 226-236 (1995)) In another embodiment, the dye Rhodamine is immobilized within a silica—zirconia material. In another embodiment, the luminophor, whether organic or ceramic or inorganic is covalently bonded to the wall of an optically transmissive enclosure. Covalently bonding to an optically transmissive enclosure can be achieved by using a silyl-chloride linker between the phosphor and the silicate groups of the silicate glass surface.

In another embodiment, organic fluorescent dye in the higher index of refraction material zirconia may be used. (E. Giorgetti, G. Margheri, S. Sottini, M. Casalboni, R. Senesi, M. Scarselli, and R. Pizzoferrato, “Dye-doped Zirconia-based Ormosil planar waveguides: optical properties and surface morphology”, J. Non-Cryst. Solids, 255, 193 (1999). See also D. B. Mitzi, K. Chondroudis, and C. R. Kagan, “Organic-inorganic electronics”, IBM Journal of Research and Development, Volume 45, Number 1, 2001.)

In one embodiment, LED 13 comprises a leaded, gallium nitride-based LED which exhibits blue light emission with an emission maximum at approximately 450 nm with a FWHM of approximately 65 nm. Such a device is available commercially from Toyoda Gosei Co. Ltd. (Nishikasugai, Japan; see U.S. Pat. No. 5,369,289) or as Nichia Product No. NLPB520, NLPB300, etc. from Nichia Chemical Industries, Ltd. (ShinNihonkaikan Bldg. 3-7-18, Tokyo, 0108 Japan; see Japanese Patent Application 4321,280).

In one embodiment, the down-converting material on the interior of a second enclosure 111 comprises three luminophors, mixed together to form a uniform mixture: a blue fluorescer (Lumogen® F Violet 570—substituted napthalenetetracarboxylic diimide), a green-yellow fluorescer (Lumogen® F Yellow 083-substituted perylenetetracarboxylic diimide) and a red fluorescer (Lumogen® F Red 300—substituted perylenetetracarboxylic diimide). A composition comprising such blue, green-yellow, and red fluorescent materials, all organic based, as incorporated in second enclosure 111, is available commercially from BASF Pigment Division.

In one embodiment, the down-converting material is spatially separated on the interior of a second enclosure 111 and the separate three luminophors are: a blue fluorescer (Lumogen® F Violet 570—substituted napthalenetetracarboxylic diimide), a green-yellow fluorescer (Lumogen® F Yellow 083—substituted perylenetetracarboxylic diimide) and a red fluorescer (Lumogen® F Red 300—substituted perylenetetracarboxylic diimide). A composition comprising such blue, green-yellow, and red fluorescent materials, all organic based, as incorporated in second enclosure 111, is available commercially from BASF Pigment Division.

In one embodiment, the spatially separated materials are printed onto the interior wall using an ink-jet printer; the three luminophors are: a blue fluorescer (Lumogen® F Violet 570—substituted napthalenetetracarboxylic diimide), a green, yellow fluorescer (Lumogen® F Yellow 083—substituted perylenetetracarboxylic diimide) and a red fluorescer (Lumogen® F Red 300—substituted perylenetetracarboxylic diimide). A composition comprising such blue, green-yellow, and red fluorescent materials, all organic based, as incorporated in a second enclosure 111, is available commercially from BASF Pigment Division.

One or ordinary skill will immediately acknowledge from the teachings presented herein that co-mingling multiple luminophors or physically separating them, by ink-jet printing of solutions of the luminophors and curing thereafter, is not limited to the Lumogen fluorescers presented herein in the preceding paragraphs but can be affected with organic luminophors and inorganic luminophors.

In one embodiment, the down-converting material in an interior space of a second enclosure 111 comprises a blue fluorescer (Lumogen® F Violet 570—substituted napthalenetetracarboxylic diimide), a green, yellow fluorescer (Lumogen® F Yellow 083-substituted perylenetetracarboxylic diimide) and a red fluorescer (Lumogen® F Red 300—substituted perylenetetracarboxylic diimide). At the same time, on the exterior wall 113, of a second enclosure 111 is coated an inorganic phosphor such as Ce³⁺ doped yttrium aluminum garnet. A composition comprising such blue, green-yellow, and red fluorescent materials, all organic based, incorporated within second enclosure 111, is adjusted by virtue of adjusting the concentration of materials, to match the “Commission Internationale de l'éclairage”, known in English as the International Commission on Illumination (CIE), coordinates of the inorganic Ce³⁺ doped yttrium aluminum garnet film on the outer wall of a second enclosure 111. In this manner, the operational performance of the solid-state device is prolonged by virtue of two identical luminescent elements of differing operations but identical photopic response.

In one embodiment, the ceramic phosphor written as Re₃(Al₁ₛGaₛ)5O₁₂:Ce³⁺:xMAl₂O₄ wherein Re is a rare earth selected from the group consisting of yttrium, gadolinium, and ytterbium; s is equal to or greater than 0 and less than or equal to 1; x is 0.01 to about 1.0%; and M is an alkali or alkaline earth metal is suspended as an emulsion with a polymerizable binder such as polyvinyl alcohol or polyvinylpyrrolidone-polyvinyl alcohol. A fixed amount of the phosphor binder material is applied to an inner wall of a second enclosure 111 and the binder is then polymerized to form a robust phosphor thin film directly on an inner wall. Polymerization can be carried out using photo-initiation or thermally induced polymerization after which a second enclosure is used to assemble the LED lamp. Thus, the present invention includes using two-phase phosphors; a method of applying these two-phase phosphors to a second enclosure that coats an inner surface of a second enclosure and which said second enclosure is ultimately comprising a vacuum or a gas selected from ammonia or other Lewis base, nitrogen, argon, xenon, and or krypton to make a LED lamp to produce achromatic light.

In one embodiment, the ceramic phosphor written as Re₃(Al₁ₛGaₛ)5O₁₂:Ce³⁺:xMAl₂O₄ wherein Re is a rare earth selected from the group consisting of yttrium, gadolinium, and ytterbium and where the composition and structure of the ceramic phosphor is determined by magic angle spinning NMR as opposed to electron dispersive X-Ray (EDX) analysis which, when carried out, yields at best an elemental composition but not the actual chemical structure of the luminescent materials; s is equal to or greater than 0 and less than or equal to 1; x is 0.01 to about 1.0%; and M is an alkali or alkaline earth metal is suspended as an emulsion with a polymer binder such as polyvinyl alcohol or more polyvinylpyrrolidone-polyvinyl acetate and applied to an inner wall of an enclosure as already described. A suspension of titanium dioxide is applied to the outer wall of a second enclosure and similarly polymerized to form a robust scattering layer; after which a second enclosure is used to assemble the LED lamp. Thus, the present invention includes using two-phase phosphors; a method of applying these two-phase phosphors to a second enclosure that coats an inner surface of said second enclosure and which said second enclosure is ultimately containing a vacuum or a gas, within its interior space, selected from ammonia or other Lewis base, nitrogen, argon, xenon, and or krypton to make a LED lamp, with a thin film of scattering particles on an outer wall 113 of a second enclosure 111, therein to produce achromatic light emanating from a Lambertian surface.

In one embodiment, a protective layer comprising Al₂O₃, Y₂O₃ or a rare-earth oxide should be applied between an interior wall 112 of a second enclosure 111 and the phosphor layer.

In one embodiment, the down-converting material on the interior of a second enclosure 111 comprises a blue fluorescer (Lumogen® F Violet 570—substituted napthalenetetracarboxylic diimide), a green, yellow fluorescer (Lumogen® F Yellow 083-substituted perylenetetracarboxylic diimide) and a red fluorescer (Lumogen® F Red 300—substituted perylenetetracarboxylic diimide). At the same time, on the exterior wall 113, of a second enclosure 111 is coated an inorganic phosphorescent phosphor such as the spinel europium doped strontium aluminate SrAl₂O₄:Eu. A composition comprising such blue, green-yellow, and red fluorescent materials, all organic based, incorporated within second enclosure 111, is adjusted by virtue of adjusting the concentration of materials, to match the CIE coordinates of the inorganic europium doped strontium aluminate film on the outer wall 112 of a second enclosure 111. In this manner, the operational performance of the solid-state device is prolonged by virtue of two identical luminescent elements of differing operations but identical photopic response. Further, with removal of electrical current the excited states of spinel europium doped strontium aluminate SrAl₂O₄:Eu continues to provide chromatic illumination.

In one embodiment, the down-converting material on the interior of a second enclosure 111 comprises a ceramic phosphor such as Ce³⁺ doped yttrium aluminum garnet film on an inner wall 112 of a second enclosure 111. At the same time, on the exterior wall 113, of a second enclosure 111 is coated an inorganic phosphorescent phosphor such as the spinel europium doped strontium aluminate SrAl₂O₄:Eu. In this manner, the operational performance of the solid-state device is prolonged by virtue of two identical luminescent elements of differing operations. Further, with removal of electrical current the excited states of spinel europium doped strontium aluminate SrAl₂O₄:Eu continues to provide green or yellow-green chromatic illumination. It is clear from the preceding discussion that in this embodiment, an inorganic phosphorescent phosphor on the exterior wall of a second enclosure means that the phosphor faces and is in contact with the inner space. In the additional case that the inner space contains a gas, then an inorganic phosphorescent phosphor in this embodiment is with a Stokes shift and at least one site of a Stokes shift is exposed to a gas.

In one embodiment, the down-converting material on the interior of a second enclosure 111 comprises a ceramic phosphor such as Ce³⁺ doped yttrium aluminum garnet film on an inner wall 112 of a second enclosure 111. At the same time, on the exterior wall 113, of a second enclosure 111 is coated an inorganic phosphorescent phosphor such as the strontium sulfide (SrS) activated with divalent europium or SrS:Eu doped with any trivalent rare earth ions, such as holmium (Ho), erbium (Er), neodymium (Nd) and the like. In this manner, the operational performance of the solid-state device is prolonged by virtue of two identical luminescent elements of differing operations. Further, with removal of electrical current the excited states of strontium sulfide continue to provide red chromatic illumination.

A light-emitting diodes 13 can be comprised of either or both gallium nitride and silicon carbide which are suitable for generating light at appropriate wavelengths and of sufficiently high energy and spectral overlap with absorption curves of the down-converting medium. In the case where radiative energy transfer is implemented, a light-emitting diode is selected to emit most efficiently in regions where luminescent dyes may be usefully employed to absorb wavelengths compatible with readily commercially available fluorescers and/or phosphors for down conversion to achromatic or chromatic light. In the case where non-radiative energy transfer between the excited state of the hole-electron recombination and the ground state of the luminophors in the luminophoric medium is implemented, a light-emitting diode is selected to allow the wavefunctions that define the excited states formed by hole-electron recombination to integrally overlap with the wavefunctions that define the excited states of the fluorescers and or phosphors used in the luminophoric medium. In the case where non-radiative energy transfer between the excited state of at least one luminophor in the luminophoric medium, a luminophor of the first kind, and the ground state of at least one other luminophor in the luminophoric medium, a luminophor of the second kind, is implemented, the luminophor of the first kind is selected to allow the wavefunctions that define the excited state of the luminophor of the first kind to integrally overlap with the wavefunction that defines the excited state of the fluorescers and or phosphors used as the luminophor of the second kind.

The luminophoric medium utilized in the light emitting assembly of the present invention thus comprises a down-converting material which may include suitable luminescent dyes which absorb the radiation emitted by a light-emitting diode or other solid-state device generating a primary radiation, to thereby transfer the radiation energy to the fluorescer(s) and/or phosphor(s) for emission of white light. Alternatively, the luminophoric medium may comprise simply the fluorescer(s) and/or phosphor(s), without any associated mediating material such as intermediate luminescent dyes, if the fluorescer(s) and/or phosphor(s) are directly excitable to emit the desired white light. It is preferential in at least some exemplary embodiments that at least portions of the luminophoric medium be enclosed with second enclosure 111 although certain elements of the luminophoric medium may be external to a second enclosure if some of the luminophoric medium is internal to a second enclosure 111.

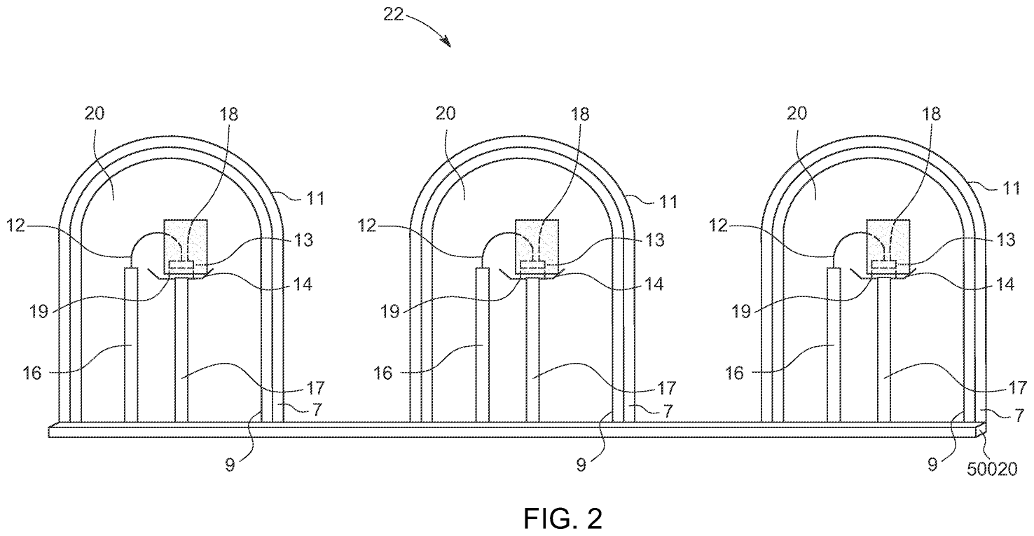

The light emitting assembly 22 shown in FIG. 2, specifically an array 22, has the same general structure as is shown in FIG. 1 (with the same reference numerals of corresponding identical parts for ease of reference and as required), but in place of the semiconductor support being placed within a second enclosure 111, the semiconductor support—but not the semiconductor itself—is external to a second enclosure 111 and therefore also supports the placement of a second enclosure. It is emphasized that FIG. 2 shows an array 22 of otherwise identical light-emitting diodes each of which has an optically transmissive second enclosure within an optically transmissive outer enclosure. The claim limitations of the instant invention are less broad than this embodiment however this embodiment shown in FIG. 2 is a substructure detailed more fully in another figure(s) that teaches, when combined, all features of the claim limitations. The array is secured to a metal base 50020.

In this embodiment, illustrated in FIG. 2, the light emitting assembly utilizes a fluorescer within a second enclosure 111 that is responsively and radiatively excited by the primary photons from the semiconductor p-n junction. The fluorescer in such embodiment may be either covalently or non-covalently attached to an inner wall 112 of a second enclosure 111 or sequestered within the structural form itself that defines the wall of a second enclosure 111, and/or coated as an interior film of the fluorescer on the interior wall surface of the housing wall 112. Alternatively, the fluorescer may be in solution and sequestered within the sealed inner enclosure of a second enclosure 111 or dispersed in a glass or polymeric matrix sealed and sequestered within the sealed inner enclosure of a second enclosure, and/or in the vapor state and sequestered within the sealed inner enclosure of a second enclosure 111. The material sequestered within a second enclosure 111 protects and enhances the emission of primary light as well as secondary light in contrast to gas sequestered within incandescent lamps which primarily regenerate the incandescent filament. The luminophoric medium may also be physically or chemically attached to the substrate of the diode die or to exposed active layer regions of the die itself. The luminophoric medium may also be coated on the interior of wall 7 of the outer enclosure 11 yielding a layer 9 of luminophoric medium in touch with the inner space of the outer enclosure.

Comparing the substructures of the FIGS. 1 and 2 assemblies, it is seen that the semiconductor support in the FIG. 1 embodiment is contiguously arranged about the LED die structure in the interior volume of the housing, while the semiconductor support in the FIG. 2 embodiment is disposed in spaced relationship to the light-emitting diode die structure. It will be apparent that the specific arrangement of the solid state device such as light-emitting diode 13, relative to the down-converting medium of the assembly and supports, may be widely varied in the broad practice of the invention, it being necessary only that the solid state device functioning as the source of the primary shorter wavelength radiation be in transmitting relationship to the recipient luminophoric medium, so that the latter functions in use to down-convert the transmitted radiation from the solid state device and responsively thereto emit achromatic light or chromatic light or infra-red light. When the luminophoric medium is distant from the active layer of the p-n junction by more than 50 Angstroms, then only radiative energy transfer is operable and non-radiative energy transfer is not possible. In that the embodiment of the substructure described in FIG. 2 is not particularly different than the substructure implementation described in FIG. 1, it is clear from the previous teachings that many different luminophors and secondary luminescent elements may be used, and that two-diode die may be used as well as one. Therefore, for the sake of simplification but not to otherwise limit the scope of this invention, we will limit our discussion of all the embodiments available when FIG. 2 represents the implementation of this invention better than FIG. 1 and refer those of ordinary skill to the teachings already utilized to describe embodiments of this invention represented by FIG. 1.

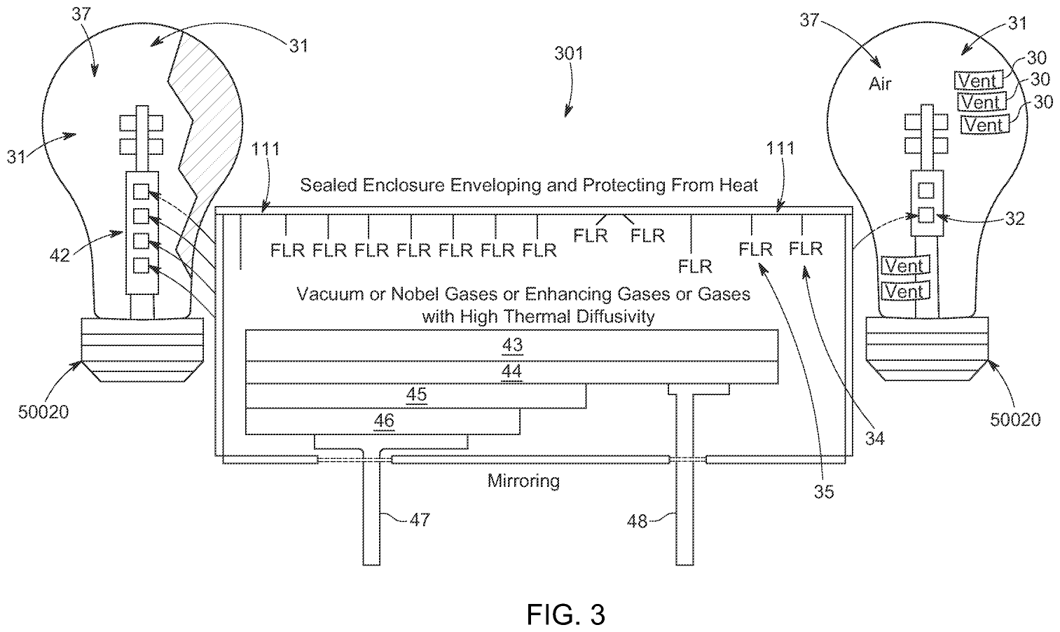

The substructures detailed in FIG. 1 and FIG. 2 are different than that of the device 301 defined by the FIG. 3 as explained more fully hereinafter. There are two variants defined in FIG. 3, one with a sealed outermost enclosure and one with an outermost enclosure that is comprised of opened vents. Recall that the substructures described in FIG. 1 and FIG. 2 already have an enclosure within an enclosure. Hence, if the substructures described in FIG. 1 and FIG. 2 are used in FIG. 3, as light-emitting diode part 32 then it is proper to say the nested enclosures are of an inner enclosure within an enclosure within an outermost enclosure (a triply nested set of enclosures). This triply nested set of enclosures is aligned with the claim limitation of . . . a plurality of optically transmissive enclosures, at least more than one fully within another. Another embodiment of the instant invention is shown for substructure 32 or the array 42 when substructure 10 or substructure 22 are replaced by a light-emitting diode and luminophoric medium in a single enclosure 301. Referring to FIG. 3, the drawing sheet shows a light-emitting diode in a single enclosure and when incorporated into one of the two outer enclosure variants thereby making an enclosure within an enclosure, this single enclosure is more properly defined as a second enclosure. The sealed outermost optically transmissive enclosure or the variant of an outermost optically transmissive enclosure with opened vents, is therefore not confined to incorporating substructure 10 in FIG. 1 or substructure 22 in FIG. 2.

In FIG. 3, the placement of the light emitting diode die within a second enclosure 111 is more noticeably described. In this embodiment, the luminophoric medium and the light-emitting diode are again in a second enclosure 111. This second enclosure substructure is an enclosure by itself and not an enclosure within an enclosure. As shown in FIG. 3, a second enclosure 111 is part designator 32 when placed within an outermost optically transmissive enclosure 31. Part designator 32 represents more than one light-emitting diode within enclosure 111 and is shown as either a single light-emitting diode in enclosure 111 or an array of light-emitting diodes 42 in enclosure 111.

In this embodiment displayed in FIG. 3, the luminescent medium is attached to an inner wall of a second enclosure 111 and or to the alumina (sapphire) substrate 43 that defines the diode die. The physical location of dyes or fluorescers specifically formulated into the luminophoric medium internal to a second enclosure which may for example include a ceramic non-luminescent dispersant in which the organic dyes and/or fluorescers are adsorbed and or otherwise dispersible, is not specifically limited, and fitting amount(s) of suitable material(s) for such purpose can be readily determined without undue experimentation, to provide good achromatic, or chromatic light emission (of virtually any tint or hue), as well as a virtually infinite series of chromaticity for all visible hues. In FIG. 3 and in an exemplary embodiment, without limiting the scope of this invention, the down-converting medium is covalently attached to an inner wall of a second enclosure 111. In the embodiment where the luminophoric medium is covalently attached to the light emitting diode die as opposed to an inner wall of a second enclosure and is immobilized as such to be within 50 Angstroms of the active region of said diode die, then non-radiative energy transfer is allowed, and down-conversion occurs without the requirement of radiative energy transfer.

An embodiment of the implementation of this invention as described by FIG. 3 is for a gas to be sequestered within a second enclosure 111 and for a gas to protect and enhance a primary radiation emanating from the p-n junction and or the secondary luminescent elements. In this embodiment, a gas is within an interior space 35. Therefore, the light-emitting diode and the luminophoric medium are both in the interior space and both are in a second enclosure. This gas or gases is described as a Vacuum or Noble Gases or Enhancing Gases or Gases with High Thermal Effusivity. The light-emitting diode comprises more than one layer including 44, 45, and 46 upon substrate 43. Layer 46, is the p-doped layer of a semiconductor; 45, is the active layer which contained the p-n junction; 44, the n-doped semiconductor layer; and 43, the substrate comprised of alumina or silicon carbide. Since the interior space is filled with gas or gases within a second enclosure, as is the luminophoric medium, then a site of a Stokes shift is exposed to a gas or gases, as within the claim limitations sought herein.

When achromatic light is the desired output of the device described by FIG. 3, down-conversion is an implementation method for generation of achromatic light with down-conversion described completely in this invention and in others. However, the full scope of this invention is not contingent on down-conversion being the sole method of implementation for achromatic light and the invention is still operable regardless of whether the secondary luminescent elements are present in FIG. 3 and regardless of whether achromatic light is the result there from. The device is operable absent the secondary luminescent element and that the device is operable when chromatic light is the desired and resultant output.

However, one of ordinary skill will note, from the complete teachings of this invention presented herein that the device described in FIG. 3 may contain two diodes die and that the secondary luminescent elements may be activated not by down-conversion but by other processes—thermoluminescence and electro-luminescence being two implementations. When the immobilized and covalently attached secondary luminescent elements are activated by an applied electric field, contacts need to be provided to the secondary luminescent elements although said contacts are not shown in the FIG. 3 for sake of simplicity. Regardless of the mechanism by which a secondary luminescent element is activated, the medium inside the enclosure that provides a protecting and enhancing effect is preferred in at least some exemplary embodiments to be a gas but need not be matter solely of a gaseous state. If a gas, then it is preferred in at least some exemplary embodiments that a gas protect and enhance by exclusion and reduction of oxidative steps which would otherwise degrade and or quench the secondary light emission. For reasons previously taught, it is preferred in at least some exemplary embodiments that a gas be nitrogen, argon, krypton and or xenon and or mixtures thereof. The protecting and enhancing gas may include other gaseous elements that protect and enhance not only the secondary luminescent elements but the p-n junction and the mechanism by which primary light is generated. A gas also dissipates the heat generated at the p-n junction.

An ultraviolet light-emitting diode light source suitable for use in the structure of FIG. 1 or FIG. 2 or FIG. 3 may comprise: aluminum gallium indium nitride; aluminum gallium nitride; indium gallium nitride; gallium nitride or any other ultraviolet emitting diode. A blue light-emitting diode light source may be based on: indium gallium nitride; silicon carbide; zinc selenide; or any other blue light emitting diode source.

TBP, Coumarin-6 and DCM-1, as described by Kido et al. in European Patent EP 647694, are suitable materials for down conversion of the output of gallium nitride or silicon carbide light-emitting diodes. Gallium nitride and its alloys can emit in the spectral range covering the blue and ultraviolet extending from wavelengths of 200 nanometers to approximately 650 nanometers. Silicon carbide light-emitting diodes emit most efficiently in the blue at wavelengths of around 470 nanometers.

If gallium nitride emitters are employed in at least some exemplary embodiments, preferred substrates for the emitters include silicon carbide, sapphire, gallium nitride and gallium aluminum indium nitride alloys, and gallium nitride-silicon carbide alloys, for achieving a proper lattice match. If gallium nitride emitters are employed, the fluorescent and phosphorescent centers may be covalently linked to the substrate surface. If sapphire is the substrate, non-covalent chemical and physical adsorption of the fluorescent and or phosphorescent centers to the sapphire substrate may be employed. If desired or if covalent linkage and or chemical and physical adsorption of the fluorescent and or phosphorescent centers to the substrate on which the gallium nitride device is constructed is disadvantageous, then another layer, such as a silicon dioxide layer may be applied to the substrate or to the gallium nitride so as to provide a platform for the covalent, chemical or physical adsorption of the fluorescent and or phosphorescent centers.

With ultraviolet or blue light light-emitting diodes, aromatic fluorescers may be employed as down-converting emitters. By way of example, suitable fluorescers could be selected from:
1) blue luminescent compositions—9,10-diphenylanthracene; 1-chloro-9,10diphenylanthracene; 2-chloro-9,10-diphenylanthracene; 2-methoxy-9,10diphenylanthracene; Lumogen® F Violet 570 (a substituted napthalenetetracarboxylic diimide); Alq2OPh (where Al is aluminum, q is 8-hydroxyquinolate, and Ph is phenyl);
2) green-yellow luminescent compositions—9,10-bis(phenyl-ethynyl) anthracene; 2-chloro-9,10-bis(phenyl-ethynyl)-anthracene; Coumarin-5 also known as (7-diethylamino-3-(2′benzothiazoyl-)coumarin); Lumogen® Yellow 083 (a substituted perylenetetracarboxylic diimide); and Mq3 (where M is a Group III metal, such as Al, Ga or In, and q is 8-hydroxyquinolate); and
3) red-orange luminescent materials—DCM-1; Lumogen® F Red 300 (a substituted perylenetetracarboxylic diimide); Lumogen® F Orange 240 (a substituted perylenetetracarboxylic diimide); tetraphenyl-naphthalene; zinc phthalocyanine; [benzoyl-thiazoylidene)-methyl] squaraines; tris(bipyridine-ruthenium)2+; and [3]-catenand complexes with copper.

When luminescent dyes are required that emit towards the red and which are capable of being excited non-radiatively as described more fully elsewhere in my present invention, the dyes may include so-called CyDyes from GE Healthcare: (Fluorophore, Color of fluorescence, Absorption Maximum, Emission Maximum)—Cy3, Orange 550 nm, 570 nm; Cy3.5, Scarlet, 581 nm, 596nm; Cy5, Far-red, 649 nm, 670 nm; and Cy5.5, Near IR, 675 nm, 694 nm. The Alexa Fluor series of dyes from Invitrogen nay also be used as many have absorption maxima near the maximum of primary radiation emanating from GaN semiconductors. More specifically the dye Alexa Fluor® 430 carboxylic acid, succinimidyl ester may be used to covalently attach to suitably prepared ceramic media and or glass wall enclosures (e.g., amine derivatized) or a metal base comprising a partially inert solid, and where said dye absorbs blue light with one maximum at 450 nm. The dye may be used to form a derivatized yttrium aluminum garnet without undue experimentation such that the new composition of matter contains both an inorganic luminescent element, such as a cerium dopant, and an organic luminescent element.

The luminophoric medium may or may not exist external to an enclosure at the same time the luminophoric medium is internal to an enclosure. The medium in which the fluorescent and or phosphorescent centers that are external to an enclosure may include a polymeric matrix or any other matrix and need not be identical to the medium of the luminophoric medium internal to the cavity or enclosure. When the external luminophoric medium contains a ceramic phosphor, it is preferential in at least some exemplary embodiments that the ceramic phosphor be a yttrium aluminum garnet phosphor in general or a Ce³⁺ doped yttrium aluminum garnet more specifically and that the internal luminophoric center contain, at the same time, a green luminescent fluorescers such as 9,10-bis (phenyl-ethynyl) anthracene. When it is desirable that Ce³⁺ doped yttrium aluminum garnet be used in intimate contact with 9,10-bis(phenyl-ethynyl) anthracene, then both luminophors, or a new composition of matter that contains the covalent addition of the anthracene to the active oxygen of garnet or other ceramic phosphors, or related chemical and physical adsorption of the former to the latter, are sequestered within the sealed second enclosure 111.

Even more preferred in at least some exemplary embodiments is to covalently attach an organic fluorescer, such as pyrene, to an inert solid matrix that protects the organic fluorescer, such as a zeolite or if it is preferred that the solid matrix emits light, cerium doped yttrium aluminum garnet. Pyrene with a chemical linker arm such as hexamethylene bromide reacts with aluminum oxide based luminophors such as anhydrous cerium doped yttrium aluminum garnet or strontium aluminate to form a new composition of matter: pyrene-(CH2)6YAG:Ce3+.

In one embodiment, cerium doped yttrium aluminum garnet prepared according to a well-known method used by many practitioners (Wang et. al., U.S. Pat. No. 6,717,349) is suspended in organic solvent and a red-orange derivative of Lumogen® F Red 300—derivatized with a methylene-acyl-chloride or like linker arm—is suspended in the same solvent. After a suitable period to ensure that all the cerium doped yttrium aluminum garnet is covalently attached to the Lumogen® F Red 300 luminophor with a CH2—CO— linker arm molecularly inserted thereto, and where the linker arm is incorporated into the Lumogen® F Red 300 without undue experimentation (See for example, linker arm procedures as in Reynolds, et. al.; Canadian Patent Application CA 2089087; also M. J. Heller, Canadian Patent Application CA 2123133. An excellent reference for “like linker arm” can be found in Waggoner, et. al.; U.S. Pat. No. 6,673,943; issued date Jan. 6, 2004, and references incorporated therein.), red enhanced cerium doped yttrium aluminum garnet, a molecular composition different than the underivatized cerium doped yttrium aluminum garnet is isolated with removal of the reaction solvent. The red enhanced yttrium aluminum garnet composition of matter is suspended in a mixture of a casting polymer and a solvent, and a film is sequestered within the sealed second enclosure 111 of FIG. 2.

The amount of dyes or fluorescers specifically formulated into the external luminophoric medium, which may for example include a polymeric matrix or other matrix material in which the dyes and/or fluorescers are soluble or dispersible, is not specifically limited, and suitable amount(s) of suitable material(s) for such purpose can be readily determined without undue experimentation, to provide good achromatic, or chromatic light emission (of virtually any tint or hue), as well as a virtually infinite series of chromaticity for all visible hues.

The amount of dyes or fluorescers specifically formulated into the luminophoric medium internal to an enclosure or cavity, which may for example include a ceramic non-luminescent dispersant in which the organic dyes and/or fluorescers are adsorbed and or otherwise dispersible, is not specifically limited, and suitable amount(s) of suitable material(s) for such purpose can be readily determined without undue experimentation, to provide good achromatic, or chromatic light emission (of virtually any tint or hue), as well as a virtually infinite series of chromaticity for all visible hues.

The concentrations of the fluorescers may suitably be determined by both their luminescence quantum yields and spectral distribution, as required to define a particular color by its respective chromaticity coordinates, as well as, in the case of radiative energy transfer (but not Förster energy transfer), the absorption extinction coefficients of the associated fluorescer(s). Such fluorescers may for example be blue light fluorescers used with a blue-emitting semiconductor-based light-emitting diode die, or ultraviolet light fluorescers used with a UV-emitting semiconductor-based light-emitting diode die. While the concentrations of the various dyes may be suitably adjusted to realize the required colors, the range of dye concentrations typically will be between 10⁻³ to 10 mole percent for each individual fluorescent component.

The light-emitting assemblies shown in FIGS. 1 and 2 and 3 may be made in any suitable size and dimensional character. In application to displays, such light emitting assemblies will generally be of a size commensurate with the size of fluorescent or incandescent lamps used in similar displays.

FIG. 3 shows an embodiment of the instant invention more broadly than that which is claimed. The additional claim limitation that is shown in FIG. 3 is a metal base comprised of an inert solid. FIG. 3 does show more broadly the embodiment in which a metal base 50020. To ensure that the metal base retains its function upon arduous conditions, it is preferable that the metal base conduct heat and be of an inert solid. The metal base 50020 is cojoined with the outermost enclosure to form the external boundary of the microelectronic device or the solid-state light-emitting device. The electrical contacts 41 and 42, to power the light-emitting diode may be connected to the metal base if the metal base also conducts electricity. It is not necessary for the metal base comprised of an inert solid to be electrically conducting, only heat conducting; if not, then electrical leads to the semiconductor contacts need to be through the metal base or the optically transmissive enclosure.

The following method is sufficient to coat a ceramic phosphor onto an inner wall of a second enclosure 111:
1. An aqueous solution of polyvinyl alcohol (PVA) is made by adding 5 grams of PVA powder to 200 ml of water. The mixture is heated to 85° C. with stirring for one hour, then cooled to room temperature, and refrigerated at 2° C. overnight.
2. YAG: Ce³⁺ (0.75 gram) having a particle size of from about 2-9 microns, is added to 1.5 ml of the above solution, and shaken for 5 minutes to form a phosphor slurry.
3. The slurry is applied with a micro syringe or an injection nozzle to inner wall of a second enclosure. The typical volume of the phosphor slurry applied to each die can be about 1.5 micro liters.
4. A second enclosure is baked in an oven at 130 degree. C. for 5 minutes to polymerize the binder.

Another method that may be used to practice the claims of this present invention is using a nanophase binder system as described more completely elsewhere. (M. A. Johnson, et. al.; Canadian Patent Application CA 2330941) The phosphor impregnated binders are coated within an enclosure of the present invention where the phosphors selected need not be limited to the luminophors identified by M. A. Johnson et. al. but where the binders identified therein are used to apply phosphors where the phosphors are selected from the embodiments presented in this present invention as disclosed herein.

Ceramic phosphors used in such a manner may also include those from Nemoto Chemie Co., Ltd.; Tokyo 167-0043, Japan: CaAl₂O₄:Eu²⁺Nd³⁺ (blue emitter with an emission maximum at 440 nm; excitation peak at 325 nm); SrAl₁₄O₂₅:Eu²⁺, Nd³⁺ (blue-green emitter with an emission maximum at 490 nm; excitation peak at 365 nm); SrAl₂O₄:Eu²⁺, Nd³⁺ (green emitter with an emission maximum at 530 nm; excitation peak at 365 nm).

In one embodiment, the red, green and or blue luminophors when using an ultraviolet light-emitting diode die or 1) red and green or 2) red, green and yellow, or 3) red, green yellow and blue, or 4) red, green blue, yellow and cyan luminophors are printed onto the surface of the protecting and enhancing enclosure using ink-jet printing where the image of colored luminescent inks is optimized to create the appearance of white light from all viewing angles and or all angle on which the light falls on to a surface.

In one embodiment, the red, green and or blue luminophors when using an ultraviolet light-emitting diode die or 1) red and green or 2) red, green and yellow, or 3) red, green, yellow and blue, or 4) red, green blue, yellow and cyan luminophors are printed onto the surface of the protecting and enhancing enclosure using ink-jet printing and where the enhancing enclosure is replaceable and interchangeable at will. In this case, for example a white light light-emitting diode lamp utilized in an automobile, the light will last if the functioning of the light-emitting diode die and the changes in color over time can be immediately reversed by inserting a replacement enhancing enclosure or enclosure containing different and newer luminescent elements.

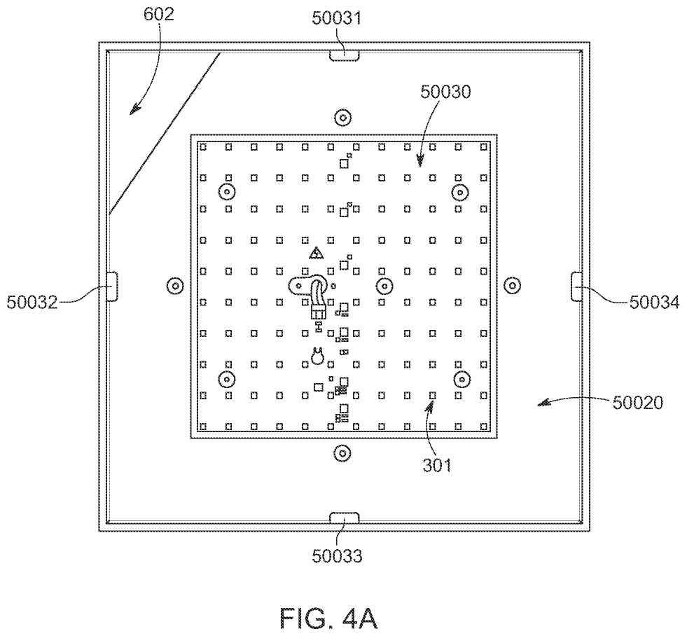

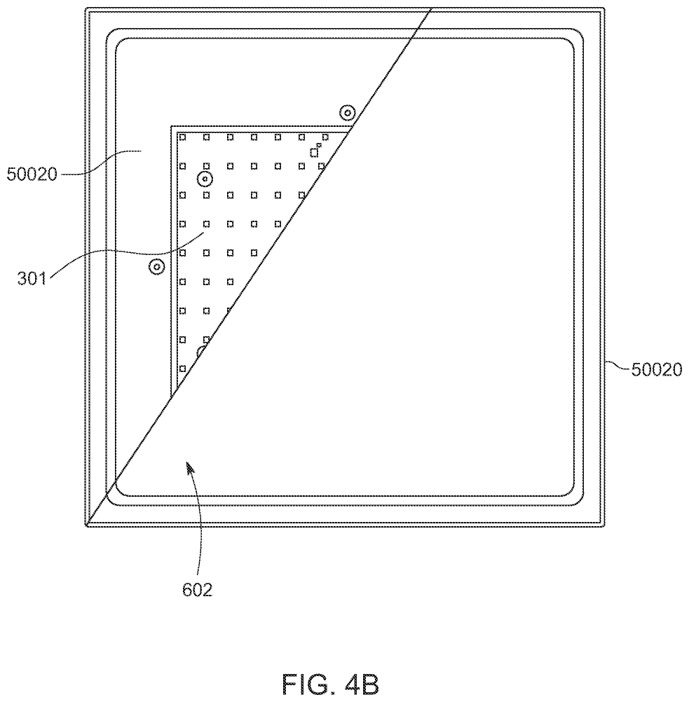

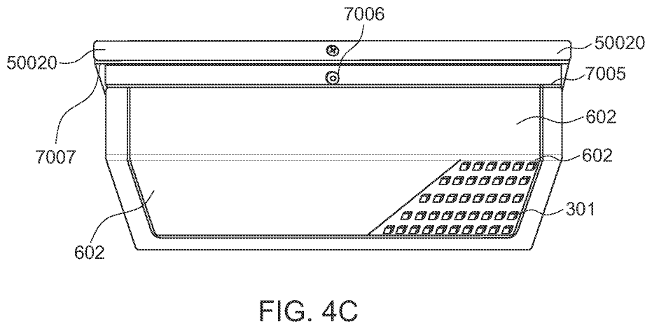

FIG. 4A, FIG. 4B and FIG. 4C are different views of one embodiment of the instant invention and aligns with the less broadly claim limitations of the instant invention. Most importantly, these different views of one embodiment teaches the metal base “50020” to be one that is flat, is comprised of an inert solid, and is contiguous, when joined, with an optically transmissive enclosure shown as 602 in the view in FIG. 4A, FIG. 4B and in FIG. 4C. The cut-away of the optical transmissive enclosure 602 shows the flat metal base comprised of an inert solid attached to an assembly of an array of light emitting diodes, each of which has an interior space defined by a secondary enclosure 111. The light-emitting diodes each within a second enclosure is labeled as 301, the same demarcation for a light-emitting diode in the interior space of a second enclosure as shown in FIG. 3. Since each light-emitting diode is in a second enclosure with an interior space, and the more than one second enclosures are all within one optically transmissive enclosure 602, then this embodiment is of an enclosures within an enclosure.

With respect to the collective figures FIG. 4A, FIG. 4B and FIG. 4C, a microelectronic device or solid state optically transmissive device has a removable cover 602 to allow mounting of a metal base of the fixture to a flat surface such as a wall or a ceiling. A device as shown may be called a luminaire. The luminaire is defined for example, as herein used, as the entire construction around the light source. It may consist of several components such as mounting, lamp-holder, reflector, shade and or cover. Inside the luminaire is the actual light source, which is called the illuminant. Not all components mentioned may be included in the final construction for the assembly to be a luminaire. The light-emitting diode arrays are the illuminant. Each array is separately powered by leads dispersed in a polymer matrix and connected to each light-emitting diode in one array.

We refer to one embodiment as shown in FIG. 4C (e.g., including 7005 and 7007) whereby in at least some exemplary embodiments the panel-facings 602 collectively comprise the at last one optically transmissive enclosure which is removable from a metal base 50020 to which the combination of both is the outer enclosure which form the outer boundary of the light fixture. The optically transmissive panel-facings which form the optically transmissive enclosure may be of glass or of plastic and may be permanently connected to each other, as of one piece, or maybe separate pieces so as when assembled, together, form the bottom part of the overall enclosure.

In FIG. 4C in at least some exemplary embodiments, a metal base 50020 for the topmost portion of the enclosure and is normally used in a way it is mounted on a wall or a ceiling or some other optically opaque surface. This metal base 50020 is a flat metal base comprised of an inert solid. One view of this lighting fixture is shown in a two-dimensional view in FIG. 4B, looking perpendicular to the fixture as if mounted on a wall or a ceiling. From this perpendicular perspective, a metal base 50020 which forms part of the outer boundary of the lighting fixture occupies a portion (e.g., a minimal portion) of the view when compared with the optically transmissive enclosure 602. A metal base is thermally connected to a light-emitting diode arrays that form the luminant.

In at least some exemplary embodiments, inside an outer optically transmissive enclosure defined by the outer boundary of the light fixture is the light-emitting diode array represented within FIG. 4A. The array in FIG. 4A is 12×10—that there are 12 columns and 10 rows—but the instant invention is not limited to a 12×10 array but by any array that comprises at least 1 column and 2 rows or 2 columns and 1 row. The light-emitting diode array is mounted onto a base and is in thermal connection with a metal base. Thermal connection means for example in the instant invention as hereinbefore described and whereby heat is transferred from the donor to the acceptor (the reservoir in many cases) by conduction, and or convection and or thermal radiation. In this sense, thermal connection means also thermodynamic connection.

In the case of thermal radiation in at least some exemplary embodiments, the thermal connection between donor and acceptor does not engage the intervening medium or gas. In this sense, engage means involve; does not engage means does not involve. Proof of this point is that thermal radiation is transmitted in a vacuum. This does not mean that thermal radiation does not pass-through intervening matter, it simply means that the intervening matter does not participate in the transmission of the thermal radiation; it is transparent or transmissive to the thermal radiation. The thermal radiation is created at the source of heat and then transports itself without the participation of the intervening matter. In the case of a vacuum, the spectral characteristics of the thermal radiation are that of the temperature of the source or location which is generating locally heat and that spectral characteristics are unchanged as the thermal radiation transports through a vacuum, regardless of the temperature of the vacuum.

In contrast, convection and conduction does engage the intervening medium or gas. That is, thermal radiation may not involve an intervening medium to carry it. Further, the intervening medium is unchanged as thermal radiation emitted by the donor traverses the medium until it is adsorbed by the acceptor. Hence, in at least some exemplary embodiments, the thermal radiation from the light-emitting diode array does not change the temperature of an inner space or interior space of the enclosures, outer-most and inner-most respectively, unless there is a frequency of radiation tuned to a frequency of absorption of the intervening gas. Thermal radiation emitted by a light-emitting diode is due to acceleration of electrons in the matter that is heated (e.g., electrons in the conduction band of a semiconductor or in the surface interface of an optically opaque, fully absorbing material). When any charged particle (such as an electron, a proton, or an ion) accelerates, it radiates away energy in the form of electromagnetic waves. Generally, the thermal radiation is increased when the temperature rises but not spectrally equally over any given ranges of temperatures.

For the sake of simplicity, only one of the light-emitting diodes, as packaged in an inner enclosure, is shown with a demarcation (i.e., “301”). The board 50030 to which the plurality of light-emitting diodes are thermally connected, is, for example, overlaying a metal base 50020 in FIG. 4A. Overlaying is meant convey that 50030 is laid or placed over or upon another (i.e., 50020) to cover. The overlaying may be partial so that electrical leads can be incorporated that ultimately will be connected to a power supply from a distant source and to not interfere with placement of the lighting fixture flush with a wall or a ceiling. The demarcations of 50031, 50032, 50033 and 50034 are protrusions from the metal base that hold the outermost optically transmissive enclosure in place. These protrusions raised from the surface of the flat, metal base comprising an inert solid, also form the basis for opened vents into the metal base.

In at least some exemplary embodiments, the thermal connection is enhanced by using a gas to transport the heat that is formed by a) operating each light-emitting diode due to inefficiencies of recombination of hole and electron pairs at the p-n junction and b) the inevitable reduction in energy, and the heat therefore created to transfer the excess energy, due to the electronic atomic or molecular relaxation of the electronic states populated by blue light (a primary radiation) to the relaxed electronic states which, when populated, yield the down-converted light (a Stokes shift) at the source of a secondary radiation.

In at least some exemplary embodiments, a source of a Stokes shift may not be adjacent to the p-n junction and may be far away, a so-called far-field energy transfer. If a source (site or location) of a Stokes shift is a molecular distance away, a so-called near field energy transfer occurs between the p-n junction and the luminophor initiating the down-conversion. For sake of simplicity, the description herein does not highlight any possible reduction in energy due to the scattering of incident primary radiation by intervening matter, such as a luminophor, or a reduction in energy due to so-called self-absorption and radiation imprisonment.

A site of a Stokes shift is that region of a luminescent element or luminophoric medium that is in its lowest vibrationally level of an electronic excited state, surrounded by ground electronic states of the same or different luminescent elements or luminophoric medium, such that when the ratio of electronic excited states to ground electronic states is one, then it is said that a mixture of thermodynamic states are at their maximum entropy of mixing. A site of a Stokes shift may also be called a location of a Stokes shift. The generation of said site is accompanied by the local generation of heat which the instant invention dissipates to and beyond the external boundary when said site is in contact with a gas. As the entropy at the site of the Stokes shift decreases with dissipation, the entropy passed into the external surroundings increases.

In at least some exemplary embodiments, a gas that provides the thermal connection to a metal base and which forms a region of an inner space of the outermost enclosure may be air. It may be a gas such as nitrogen, helium, deuterium, hydrogen, argon, krypton or xenon or any combination thereof including combinations with air. Such gases may be introduced into the outmost optically transmissive enclosure by ways of actuating the entry and exit port 7006 in FIG. 4C. The desired gas may be introduced into an inner space of the outer-most enclosure after first creating a vacuum in the same enclosure by connecting a vacuum pump to the same port 7006 and applying a vacuum.

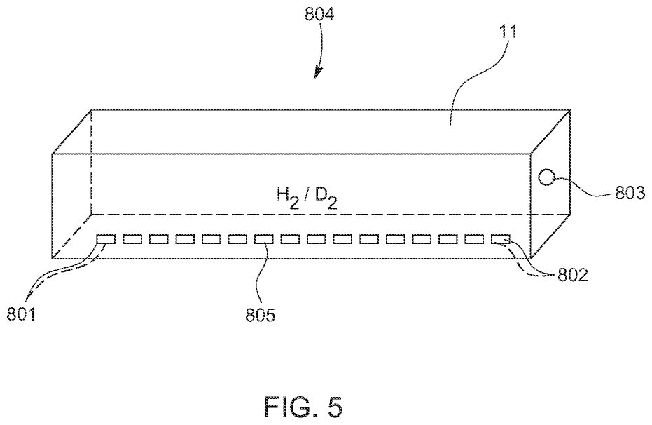

FIG. 5 shows an array 804 of light-emitting diodes (e.g., each diode would be with the demarcation 805 although for purposes of clarity only one diode is so marked) each within a secondary enclosure. In at least some exemplary embodiments, the electrical leads transport the current which power the array is shown as 801 and 802, and 11 marks an outer enclosure which comprises both the light-emitting diode array (each within a secondary enclosure) and an inner space of an outer enclosure 11. In FIG. 5, a gas that occupies an inner space of an outer enclosure, is shown as H₂ (hydrogen molecular) gas and Deuterium (D₂ or H-D) gas. It may be a gas such as nitrogen, helium, argon, krypton or xenon or any combination thereof including combinations with air.

The port 803 may be used to introduce other inert gases such as perfluorobutane, perfluoropropane, hexafluoroethane, or carbon dioxide. The purpose of this figure is to demonstrate that an embodiment that meets the claim limitations of the instant invention may have a port in which gas within the inner space can be refilled or introduced after device construction.

In one embodiment of the instant invention, each light-emitting diode array is of the same color of primary radiation; in another embodiment a plurality of light-emitting diode arrays are of the same color of primary radiation; in another embodiment, each light-emitting diode array is of a different color of primary radiation than that of the array to which it is adjacent.

In one embodiment of the instant invention, a gas introduced into an enclosure may be a luminescent gas when its absorption spectrum overlaps with the emission spectrum of a primary radiation. By usage of the entry and exit ports, and the initial preparation of an evacuated space and then the introduction of a gas vapor, a gas so entrained may be a liquid at atmospheric pressure but a gas in a region that is a partial vacuum. An example of a luminescent gas is hexafluoro-acetone. As with Hg vapor, it is best to permanently entrain the hexafluoro-acetone vapor inside a permanently sealed enclosure or enclosure, e.g. a non-glass enclosure.

In one embodiment, a metal base, in thermal contact with a gas in an inner space and in contact with a second enclosures that comprise of light emitting diodes, through which heat is transferred away, from the aforementioned, by conduction, is comprised of steel or another metal imprinted with non-electrical conducting boron-containing metals or electrical conducting copper-containing metals.

In one embodiment, a metal base comprising an inert solid metal base is rectangular, oval, oblong, circular or triangular in shape.

In one embodiment, the light-emitting diode arrays emit blue light and the optically transmissive outer enclosure contains a red colorant.

In one embodiment, the light emitting diode arrays comprise light-emitting diode dies that emit visible blue primary radiation and visible red primary radiation as determined by a human observer.

Further, while the invention has been described primarily herein in reference to the generation of white light, it will be apparent that the scope of the invention is not thus limited, but rather extends to and encompasses the production of light of other colors than mixed white light, utilizing solid state primary radiation emitters, and down converting luminophoric media.

In one embodiment, a second enclosure 111 is filled with a gaseous medium that is inert such as argon gas and otherwise prevents the quenching of the excited state of a phosphorescent component of the luminescent medium that provides secondary radiation after excitation by either primary radiation or non-radiative energy transfer.

Thus, while the invention has been described with reference to various illustrative embodiments, features, aspects, and modifications, it will be apparent that the invention may be widely varied in its construction and mode of operation, within the spirit and scope of the invention as hereinafter claimed.

1. A microelectronic device, comprising:
a plurality of optically transmissive enclosures, at least one fully nested within another;
at least one outer optically transmissive enclosure coupled to a metal base both forming jointly, when coupled, an outer boundary of the microelectronic device which defines an inner space;
at least one light-emitting diode with a plurality of light-emitting diodes each including at least one p-n junction operable to emit a primary radiation when energized with an electrical connection, positioned fully within at least one second enclosure that isolates the plurality of light-emitting diodes from an outer boundary of said second enclosure, and which defines an interior space;
a gas within an inner space;
one luminescent element that is radiatively excited by a primary radiation to cause the luminescent element to emit a secondary radiation with a Stokes shift wherein the at least one site of a Stokes shift is exposed to a gas;
a thermal connection within said inner space with at least one light-emitting diode die p-n junction, the interior space, a gas, said metal base;
wherein heat is dissipated to external surroundings through the inner space and through the at least one outer optically transmissive enclosure, and through the at least one metal base; and
wherein said interior space is disposed within and surrounded by said inner space.

2. The device of claim 1, wherein the plurality of optically transmissive enclosures are in a doubly nested relationship or a triply nested relationship.

3. The device of claim 1, wherein said metal base is a flat metal base comprising an inert solid in a rectangular, oval, oblong, triangular or circular in shape.

4. The device of claim 2 wherein said inner space is comprised of a gas other than pure oxygen or a vacuum, coupled with said interior space comprised of any concentration of deuterium, helium, hydrogen, air, nitrogen, argon, krypton or xenon or any combination thereof.

5. The device of claim 4 wherein the inner space contains a gas comprised of any concentration of deuterium, helium, hydrogen, air, nitrogen, argon, krypton or xenon or any combination thereof.

6. The device of claim 5 wherein the interior space contains a luminescent element.

7. The device of claim 1, further comprising:
at least one single-die semiconductor light-emitting diode (LED) of the plurality of light-emitting diodes, comprising a GaN, InGaN, AlGaN, SiC semiconductor, or a semiconductor comprising Si, C, Ga, N, In or Al configured to emit a primary radiation which is the same for the at least one single light-emitting diode die in at least one light-emitting diode array present in the device, said primary radiation being a first wavelength radiation; and
a collection or concentration luminophoric medium arranged within an interior space in a receiving relationship to said primary radiation, wherein the luminophoric medium responsively emits from a site of a Stokes shift, both thermal radiation and a secondary, longer wavelength than the first wavelength radiation, polychromatic radiation, when the luminophoric medium is excited via exposure to a primary radiation, wherein separate wavelengths of said polychromatic radiation mix to produce an achromatic or a chromatic light output.

8. A solid-state light-emitting device, comprising:
at least one single-die semiconductor light-emitting diode assembly with a p-n junction operable to emit light when energized with an electrical connection;
at least one outermost optically transmissive enclosure said enclosure connected to a metal base comprising an inert solid, both forming, when connected, an outer boundary of the solid-state light-emitting device which defines an inner space;
at least one opened vent, disrupting the continuity of the connection between the paired outermost optically transmissive enclosure and said metal base comprising an inert solid; and
at least one light-emitting diode die fully within a second enclosure;
wherein an interior volume is formed by said second enclosure,
wherein heat is dissipated to external air surroundings through said metal base comprising an inert solid;
wherein heat is dissipated to external air surroundings through the at least one optically transmissive enclosure;
wherein a second enclosure is disposed within and surrounded by said inner space; wherein one luminescent element that is radiatively excited by primary radiation to cause the luminescent element to emit secondary radiation with a Stokes shift wherein the at least one site of a Stokes shift is exposed to a gas;
wherein a plurality of optically transmissive enclosures, at least one fully within another.

9. The device of claim 8, wherein said metal base comprising an inert solid is flat.

10. The device of claim 9, wherein said metal base is rectangular, oval, oblong, circular, or triangular.

11. The device of claim 10, wherein said luminescent element is covalently bonded onto the wall of a second enclosure comprised of glass.

12. The device of claim 11 wherein said inner space is comprised of a gas other than pure oxygen, or a vacuum, coupled with said interior space comprised of any concentration of deuterium, helium, hydrogen, air, nitrogen, argon, krypton or xenon or any combination thereof.

13. The device of claim 12 wherein the inner space contains a gas comprised of any concentration of deuterium, helium, hydrogen, air, nitrogen, argon, krypton or xenon or any combination thereof.

14. The device of claim 7, wherein said luminescent element is covalently attached to the inner wall of the second enclosure.

15. The device of claim 2, further comprising:
at least one single-die semiconductor light-emitting diode (LED) of the plurality of light-emitting diodes, comprising a GaN, InGaN, AlGaN, SiC semiconductor, or a semiconductor comprising Si, C, Ga, N, In or Al configured to emit a primary radiation which is the same for the at least one single light-emitting diode die in at least one light-emitting diode array present in the device, said primary radiation being a first wavelength radiation; and
a collection or concentration luminophoric medium arranged in receiving relationship to said primary radiation, wherein the luminophoric medium responsively emits from a site of a Stokes shift, both thermal radiation and a secondary, longer wavelength than the first wavelength radiation, polychromatic radiation when the luminophoric medium is excited via exposure to a primary radiation, wherein separate wavelengths of said polychromatic radiation mix to produce an achromatic or a chromatic light output.

16. The device of claim 15 wherein a fluorescent, a phosphorescent, a thermo-luminescent or an electro-luminescent material is a thin layer to both an inner wall of the second enclosure and an outer wall of a second enclosure whereby the spontaneous emission spectrum from the inner wall and that from the outer wall is one of the same or different.

17. The device of claim 15, wherein said plurality of optically transmissive enclosures includes a triply nested enclosure.

18. The device of claim 15, further comprising a fluorescent material as a thin layer on the light-emitting diode die with a radiative lifetime between 17 and 39 nanoseconds.

19. The device of claim 15, wherein the metal base comprises of steel, boron nitride, aluminum, or copper.

20. The device of claim 15, further comprising at least one opened vent on the outer boundary of the device wherein said at least opened vent is a seam between a metal base and an outer optically transmissive enclosure.
